(19) United States
(12) Patent Application Publication
(10) Pub. No.: US 2023/0165135 A1
(43) Pub. Date: May 25, 2023

(54) d10 METAL CARBENE COMPLEXES FOR OLED APPLICATIONS

(71) Applicants: Versitech Limited, Hong Kong (CN); Hong Kong Quantum AI Lab Limited, Hong Kong (CN)

(72) Inventors: Rui Tang, Hong Kong (CN); Chi-Ming Che, Hong Kong (CN); Gang Cheng, Hong Kong (CN); Tsz-Lung Lam, Hong Kong (CN)

(21) Appl. No.: 18/057,632

(22) Filed: Nov. 21, 2022

Related U.S. Application Data
(60) Provisional application No. 63/282,496, filed on Nov. 23, 2021.

(51) Int. Cl. H10K 85/30; C07F 1/08; C07F 1/00; C09K 11/06

(52) U.S. Cl. CPC H01L 51/0091; C07F 1/08; C07F 1/00; C09K 11/06; C09K 2211/188; C09K 2211/1074; C09K 2211/1029; C09K 2211/1044; H01L 51/5012

(57) ABSTRACT

Described herein are two-coordinated d10 metal carbene complexes containing (i) Cu(I), Ag(I), or Au(I), (ii) a pyrazine-fused NHC ligand or a pyridine-fused NHC ligand, and (iii) a carbazole ligand, a pyrido[2,3-b]indole ligand, or a pyrido[3,4-b]indole ligand. The radiative properties of the compounds can be controlled by thermally activated delayed fluorescence. The emission colors of the complexes can be tuned by using carbazoles with varying donor strength. Also described are methods of using the complexes.

### CROSS-REFERENCE TO RELATED APPLICATION

This application claims benefit of and priority to U.S. Provisional Application No. 63/282,496 filed Nov. 23, 2021, which is incorporated herein by reference in its entirety.

### FIELD OF THE INVENTION

The disclosed invention is generally in the field of luminescent d10 metal carbene complexes, particularly d10 metal carbene complexes containing (i) a pyrazine-fused N-heterocyclic carbene ligand or a pyridine-fused N-heterocyclic carbene ligand and (ii) a carbazole ligand or an alpha-, beta-gamma-, or delta carboline ligand, and the use of these complexes in organic light-emitting devices (OLEDs).

### BACKGROUND OF THE INVENTION

Transition metal complexes have gained significant interest in commercial and academic settings as molecular probes, catalysts, and luminescent materials. As luminescent materials, transition metal complexes are increasingly being explored as potential alternatives to pure organic-based materials due to their potential for improved luminescence efficiency and device stability, compared to pure organic-based materials.

Currently, cyclometalated iridium(III) and Pt(II) phosphors are among the most competitive candidates in commercial OLED emitters. Nonetheless, the development of metal-based or organic thermally activated delayed fluorescence (TADF) emitters still lag behinds, mainly because of their lower stability that can affect device lifetimes. The device performance and operational stability/lifetime of metal-based OLEDs must be enhanced for practical applications. Several studies have described d10 complexes for use as OLED emitters. These include U.S. Pat. No. 9,773,986 to Thompson, et al.; European Patent Application Publication 3,489,243 by Thompson, et al.; U.S. Patent Application Publication 2015/0108451 by Thompson, et al., and U.S. Patent Application Publication 2019/0161504 by Thompson, et al.; and CN112794863. Nonetheless, these studies do not report the results of device lifetime. Additional studies include complexes of Cu(I), Ag(I), or Au(I), involving carbene ligands and carbazoles, such as: Hamze, et al., Science 2019, 363, 601-606; Shi, et al., J. Am. Chem. Soc. 2019, 141, 3576-3588; Hamze, et al., J. Am. Chem. Soc. 2019, 141, 21, 8616-8626; Li, et al., Angew. Chem. Int. Ed. 2020, 59,8210-8217; and Hamze, et al., Front. Chem. 2020, 8:401. However, some of the complexes showed phosphorescent character, leading to lower radiative decay rates. For example, the complexes IPr-Cu-Cz and IMes-Cu-Cz (Angew. Chem. Int. Ed. 2020, 59,8210-8217) showed long-lived room-temperature phosphorescence with lifetime in the millisecond range.

Accordingly, there remains a need to develop improved and efficient transition metal complexes so that OLED-containing products can have improved efficiencies.

Therefore, is an object of the present invention to provide new and improved luminescent transition metal two-coordinate complexes containing a d10 metal.

### SUMMARY OF THE INVENTION

Described are two-coordinated d10 metal carbene complexes containing (i) Cu(I), Ag(I), or Au(I), (ii) a pyrazine-fused N-heterocyclic carbene (NHC) ligand or a pyridine-fused N-heterocyclic carbene ligand, and (iii) a carbazole ligand, a pyrido[2,3-b]indole ligand or a pyrido[3,4-b]indole ligand. The radiative properties of these compounds can be controlled by TADF. The emission colors of these compounds can also be tuned by using carbazoles, pyrido[2,3-b]indoles, or pyrido[3,4-b]indoles with varying donor strength.

The compounds have a structure:

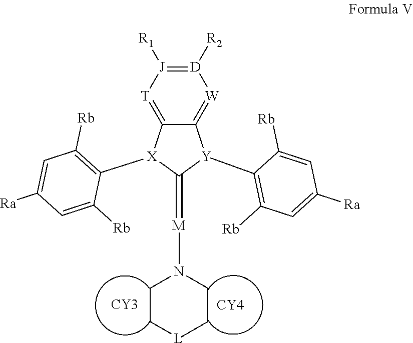

wherein:

D is carbon,

T, J, and W are independently carbon or nitrogen, wherein at least one of T, J, and W is nitrogen, wherein when T is carbon, J is nitrogen, or when T is nitrogen, J is carbon, and T, J, and W are bonded to one or no hydrogen atom according to valency,

each Ra is independently hydrogen, unsubstituted alkyl, or substituted alkyl,

each Rb is independently unsubstituted alkyl, or substituted alkyl,

X and Y are nitrogen,

L is absent or a single bond,

CY3 and CY4 are independently unsubstituted aryl, substituted aryl, unsubstituted heteroaryl, substituted heteroaryl, substituted C₃-C₂₀ cycloalkenyl, unsubstituted C₃-C₂₀ cycloalkenyl, or a fused combination thereof, and

R₁ and R₂ are hydrogen, or R₁, J, D, and R₂ together form an unsubstituted aryl, substituted aryl, unsubstituted heteroaryl, or substituted heteroaryl.

In some forms, the compounds have a structure:

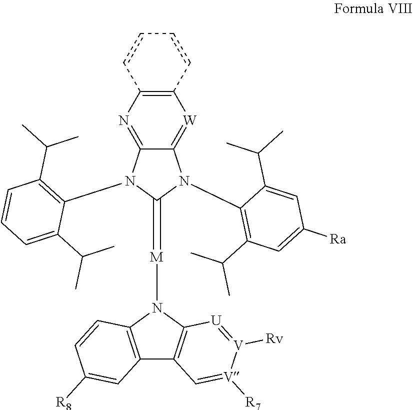

wherein:

(i) M=Cu(I); W=N; Ra=H; U=CH; V=V″=carbon; Rv=H; R₇=R₈=H;

(ii) M=Cu(I); W=N; Ra=H; U=CH; V=V″=carbon; Rv=H; R₇=H; R₈=CN;

(iii) M=Cu(I); W=N; Ra=H; U=CH; V=V″=carbon; Rv=H; R₇=R₈=tert-butyl;

(iv) M=Cu(I); W=N; Ra=H; U=CH; V=V″=carbon; Rv=H; R₇=R₈=phenyl;

(v) M=Cu(I); W=N; Ra=H; U=CH; V=N; V″=carbon; Rv=absent; R₇=R₈=H; (vi) M=Cu(I); W=U=CH; V=V″=carbon; Rv=H; Ra=iso-propyl; R₇=R₈=H;

(vii) M=Cu(I); W=N; Ra=H; U=CH; V=V″=carbon; R₈=H; Rv and R₇ together form

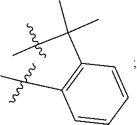 [SMILES: *c1ccccc1C(*)(C)C]

(viii) M=Cu(I); W=U=CH; Ra=iso-propyl; V=V″=carbon; R₈=H; Rv and R₇ together form

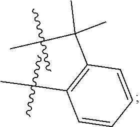 [SMILES: *c1ccccc1C(*)(C)C]

(ix) M=Cu(I); W=N; Ra=H; U=CH; V=V″=carbon; Rv=H; R₇=R₈=H;

(x) M=Cu(I); W=N; Ra=H; U=CH; V=V″=carbon; Rv=H; R₇=H; R₈=F;

(xi) M=Cu(I); W=N; Ra=H; U=CH; V=V″=carbon; Rv=H; R₇=R₈=methyl;

(xii) M=Au(I); W=N; Ra=H; U=CH; V=carbon; Rv=H; V″=carbon; R₇=R₈=H;

(xiii) M=Au(I); W=N; Ra=H; U=CH; V=carbon; Rv=H; V″=carbon; R₇=H, R₈=CN;

(xiv) M=Au(I); W=N; Ra=H; U=N; V=carbon; Rv=H; V″=carbon; R₇=R₈=H;

(xv) M=Au(I); W=U=CH; V=carbon; Rv=H; ; Ra=iso-propyl; V″=carbon; R₇=R₈=H;

(xvi) M=Au(I); W=N; Ra=H; U=CH; V=N; Rv=absent; V″=carbon; R₇=R₈=H;

(xvii) M=Au(I); W=N; Ra=H; U=CH; V=V″=carbon; Rv=H; R₇=R₈=CN;

(xviii) M=Au(I); W=N; Ra=hydrogen; U=CH; V=V″=carbon; R₈=H; Rv and R₇ together form

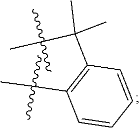 [SMILES: *c1ccccc1C(*)(C)C]

(xix) M=Au(I); W=U=CH; Ra=iso-propyl; V=V″=carbon; Rv=H; R₇=R₈=tert-butyl;

(xx) M=Au(I); W=U=CH; Ra=iso-propyl; V=V″=carbon; Rv=H; R₇=H; R₈=F;

(xxi) M=Au(I); W=N; U=CH; Ra=H; V=V″=carbon; Rv=H; R₇=R₈=H;

(xxii) M=Au(I); W=N; U=CH; Ra=H; V=V″=carbon; Rv=H; R₇=R₈=tert-butyl;

(xxiii) M=Ag(I); W=N; U=CH; Ra=H; V=V″=carbon; Rv=H; R₇=R₈=H;

for (i), (ii), (iii), (iv), (v), (vi), (vii), (viii), (xii), (xiii), (xiv), (xv), (xvi), (xvii), (xviii), (xix), (xx), and (xxiii), the dashed lines denote the absence of bonds, and

for (ix), (x), (xi), xxi, and xxii, the dashed lines denote the presence of bonds.

The disclosed compounds can be included in organic light-emitting devices, for use in commercial applications.

### BRIEF DESCRIPTION OF THE DRAWINGS

FIG. 1 shows chemical structures of metal carbene complexes denoted Cu1, Cu2, Cu3, Cu4, Cu5, Cu6, Cu1, Cu8, Cu9, Cu10, Cu11, Au1, Au2, Au3, Au4, Au5, Au6, Au7, Au8, Au9, Au10, Au11, and Ag1.

FIGS. 2A, 2B, 2C, 2D, 2E, and 2F show the crystal structures of Au1, Au4, Au8, Au9, Cu3, and Cu6, respectively, shown in FIG. 1.

FIGS. 3A-3D are line graphs showing electroluminescent spectra and performance characteristics of Cu1-based devices with doping concentration of 2-8wt/wt %. Device structure: ITO/HAT-CN (5 nm)/TAPC (40 nm)/TCTA (10 nm)/TCTA: TPBi: Cu1 (20 nm)/TPBi (50 nm)/LiF (1 nm)/Al (100 nm).

FIGS. 4A-4D are line graphs showing electroluminescent spectra and performance characteristics of devices of Cu2 with doping concentration of 2-6 wt/wt %. Device structure: ITO/HAT-CN (5 nm)/TAPC (40 nm)/TCTA (10 nm)/TCTA: DPEPO: Cu2 (20 nm)/DPEPO (10 nm)/TPBi (40 nm)/LiF (1 nm)/Al (100 nm).

FIGS. 5A-5D are line graphs showing electroluminescent spectra and performance characteristics of devices of Cu3 with doping concentration of 2-6 wt/wt %. Device structure: ITO/HAT-CN (5 nm)/TAPC (40 nm)/TCTA (10 nm)/TCTA: TPBi: Cu3 (20 nm)/TPBi (50 nm)/LiF (1 nm)/Al (100 nm).

FIGS. 6A-6D are line graphs showing electroluminescent spectra and performance characteristics of devices of Au1 with doping concentration of 2-6 wt/wt %. Device structure: ITO/HAT-CN (5 nm)/TAPC (40 nm)/TCTA (10 nm)/TCTA: TPBi: Au1 (20 nm)/TPBi (50 nm)/LiF (1 nm)/Al (100 nm).

FIGS. 7A-7D are line graphs showing electroluminescent spectra and performance characteristics of devices of Au2 with doping concentration of 2-6 wt/wt %. Device structure(I): ITO/HAT-CN (5 nm)/TAPC (40 nm)/TCTA (10 nm)/TCTA: TPBi: Au2 (20 nm)/TPBi (50 nm)/LiF (1 nm)/Al (100 nm).

FIGS. 8A-8D are line graphs showing electroluminescent spectra and performance characteristics of devices of Au2 with doping concentration of 2-8 wt/wt %. Device structure (II): ITO/HAT-CN (5 nm)/TAPC (40 nm)/TCTA (10 nm)/TCTA: DPEPO: Au2 (20 nm)/DPEPO (10 nm)/TPBi (40 nm)/LiF (1 nm)/Al (100 nm).

FIG. 9 is a line graph showing the emission spectra of Cu4.

FIG. 10 is a line graph showing the emission spectra of Au3.

FIG. 11 is a line graph showing the emission spectra of Cu5.

FIGS. 12A and 12B are line graphs showing the emission spectra of Cu6 and Au4.

FIGS. 13A-13C are line graphs showing device data for Cu2 in Table 5b. EL spectra and performance characteristics of devices of Cu2 with doping concentration of 2 wt/wt %. Device structure: ITO/HAT-CN (5 nm)/PT-301 (160 nm)/PT-603I (5 nm)/Cu2: LLP604 (20 nm)/PT74M (5 nm)/LET321: Liq (1:1, 25 nm)/Liq (1 nm)/Al (100 nm).

FIGS. 14A-14D are line graphs showing the EL spectra and performance characteristics of devices of Cu3 with doping concentration of 2-6 wt/wt %. Device structure (II): ITO/HAT-CN (5 nm)/PT-301 (160 nm)/EB (5 nm)/Cu3: RH (40 nm)/HB (5 nm)/ZADN: Liq (35:65, 35 nm)/Liq (1 nm)/Al (100 nm).

FIGS. 15A-15D are line graphs showing the EL spectra and performance characteristics of devices of Cu4 with doping concentration of 2-6 wt/wt %. Device structure (I): ITO/HAT-CN (5 nm)/TAPC (40 nm)/TCTA (10 nm)/TCTA: TPBi: Cu4 (20 nm)/TPBi (50 nm)/LiF (1 nm)/Al (100 nm).

FIGS. 16A-16D are line graphs showing the EL spectra and performance characteristics of devices of Cu4 with doping concentration of 2-6 wt/wt %. Device structure (II): ITO/HAT-CN (5 nm)/PT-301 (160 nm)/PT-603I (5 nm)/Cu4: LLP604 (20 nm)/PT74M (5 nm)/LET321: Liq (1:1, 25 nm)/Liq (1 nm)/Al (100 nm).

FIGS. 17A-17D are line graphs showing the EL spectra and performance characteristics of devices of Au2 with doping concentration of 2-8 wt/wt %. Device structure (III): ITO/HAT-CN (5 nm)/PT-301 (160 nm)/PT-603I (5 nm)/Au2: LLP604 (20 nm)/PT74M (5 nm)/LET321: Liq (1:1, 25 nm)/Liq (1 nm)/Al (100 nm).

FIG. 18 is a line graph showing the emission spectra of Cu1 (in MCP film).

FIG. 19 is a line graph showing the emission spectra of Cu8 (in MCP film).

FIG. 20 is a line graph showing the emission spectra of Cu9 (in degassed toluene and MCP film).

FIG. 21 is a line graph showing the emission spectra of Au7 (2 wt/wt % in PMMA film).

FIGS. 22A-22D are line graphs showing the EL spectra and performance characteristics of devices of Cu6 in TCTA:DPEPO co-host, with doping concentration of 2-6 wt/wt %. Device structure: ITO/HAT-CN (5 nm)/TAPC (40 nm)/TCTA (10 nm)/TCTA: DPEPO: Cu6 (20 nm)/DPEPO (10 nm)/TPBi (40 nm)/LiF (1.2 nm)/Al (100 nm).

FIGS. 23A-23D are line graphs showing the EL spectra and performance characteristics of vapor-deposited hyper-fluorescence OLED with Cu6 and v-DABNA in mCBP. Device structure: ITO/HAT-CN (10 nm)/BPBPA (120 nm)/mCBP (10 nm)/mCBP: Cu6: v-DABNA (20 nm)/SF3-TRz (5 nm)/SF3-TRz: Liq (1:1, 25 nm)/Liq (2 nm)/Al (100 nm).

FIGS. 24A-24D are line graphs showing the EL spectra and performance characteristics of Cu7 in DMIC-Cz: DMIC-Trz co-host, with doping concentration of 2-6 wt/wt %. Device structure: ITO/HAT-CN (10 nm)/BPBOA (80 nm)/FSF4A (5 nm)/DMIC-Cz: DMIC-Trz: Cu7 (30 nm)/ANT-Biz (5 nm)/ANT-Biz: Liq (25 nm)/Liq (2 nm)/Al (100 nm).

FIGS. 25A-25D are line graphs showing the EL spectra and performance characteristics of vapor-deposited hyper-fluorescence OLED with Cu7 and MR-R in RH. Device structure: ITO/HAT-CN (10 nm)/HT (40 nm)/EB (5 nm)/Cu7: MR-R: RH (40 nm)/HB (5 nm)/ZADN: Liq (35:65) (35 nm)/Liq (2 nm)/Al (100 nm).

FIGS. 26A-26D are line graphs showing the EL spectra and performance characteristics of vapor-deposited hyper-fluorescence OLED with Au3 and BN-2 in mCBP. Device structure: ITO/HAT-CN (5 nm)/TAPC (40 nm)/mCBP (10 nm)/Au3: BN-2: mCBP (20 nm)/PPF (10nm)/TmPyPb (40 nm)/LiF (1.2 nm)/Al (100 nm).

FIGS. 27A-27D are line graphs showing the EL spectra and performance characteristics of Au5 in mCBP:CzSiTrz co-host, with doping concentration of 2-8 wt/wt %. Device structure: ITO/HAT-CN (10 nm)/FSFA (120 nm)/mCBP (10 nm)/mCBP: CzSiTrz: Au5 (30 nm)/SF3-Trz (5 nm)/SF3-Trz: Liq (25 nm)/Liq (2 nm)/Al (100 nm).

FIG. 28 is a line graph showing the emission spectra of Au10 (in MCP film).

FIG. 29 is a line graph showing the emission spectra of Au11 (in MCP film).

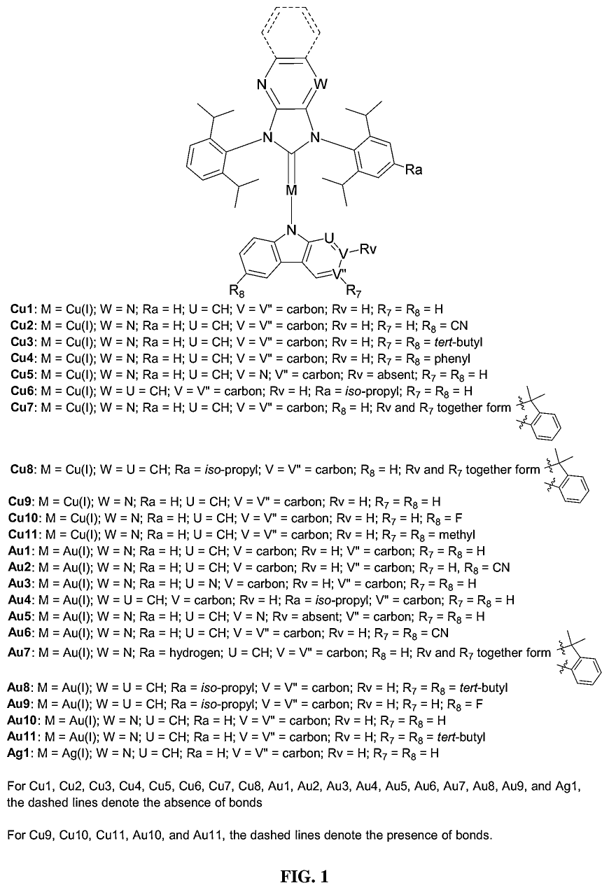

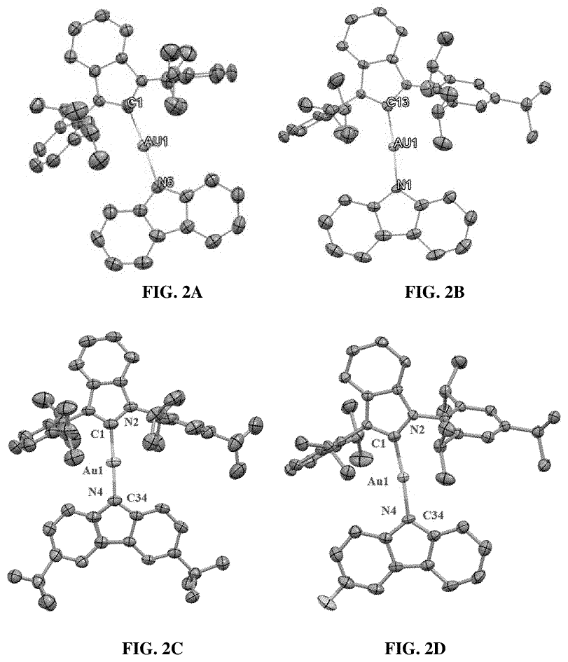

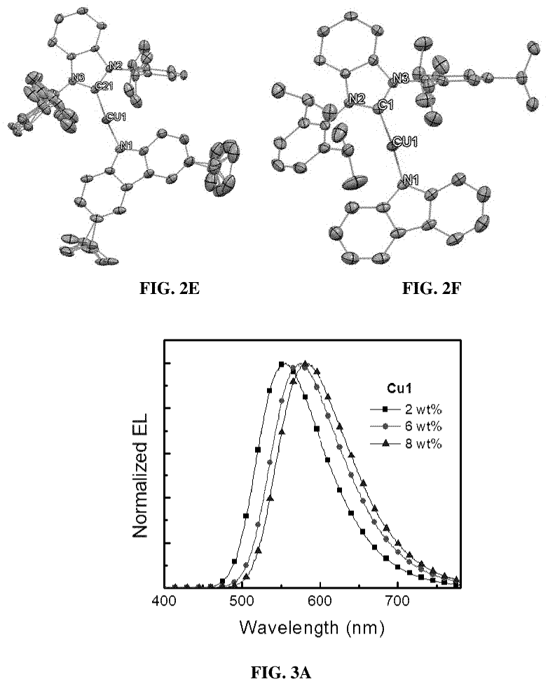

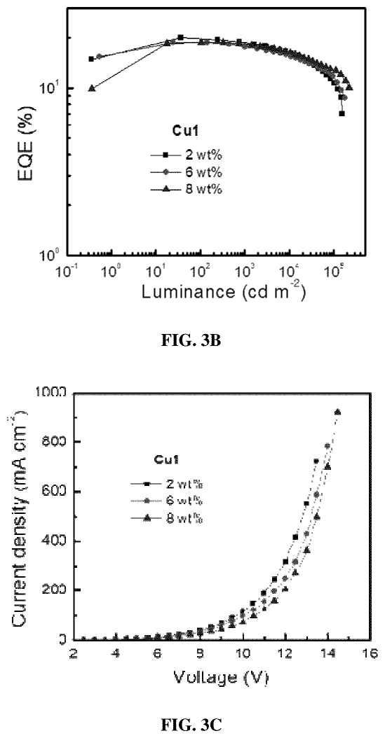

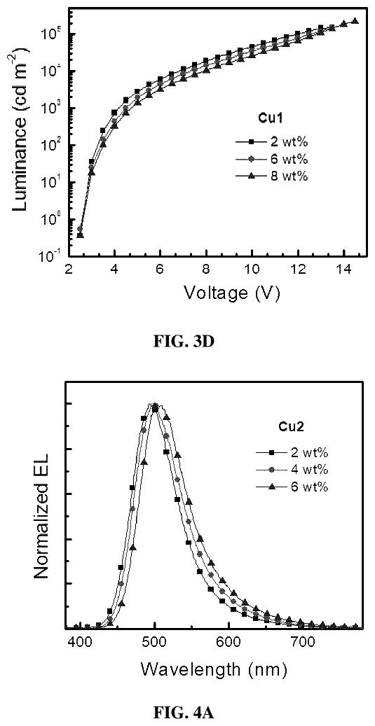

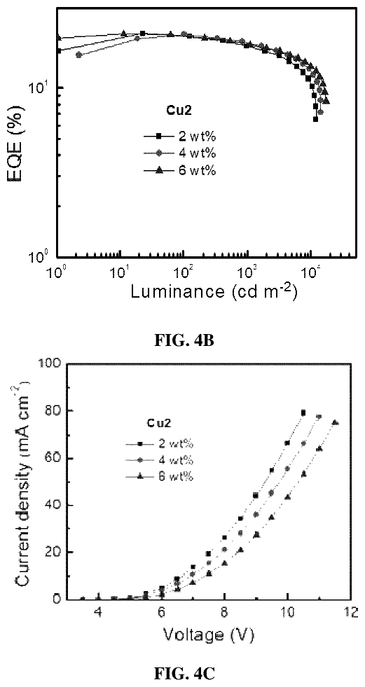

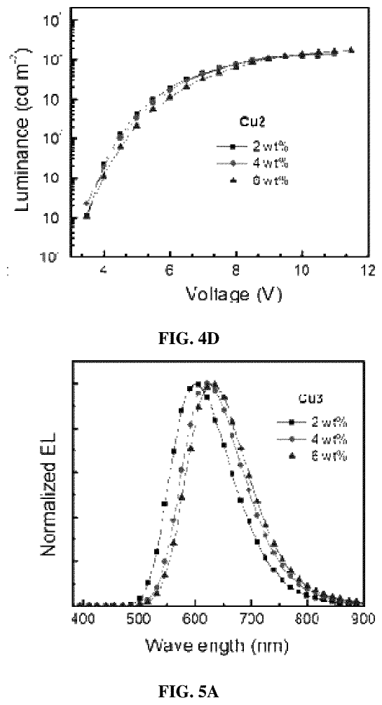

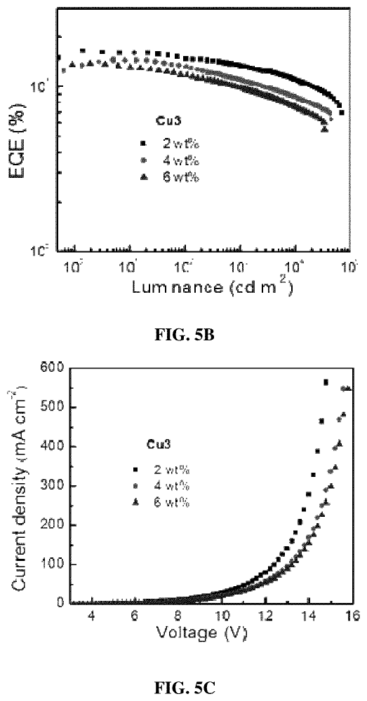

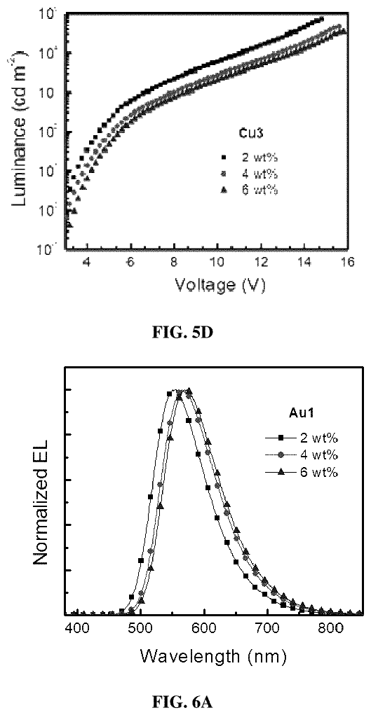

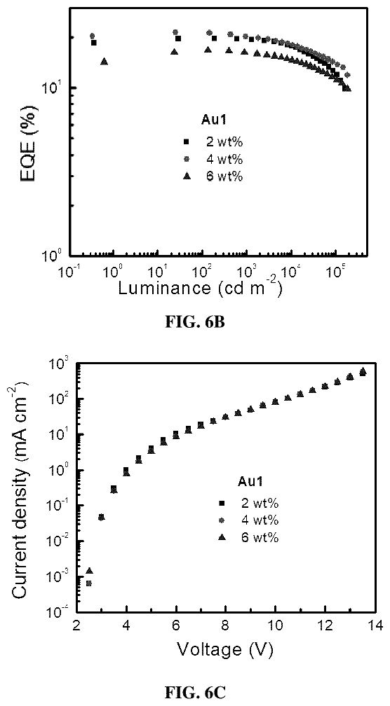

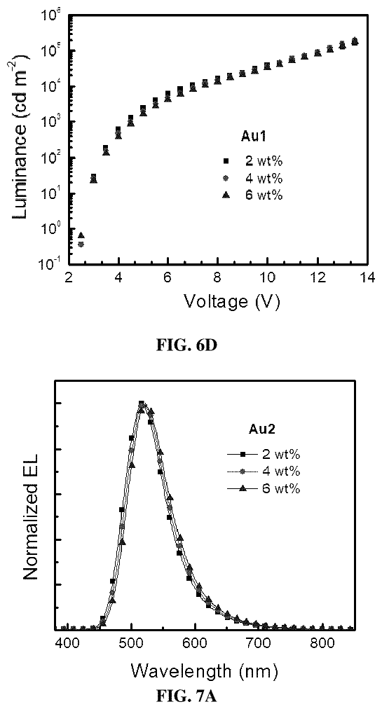

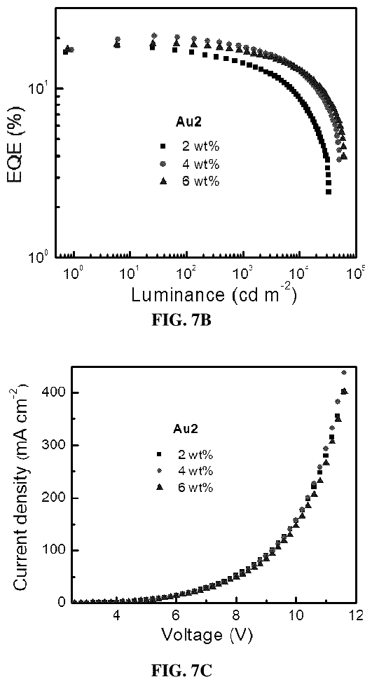

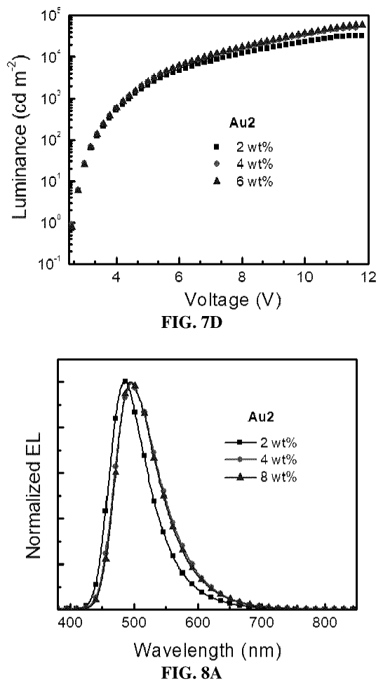

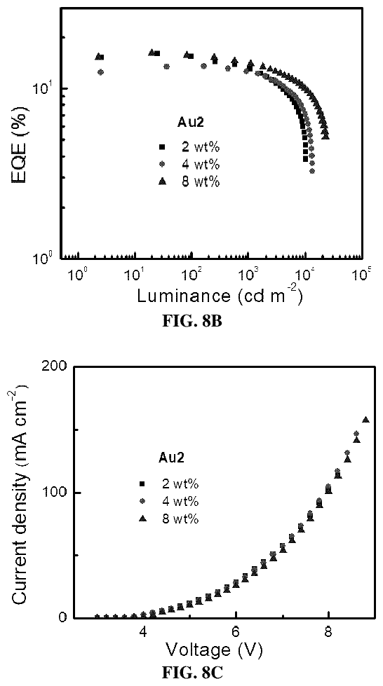

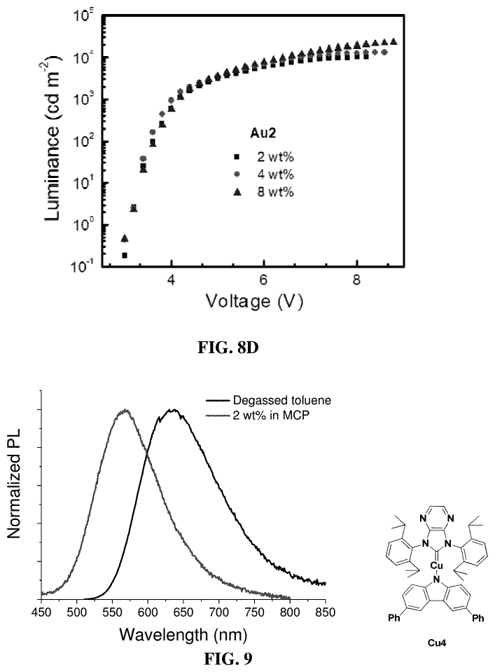

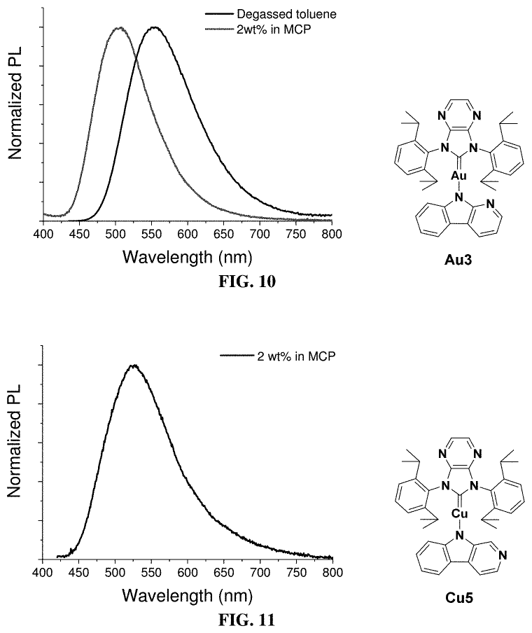

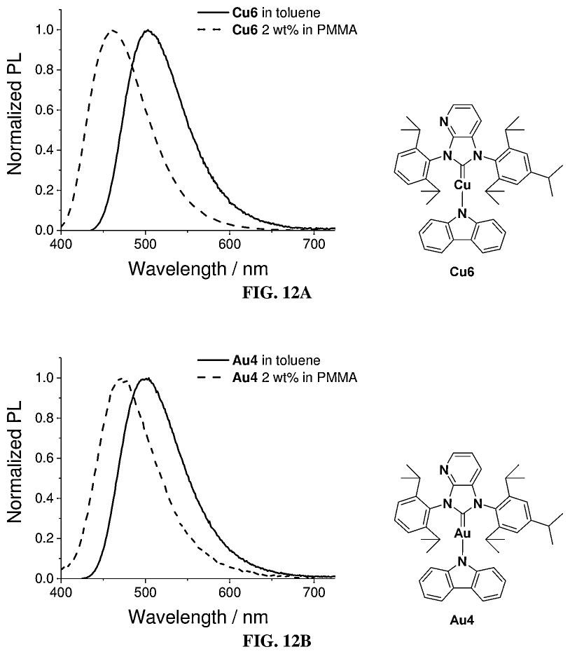

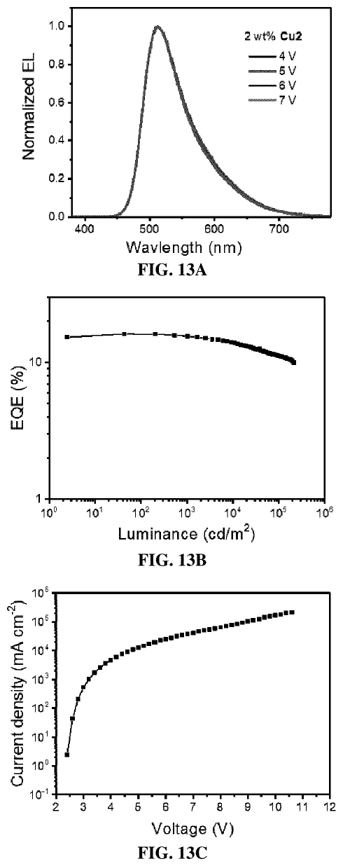

### DETAILED DESCRIPTION OF THE INVENTION

### I. Definitions

“Alkyl” includes straight and branched chain alkyl groups, as well as cycloalkyl groups with alkyl groups having a cyclic structure. Preferred alkyl groups are those containing between one to eighteen carbon atoms and includes methyl, ethyl, propyl, isopropyl, butyl, isobutyl, tert-butyl, and other similar compounds. In addition, the alkyl group may be optionally substituted with one or more substituents selected from hydrogen atom, deuterium atom, formaldehyde, cyano, alkylalkynyl, substituted alkylalkynyl, arylalkynyl, substituted arylalkynyl, heteroarylalkynyl, substituted heteroarylalkynyl, condensed polycyclic, substituted condensed polycyclic, aryl, alkyl, heteroaryl, nitro, trifluoromethane, cyano, arylether, alkylether, heteroarylether, diarylamine, dialkylamine, diheteroarylamine, diarylborane, triarylsilane, trialkylsilane, alkenyl, alkylaryl, cycloalkyl, haloformyl, hydroxyl, aldehyde, carboxamide, amine, amino, alkoxy, azo, benzyl, carbonate ester, carboxylate, carboxyl, ketamine, isocyanate, isocyanide, isothiocyanate, nitrile, nitro, nitroso, phosphine, phosphate, phosphono, pyridyl, sulfonyl, sulfo, sulfinyl, sulfhydryl, halo, aryl, substituted aryl, heteroaryl, substituted heteroaryl, heterocyclic and derivatives thereof. It will be understood by those skilled in the art that the moieties substituted on the hydrocarbon chain can themselves be substituted, if appropriate. For instance, the substituents of a substituted alkyl may include halogen, hydroxy, nitro, thiols, amino, azido, imino, amido, phosphoryl (including phosphonate and phosphinate), sulfonyl (including sulfate, sulfonamido, sulfamoyl and sulfonate), and silyl groups, as well as ethers, alkylthios, carbonyls (including ketones, aldehydes, carboxylates, and esters), haloalkyls, —CN and the like. Cycloalkyls can be substituted in the same manner.

“Substituted,” as used herein, refers to all permissible substituents of the compounds or functional groups described herein. In the broadest sense, the permissible substituents include acyclic and cyclic, branched and unbranched, carbocyclic and heterocyclic, aromatic and nonaromatic substituents of organic compounds. Illustrative substituents include, but are not limited to, halogens, hydroxyl groups, or any other organic groupings containing any number of carbon atoms, preferably 1-14 carbon atoms, and optionally include one or more heteroatoms such as oxygen, sulfur, or nitrogen grouping in linear, branched, or cyclic structural formats. Representative substituents include alkyl, substituted alkyl, alkenyl, substituted alkenyl, alkynyl, substituted alkynyl, phenyl, substituted phenyl, aryl, substituted aryl, heteroaryl, substituted heteroaryl, halo, hydroxyl, alkoxy, substituted alkoxy, phenoxy, substituted phenoxy, aroxy, substituted aroxy, alkylthio, substituted alkylthio, phenylthio, substituted phenylthio, arylthio, substituted arylthio, cyano, isocyano, substituted isocyano, oxo (═O), carbonyl, substituted carbonyl, carboxyl, substituted carboxyl, amino, substituted amino, amido, substituted amido, sulfonyl, substituted sulfonyl, sulfonic acid, phosphoryl, substituted phosphoryl, phosphonyl, substituted phosphonyl, polyaryl, substituted polyaryl, cyclic (such as C₃-C₂₀ cyclic), substituted cyclic (such as substituted C₃-C₂₀ cyclic), heterocyclic, substituted heterocyclic, amino acid, poly(lactic-co-glycolic acid), peptide, polypeptide, deuterium, unsubstituted alkylalkynyl, substituted alkylalkynyl, unsubstituted arylalkynyl, substituted arylalkynyl, unsubstituted heteroarylalkynyl, substituted heteroarylalkynyl, trihaloalkyl (trifluoromethyl), unsubstituted heteroarylether, substituted heteroarylether, unsubstituted diarylamino, substituted diarylamino, unsubstituted dialkylamino, substituted dialkylamino, unsubstituted diheteroarylamino, substituted diheteroarylamino, unsubstituted diarylboraneyl, substituted diarylboraneyl, unsubstituted triarylsilyl, substituted triarylsilyl, unsubstituted trialkylsilyl, substituted trialkylsilyl, azo, carbonate ester, ketamine, nitro, nitroso, phosphino, pyridyl, NRR′, SR, C(O)R, COOR, C(O)NR, SOR, and BRR' groups, wherein and R and R′ are independently selected from hydrogen atom, deuterium atom, formaldehyde, cyano, alkylalkynyl, substituted alkylalkynyl, arylalkynyl, substituted arylalkynyl, heteroarylalkynyl, substituted heteroarylalkynyl, condensed polycyclic, substituted condensed polycyclic, aryl, alkyl, heteroaryl, nitro, trifluoromethane, cyano, arylether, alkylether, heteroarylether, diarylamine, dialkylamine, diheteroarylamine, diarylborane, triarylsilane, trialkylsilane, alkenyl, alkylaryl, cycloalkyl, haloformyl, hydroxyl, aldehyde, carboxamide, amine, amino, alkoxy, azo, benzyl, carbonate ester, carboxylate, carboxyl, ketamine, isocyanate, isocyanide, isothiocyanate, nitrile, nitro, nitroso, phosphine, phosphate, phosphono, pyridyl, sulfonyl, sulfo, sulfinyl, sulfhydryl, halo, aryl, substituted aryl, heteroaryl, substituted heteroaryl, and heterocyclic groups. Such alkyl, substituted alkyl, alkenyl, substituted alkenyl, alkynyl, substituted alkynyl, phenyl, substituted phenyl, aryl, substituted aryl, heteroaryl, substituted heteroaryl, halo, hydroxyl, alkoxy, substituted alkoxy, phenoxy, substituted phenoxy, aroxy, substituted aroxy, alkylthio, substituted alkylthio, phenylthio, substituted phenylthio, arylthio, substituted arylthio, cyano, isocyano, substituted isocyano, carbonyl, substituted carbonyl, carboxyl, substituted carboxyl, amino, substituted amino, amido, substituted amido, sulfonyl, substituted sulfonyl, sulfonic acid, phosphoryl, substituted phosphoryl, phosphonyl, substituted phosphonyl, polyaryl, substituted polyaryl, cyclic (such as C₃-C₂₀ cyclic), substituted cyclic (such as substituted C₃-C₂₀ cyclic), heterocyclic, substituted heterocyclic, amino acid, poly(lactic-co-glycolic acid), peptide, polypeptide, deuterium, substituted alkylalkynyl, substituted alkylalkynyl, unsubstituted arylalkynyl, substituted arylalkynyl, unsubstituted heteroarylalkynyl, substituted heteroarylalkynyl, trihaloalkyl (trifluoromethyl), unsubstituted heteroarylether, substituted heteroarylether, unsubstituted diarylamino, substituted diarylamino, unsubstituted dialkylamino, substituted dialkylamino, unsubstituted diheteroarylamino, substituted diheteroarylamino, unsubstituted diarylboraneyl, substituted diarylboraneyl, unsubstituted triarylsilyl, substituted triarylsilyl, unsubstituted trialkylsilyl, substituted trialkylsilyl, azo, carbonate ester, ketamine, nitro, nitroso, phosphide, phosphino, and pyridyl groups can be further substituted.

The term “heteroatom” as used herein includes, but is not limited to, S, O, N, P, Se, Te, As, Sb, Bi, B, Si, Ge, Sn and Pb. Heteroatoms such as nitrogen may have hydrogen substituents and/or any permissible substituents of organic compounds described herein which satisfy the valences of the heteroatoms. It is understood that “substitution” or “substituted” includes the implicit proviso that such substitution is in accordance with permitted valence of the substituted atom and the substituent, and that the substitution results in a stable compound, i.e. a compound that does not spontaneously undergo transformation such as by rearrangement, cyclization, elimination, etc.

The term “alkenyl” as used herein is a hydrocarbon group having, for example, from 2 to 24 carbon atoms and a structural formula containing at least one carbon-carbon double bond. Asymmetric structures such as (AB)C=C(CD) are intended to include both the E and Z isomers. This may be presumed in structural formulae herein wherein an asymmetric alkene is present, or it may be explicitly indicated by the bond symbol C.

The term “alkynyl group” as used herein is a hydrocarbon group having, for example, 2 to 24 carbon atoms and a structural formula containing at least one carbon-carbon triple bond.

The term “aryl” as used herein is any C₅-C₂₆ carbon-based aromatic group, fused aromatic, fused heterocyclic, or biaromatic ring systems. Broadly defined, “aryl,” as used herein, includes 5-, 6-, 7-, 8-, 9-, 10-, 14-, 18-, and 24-membered single-ring aromatic groups, including, but not limited to, benzene, naphthalene, anthracene, phenanthrene, chrysene, pyrene, corannulene, coronene, etc. “Aryl” further encompasses polycyclic ring systems having two or more cyclic rings in which two or more carbons are common to two adjoining rings (i.e., “fused rings”) wherein at least one of the rings is aromatic, e.g., the other cyclic ring or rings can be cycloalkyls, cycloalkenyls, cycloalkynyls, aryls and/or heterocycles. The aryl group can be substituted with one or more groups including, but not limited to, alkyl, alkynyl, alkenyl, aryl, halide, nitro, amino, ester, ketone, aldehyde, hydroxy, carboxylic acid, or alkoxy.

The term “substituted aryl” refers to an aryl group, wherein one or more hydrogen atoms on one or more aromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfonamido, sulfonyl, heterocyclyl, alkylaryl, haloalkyl (such as CF3, —CH₂-CF₃, —CCl₃), —CN, aryl, heteroaryl, and combinations thereof.

“Heterocycle,” “heterocyclic” and “heterocyclyl” are used interchangeably, and refer to a cyclic radical attached via a ring carbon or nitrogen atom of a monocyclic, bicyclic, or tricyclic ring containing 3-14 ring atoms, and preferably from 5-6 ring atoms, consisting of carbon and one to four heteroatoms each selected from the group consisting of non-peroxide oxygen, sulfur, and N(Y) wherein Y is absent or is H, O, C₁-C₁₀ alkyl, phenyl or benzyl, and optionally containing 1-3 double bonds and optionally substituted with one or more substituents. Heterocyclyl are distinguished from heteroaryl by definition. Examples of heterocycles include, but are not limited to piperazinyl, piperidinyl, piperidonyl, 4-piperidonyl, dihydrofuro[2,3-b]tetrahydrofuran, morpholinyl, piperazinyl, piperidinyl, piperidonyl, 4-piperidonyl, piperonyl, pyranyl, 2H-pyrrolyl, 4H-quinolizinyl, quinuclidinyl, tetrahydrofuranyl, 6H-1,2,5-thiadiazinyl. Heterocyclic groups can optionally be substituted with one or more substituents as defined above for alkyl and aryl.

The term “heteroaryl” refers to C₅-C₂₆-membered aromatic, fused aromatic, biaromatic ring systems, or combinations thereof, in which one or more carbon atoms on one or more aromatic ring structures have been substituted with a heteroatom. Suitable heteroatoms include, but are not limited to, oxygen, sulfur, and nitrogen. Broadly defined, “heteroaryl,” as used herein, includes 5-, 6-, 7-, 8-, 9-, 10-, 14-, 18-, and 24-membered single-ring aromatic groups that may include from one to four heteroatoms, for example, pyrrole, furan, thiophene, imidazole, oxazole, thiazole, triazole, tetrazole, pyrazole, pyridine, pyrazine, pyridazine and pyrimidine, and the like. The heteroaryl group may also be referred to as “aryl heterocycles” or “heteroaromatics.” “Heteroaryl” further encompasses polycyclic ring systems having two or more rings in which two or more carbons are common to two adjoining rings (i.e., “fused rings”) wherein at least one of the rings is heteroaromatic, e.g., the other cyclic ring or rings can be cycloalkyls, cycloalkenyls, cycloalkynyls, aryls, heterocycles, or combinations thereof. Examples of heteroaryl rings include, but are not limited to, benzimidazolyl, benzofuranyl, benzothiofuranyl, benzothiophenyl, benzoxazolyl, benzoxazolinyl, benzthiazolyl, benztriazolyl, benztetrazolyl, benzisoxazolyl, benzisothiazolyl, benzimidazolinyl, carbazolyl, 4aH-carbazolyl, carbolinyl, chromanyl, chromenyl, cinnolinyl, decahydroquinolinyl, 2H,6H-1,5,2-dithiazinyl, furanyl, furazanyl, imidazolidinyl, imidazolinyl, imidazolyl, 1H-indazolyl, indolenyl, indolinyl, indolizinyl, indolyl, 3H-indolyl, isatinoyl, isobenzofuranyl, isochromanyl, isoindazolyl, isoindolinyl, isoindolyl, isoquinolinyl, isothiazolyl, isoxazolyl, methylenedioxyphenyl, naphthyridinyl, octahydroisoquinolinyl, 1,2,3-oxadiazolyl, 1,2,4-oxadiazolyl, 1,2,5-oxadiazolyl, 1,3,4-oxadiazolyl, oxazolidinyl, oxazolyl, oxindolyl, pyrimidinyl, phenanthridinyl, phenanthrolinyl, phenazinyl, phenothiazinyl, phenoxathinyl, phenoxazinyl, phthalazinyl, pteridinyl, purinyl, pyrazinyl, pyrazolidinyl, pyrazolinyl, pyrazolyl, pyridazinyl, pyridooxazole, pyridoimidazole, pyridothiazole, pyridinyl, pyridyl, pyrimidinyl, pyrrolidinyl, pyrrolinyl, pyrrolyl, quinazolinyl, quinolinyl, quinoxalinyl, tetrahydroisoquinolinyl, tetrahydroquinolinyl, tetrazolyl, 1,2,3-thiadiazolyl, 1,2,4-thiadiazolyl, 1,2,5-thiadiazolyl, 1,3,4-thiadiazolyl, thianthrenyl, thiazolyl, thienyl, thienothiazolyl, thienooxazolyl, thienoimidazolyl, thiophenyl and xanthenyl. One or more of the rings can be substituted as defined below for “substituted heteroaryl”.

The term “substituted heteroaryl” refers to a heteroaryl group in which one or more hydrogen atoms on one or more heteroaromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfonamido, sulfonyl, heterocyclyl, alkylaryl, haloalkyl (such as CF3, —CH₂-CF₃, —CCl₃), —CN, aryl, heteroaryl, and combinations thereof.

The term “substituted alkenyl” refers to alkenyl moieties having one or more substituents replacing one or more hydrogen atoms on one or more carbons of the hydrocarbon backbone. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “substituted alkynyl” refers to alkynyl moieties having one or more substituents replacing one or more hydrogen atoms on one or more carbons of the hydrocarbon backbone. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, etc. The term “heterocycloalkyl group” is a cycloalkyl group as defined above where at least one of the carbon atoms of the ring is substituted with a heteroatom such as, but not limited to, nitrogen, oxygen, sulphur, or phosphorus.

The term “aralkyl” as used herein is an aryl group having an alkyl, alkynyl, or alkenyl group as defined above attached to the aromatic group. An example of an aralkyl group is a benzyl group.

“Carbonyl,” as used herein, is art-recognized and includes such moieties as can be represented by the general formula:

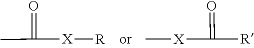

wherein X is a bond, or represents an oxygen or a sulfur, and R represents a hydrogen, a substituted or unsubstituted alkyl, substituted or unsubstituted alkenyl, substituted or unsubstituted alkynyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R″, or a pharmaceutical acceptable salt, R′ represents a hydrogen, substituted or unsubstituted alkyl, substituted or unsubstituted alkenyl, substituted or unsubstituted alkynyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl or —(CH2)ₘR″; R″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. Where X is oxygen and R is defined as above, the moiety is also referred to as a carboxyl group. When X is oxygen and R is hydrogen, the formula represents a ‘carboxylic acid’. Where X is oxygen and R′ is hydrogen, the formula represents a ‘formate’. Where X is oxygen and R or R′ is not hydrogen, the formula represents an “ester”. In general, where the oxygen atom of the above formula is replaced by a sulfur atom, the formula represents a ‘thiocarbonyl’ group. Where X is sulfur and R or R′ is not hydrogen, the formula represents a ‘thioester.’ Where X is sulfur and R is hydrogen, the formula represents a ‘thiocarboxylic acid.’ Where X is sulfur and R′ is hydrogen, the formula represents a ‘thioformate.’ Where X is a bond and R is not hydrogen, the above formula represents a ‘ketone.’ Where X is a bond and R is hydrogen, the above formula represents an ‘aldehyde.’

The term “substituted carbonyl” refers to a carbonyl, as defined above, wherein one or more hydrogen atoms in R, R′ or a group to which the moiety

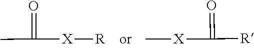

is attached, are independently substituted. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “carboxyl” is as defined above for the formula

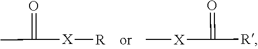

and is defined more specifically by the formula —R^{iv}COOH, wherein R^{iv} is an alkyl, alkenyl, alkynyl, cycloalkyl, heterocyclyl, alkylaryl, arylalkyl, aryl, or heteroaryl. In preferred forms, a straight chain or branched chain alkyl, alkenyl, and alkynyl have 30 or fewer carbon atoms in its backbone (e.g., C₁-C₃₀ for straight chain alkyl, C₃-C₃₀ for branched chain alkyl, C₂-C₃₀ for straight chain alkenyl and alkynyl, C₃-C₃₀ for branched chain alkenyl and alkynyl), preferably 20 or fewer, more preferably 15 or fewer, most preferably 10 or fewer.

Likewise, preferred cycloalkyls, heterocyclyls, aryls and heteroaryls have from 3-10 carbon atoms in their ring structure, and more preferably have 5, 6 or 7 carbons in the ring structure.

The term “substituted carboxyl” refers to a carboxyl, as defined above, wherein one or more hydrogen atoms in R^{iv} are substituted. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “phenoxy” is recognized, and refers to a compound of the formula —ORv wherein Rᵥ is (i.e., —O—C₆H₅). One of skill in the art recognizes that a phenoxy is a species of the aroxy genus.

The term “substituted phenoxy” refers to a phenoxy group, as defined above, having one or more substituents replacing one or more hydrogen atoms on one or more carbons of the phenyl ring. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The terms “aroxy” and “aryloxy,” as used interchangeably herein, are represented by —O-aryl or —O-heteroaryl, wherein aryl and heteroaryl are as defined herein.

The terms “substituted aroxy” and “substituted aryloxy,” as used interchangeably herein, represent −O-aryl or —O-heteroaryl, having one or more substituents replacing one or more hydrogen atoms on one or more ring atoms of the aryl and heteroaryl, as defined herein. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “alkylthio” refers to an alkyl group, as defined above, having a sulfur radical attached thereto. The “alkylthio” moiety is represented by —S-alkyl. Representative alkylthio groups include methylthio, ethylthio, and the like. The term “alkylthio” also encompasses cycloalkyl groups having a sulfur radical attached thereto.

The term “substituted alkylthio” refers to an alkylthio group having one or more substituents replacing one or more hydrogen atoms on one or more carbon atoms of the alkylthio backbone. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “phenylthio” is art recognized, and refers to —S—C₆H₅, i.e., a phenyl group attached to a sulfur atom.

The term “substituted phenylthio” refers to a phenylthio group, as defined above, having one or more substituents replacing a hydrogen on one or more carbons of the phenyl ring. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

“Arylthio” refers to —S-aryl or —S-heteroaryl groups, wherein aryl and heteroaryl as defined herein.

The term “substituted arylthio” represents —S-aryl or —S-heteroaryl, having one or more substituents replacing a hydrogen atom on one or more ring atoms of the aryl and heteroaryl rings as defined herein. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The terms “amide” or “amido” are used interchangeably, refer to both “unsubstituted amido” and “substituted amido” and are represented by the general formula:

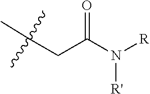

wherein, E is absent, or E is substituted or unsubstituted alkyl, substituted or unsubstituted alkenyl, substituted or unsubstituted alkynyl, substituted or unsubstituted aralkyl, substituted or unsubstituted cycloalkyl, substituted or unsubstituted aryl, substituted or unsubstituted heteroaryl, substituted or unsubstituted heterocyclyl, wherein independently of E, R and R′ each independently represent a hydrogen, substituted or unsubstituted alkyl, substituted or unsubstituted alkenyl, substituted or unsubstituted alkynyl, substituted or unsubstituted carbonyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″, or R and R′ taken together with the N atom to which they are attached complete a heterocycle having from 3 to 14 atoms in the ring structure; R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. In preferred forms, only one of R and R′ can be a carbonyl, e.g., R and R′ together with the nitrogen do not form an imide. In preferred forms, R and R′ each independently represent a hydrogen atom, substituted or unsubstituted alkyl, a substituted or unsubstituted alkenyl, or —(CH₂)ₘ—R′″. When E is oxygen, a carbamate is formed. The carbamate cannot be attached to another chemical species, such as to form an oxygen-oxygen bond, or other unstable bonds, as understood by one of ordinary skill in the art.

The term “sulfonyl” is represented by the formula

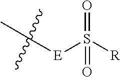

wherein E is absent, or E is alkyl, alkenyl, alkynyl, aralkyl, alkylaryl, cycloalkyl, aryl, heteroaryl, heterocyclyl, wherein independently of E, R represents a hydrogen, substituted or unsubstituted alkyl, substituted or unsubstituted alkenyl, substituted or unsubstituted alkynyl, substituted or unsubstituted amine, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″, or E and R taken together with the S atom to which they are attached complete a heterocycle having from 3 to 14 atoms in the ring structure; R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. In preferred forms, only one of E and R can be substituted or unsubstituted amine, to form a “sulfonamide” or “sulfonamido.” The substituted or unsubstituted amine is as defined above.

The term “substituted sulfonyl” represents a sulfonyl in which E, R, or both, are independently substituted. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “sulfonic acid” refers to a sulfonyl, as defined above, wherein R is hydroxyl, and E is absent, or E is substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl.

The term “sulfate” refers to a sulfonyl, as defined above, wherein E is absent, oxygen, alkoxy, aroxy, substituted alkoxy or substituted aroxy, as defined above, and R is independently hydroxyl, alkoxy, aroxy, substituted alkoxy or substituted aroxy, as defined above. When E is oxygen, the sulfate cannot be attached to another chemical species, such as to form an oxygen-oxygen bond, or other unstable bonds, as understood by one of ordinary skill in the art.

The term “sulfonate” refers to a sulfonyl, as defined above, wherein E is oxygen, alkoxy, aroxy, substituted alkoxy or substituted aroxy, as defined above, and R is independently hydrogen, substituted or unsubstituted alkyl, substituted or unsubstituted alkenyl, substituted or unsubstituted alkynyl, substituted or unsubstituted amine, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″, R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. When E is oxygen, sulfonate cannot be attached to another chemical species, such as to form an oxygen-oxygen bond, or other unstable bonds, as understood by one of ordinary skill in the art.

The term “sulfamoyl” refers to a sulfonamide or sulfonamide represented by the formula

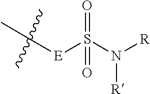

wherein E is absent, or E is substituted or unsubstituted alkyl, substituted or unsubstituted alkenyl, substituted or unsubstituted alkynyl, substituted or unsubstituted aralkyl, substituted or unsubstituted alkylaryl, substituted or unsubstituted cycloalkyl, substituted or unsubstituted aryl, substituted or unsubstituted heteroaryl, substituted or unsubstituted heterocyclyl, wherein independently of E, R and R′ each independently represent a hydrogen, substituted or unsubstituted alkyl, substituted or unsubstituted alkenyl, substituted or unsubstituted alkynyl, substituted or unsubstituted carbonyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″, or R and R′ taken together with the N atom to which they are attached complete a heterocycle having from 3 to 14 atoms in the ring structure; R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. In preferred forms, only one of R and R′ can be a carbonyl, e.g., R and R′ together with the nitrogen do not form an imide.

The term “phosphonyl” is represented by the formula

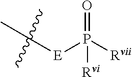

wherein E is absent, or E is substituted or unsubstituted alkyl, substituted or unsubstituted alkenyl, substituted or unsubstituted alkynyl, substituted or unsubstituted aralkyl, substituted or unsubstituted alkylaryl, substituted or unsubstituted cycloalkyl, substituted or unsubstituted aryl, substituted or unsubstituted heteroaryl, substituted or unsubstituted heterocyclyl, wherein, independently of E, Rv^{iv} and R^{vii} are independently hydrogen, substituted or unsubstituted alkyl, substituted or unsubstituted alkenyl, substituted or unsubstituted alkynyl, substituted or unsubstituted carbonyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″, or R and R′ taken together with the P atom to which they are attached complete a heterocycle having from 3 to 14 atoms in the ring structure; R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8.

The term “substituted phosphonyl” represents a phosphonyl in which E, R^{vi} and R^{vii} are independently substituted. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “phosphoryl” defines a phosphonyl in which E is absent, oxygen, alkoxy, aroxy, substituted alkoxy or substituted aroxy, as defined above, and independently of E, R^{vi} and R^{vii} are independently hydroxyl, alkoxy, aroxy, substituted alkoxy or substituted aroxy, as defined above. When E is oxygen, the phosphoryl cannot be attached to another chemical species, such as to form an oxygen-oxygen bond, or other unstable bonds, as understood by one of ordinary skill in the art. When E, R^{vi} and R^{vii} are substituted, the substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “polyaryl” refers to a chemical moiety that includes two or more aryls, heteroaryls, and combinations thereof. The aryls, heteroaryls, and combinations thereof, are fused, or linked via a single bond, ether, ester, carbonyl, amide, sulfonyl, sulfonamide, alkyl, azo, and combinations thereof. When two or more heteroaryls are involved, the chemical moiety can be referred to as a “polyheteroaryl.”

The term “substituted polyaryl” refers to a polyaryl in which one or more of the aryls, heteroaryls are substituted, with one or more substituents including, but not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof. When two or more heteroaryls are involved, the chemical moiety can be referred to as a “substituted polyheteroaryl.”

The term “cyclic” refers to a substituted or unsubstituted cycloalkyl, substituted or unsubstituted cycloalkenyl, substituted or unsubstituted cycloalkynyl, substituted or unsubstituted heterocyclyl that, preferably, have from 3 to 20 carbon atoms, as geometric constraints permit. The cyclic structures are formed from single or fused ring systems. The substituted cycloalkyls, cycloalkenyls, cycloalkynyls and heterocyclyls are substituted as defined above for the alkyls, alkenyls, alkynyls and heterocyclyls, respectively.

### II. Compositions

Described are two-coordinated d10 metal carbene complexes containing an imidazopyrazine ligand (e.g., pyrazine-fused N-heterocyclic carbene (NHC) ligand), an imidazopyridine ligand (e.g. pyridine-fused NHC), or a pyrrolopyrazine (e.g. pyrazine-fused NHC) ligand. The radiative properties of the compounds can be controlled by TADF. Preferably, the d10 metal carbene complexes contain a d10 metal in the +1-oxidation state (such as Cu(I), Ag(I), or Au(I)), a pyrazine-fused NHC ligand, and a carbazole ligand. A preferred pyrazine-fused NHC ligand or pyridine-fused N-heterocyclic carbene ligand contains a 2,6-diisopropylphenyl group covalently bonded to the nitrogen atoms of the imidazole moiety of the pyrazine-fused NHC ligand. The described compounds (i) are easy to produce in large scale, (ii) can be cheaper to produce because of the earth-abundant metal (copper), (iii) show tunable color emission properties, such as from blue-green to orange-red, (iv) are sublimable and solution-processable for OLED fabrication, (v) show improved OLED brightness and efficiency compared to existing emitters, and/or (vi) show improved device stability compared to reported d10 Cu/Ag/Au emitters.

The disclosed compounds have a structure:

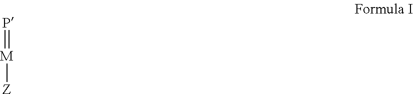

wherein:

the compound has an overall neutral, negative, or positive charge,

M is copper, silver, or gold with an oxidation state of 0, +1, +2, or +3, preferably +1,

P′ has the structure:

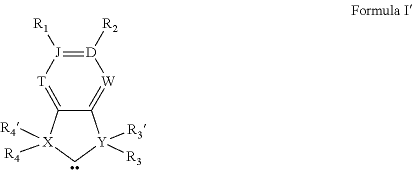

D is carbon,

T, J, and W are independently carbon or nitrogen, wherein at least one of T, J, and W is nitrogen, wherein when T is carbon, J is nitrogen, or when T is nitrogen, J is carbon, and T, J, and W are bonded to one or no hydrogen atom according to valency,

X and Y are independently carbon or nitrogen, wherein at least one of X and Y is nitrogen, and X and Y are bonded to one or no hydrogen atom according to valency,

R₁ and R₂ are independently hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, or R₁, J, D, and R₂ together form an unsubstituted aryl, substituted aryl, unsubstituted heteroaryl, or substituted heteroaryl,

R₃ and R₄ are independently hydrogen, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,

R₃′ and R₄′ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, and

Z is substituted heteroaryl, unsubstituted heteroaryl, substituted polyheteroaryl, unsubstituted polyheteroaryl, substituted polyheterocyclyl, unsubstituted polyheterocyclyl, substituted heterocyclyl, or unsubstituted heterocyclyl, or —NRₐR_{b}, wherein Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl,

wherein (i) R₃ and R₄ are not both 3,5 dialkyl substituted aryl, (ii) R₃ and R₄ are not both 3,5 dialkyl substituted phenyl, (iii) R₃ and R₄ are not both 3,5 dimethylphenyl, (iv) R₃ and R₄ are not both 3,5 dimethylphenyl when M is Cu or Au, or (v) the compound is not

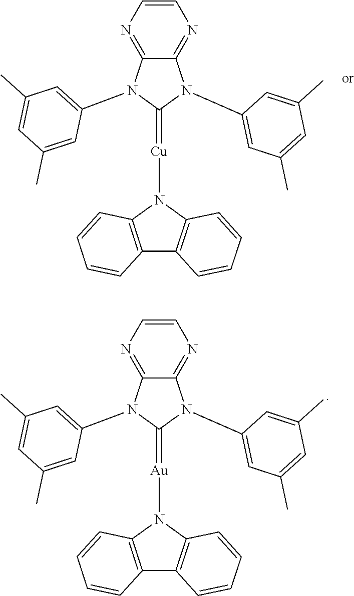

In some forms, the compound is as described above for Formula I, except that the compound has a structure:

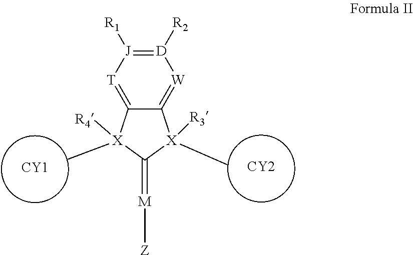

wherein CY1 and CY2 are independently substituted aryl, unsubstituted aryl, substituted polyaryl, unsubstituted polyaryl, substituted heteroaryl, unsubstituted heteroaryl, substituted polyheteroaryl, unsubstituted polyheteroaryl, substituted C₃-C₂₀ cycloalkyl, unsubstituted C₃-C₂₀ cycloalkyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl. In some forms, CY1 and CY2 are independently substituted aryl, unsubstituted aryl, substituted polyaryl, or unsubstituted polyaryl. In some forms, CY1 and CY2 are substituted aryl.

In some forms, the compound is a described above for Formula I or II, except that R₃′ and R₄′ are absent.

In some forms, the compound is as described above for Formula I or II, except that the compound has a structure:

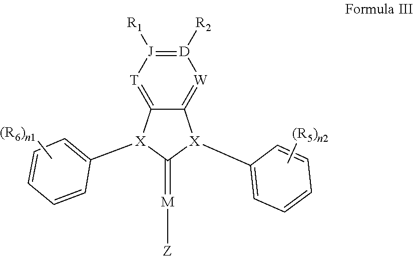

wherein:

R₅ and R₆ are independently substituted alkyl or unsubstituted alkyl, and

n1 and n2 are independently integers between 0 and 5; between 1 and 5; between 2 and 5, such as 2; or between 3 and 5, such as 3.

In some forms, the compound is as described above for any of Formula I-III, except that the compound has a structure:

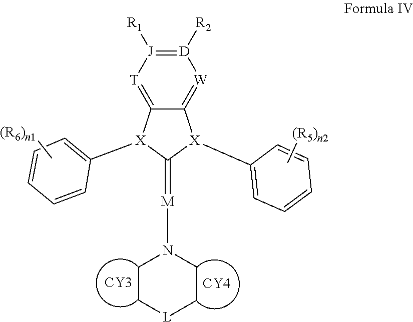

wherein:

n1 and n2 are independently integers between 1 and 5, between 2 and 5, or between 3 and 5,

L is absent, a single bond, substituted alkyl, —(CH₂)ₙₓ—, oxygen, sulfur, or NRx, wherein nx is an integer between 1 and 3 (such as 1, 2, or 3), and Rx is unsubstituted alkyl, substituted alkyl, unsubstituted aryl, or substituted aryl, and

CY3 and CY4 are independently unsubstituted aryl, substituted aryl, unsubstituted polyaryl, substituted polyaryl, unsubstituted heteroaryl, substituted heteroaryl, unsubstituted polyheteroaryl, substituted polyheteroaryl, unsubstituted C₃-C₂₀ cycloalkyl, substituted C₃-C₂₀ cycloalkyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, or a fused combination thereof.

In some forms, the compound is as described above for any of Formula I-IV, except that the compound has a structure:

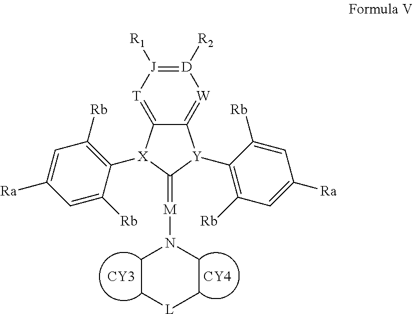

wherein:

each Ra is independently hydrogen, unsubstituted alkyl, or substituted alkyl,

each Rb is independently unsubstituted alkyl, or substituted alkyl, L is absent, a single bond, substituted alkyl, —(CH₂)ₙₓ—, oxygen, sulfur, or NRx, wherein nx is an integer between 1 and 3 (such as 1, 2, or 3), and Rx is unsubstituted alkyl, substituted alkyl, unsubstituted aryl, or substituted aryl, and optionally wherein at least one of X and Y is nitrogen. In some forms, X and Y are nitrogen.

In some forms, the compound is as described above for any of Formula I-V, except that:

(i) T is nitrogen, J is carbon, and W is carbon,

(ii) T is nitrogen, J is carbon, and W is nitrogen,

(iii) T is carbon, J is nitrogen, and W is carbon, or

(iv) T is carbon, J is nitrogen, and W is nitrogen.

In some forms, the compound is as described above for Formula V, except that Ra is hydrogen, unsubstituted alkyl, or substituted alkyl, and Rb is unsubstituted alkyl or substituted alkyl.

In some forms, the compound is as described above for any of Formula I-V, except that P′ is selected from:

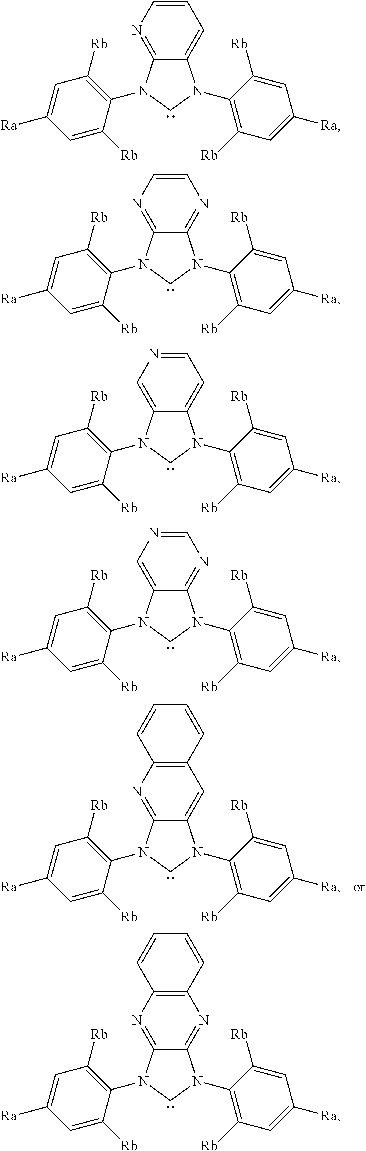

wherein:

Ra is hydrogen, unsubstituted alkyl, or substituted alkyl, and Rb is unsubstituted alkyl or substituted alkyl.

In some forms, the compound is as described above for any of Formula I-V, wherein when specified Ra is hydrogen, methyl, iso-propyl, or —CH(C₂H₅)₂, and Rb is methyl, iso-propyl, or —CH(C₂H₅)₂.

In some forms, the compound is as described above for Formula IV or V, except that CY3 and CY4 are independently unsubstituted aryl, substituted aryl, unsubstituted polyaryl, substituted polyaryl, unsubstituted heteroaryl, unsubstituted heteroaryl, or substituted C₃-C₂₀ cycloalkenyl, unsubstituted C₃-C₂₀ cycloalkenyl, or a fused combination thereof. In some forms, CY3 and CY4 are independently unsubstituted aryl, substituted aryl, unsubstituted heteroaryl, unsubstituted heteroaryl, substituted C₃-C₂₀ cycloalkenyl, unsubstituted C₃-C₂₀ cycloalkenyl, or a fused combination thereof.

In some forms, the compound is as described above for any of Formula I-V, except that Z has a structure:

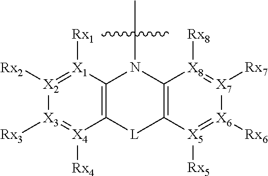

wherein:

X₁, X₂, X₃, X₄, X₅, X₆, X₇, and X₈ are independently carbon or nitrogen,

Rx₁, Rx₂, Rx₃, Rx₄, Rx₅, Rx₆, Rx₇, and Rx₈ are independently hydrogen, halogen, cyano, unsubstituted alkyl, substituted alkyl, unsubstituted alkoxy, substituted alkoxy, unsubstituted aryl, substituted aryl, unsubstituted heteroaryl, or substituted heteroaryl, wherein each Rx₁, Rx₂, Rx₃, Rx₄, Rx₅, Rx₆, Rx₇, or Rx₈ is absent, when the corresponding X₁, X₂, X₃, X₄, X₅, X₆, X₇, or X₈ is nitrogen, or Rx₄ is a bond connected to a substituent on L, or adjacent Rxn groups together with the atoms in the ring to which they are bonded, together independently form five- or six-membered substituted aryl, unsubstituted aryl, substituted heteroaryl, unsubstituted heteroaryl, substituted C₃-C₂₀ cycloalkenyl, unsubstituted C₃-C₂₀ cycloalkenyl, or a fused combination thereof, wherein the n in the adjacent Rxn groups are sequential pairs of integers from 1 to 4, or 5 to 8, and

L is absent, a single bond, substituted alkyl, —(CH₂)ₙₓ—, oxygen, sulfur, or NRx, wherein nx is an integer between 1 and 3 (such as 1, 2, or 3), and Rx is unsubstituted alkyl, substituted alkyl, unsubstituted aryl, or substituted aryl.

In some forms, the compound is as described above for any of Formula I-V, except that Z has a structure:

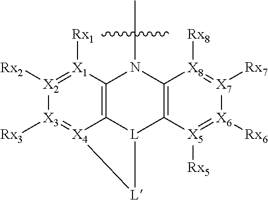

wherein:

L′ is substituted aryl, unsubstituted aryl, substituted heteroaryl, or unsubstituted heteroaryl, preferably substituted aryl or unsubstituted aryl, preferably substituted phenyl or unsubstituted phenyl.

In some forms, the compound is as described above for any of Formula I-V, except that Z has a structure:

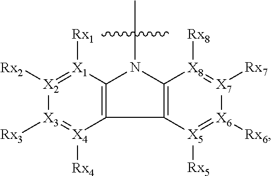

wherein:

X₁, X₂,X₃, X₄, X₅, X₆, X₇, and X₈ are independently carbon or nitrogen, and

Rx₁, Rx₂, Rx₃, Rx₄, Rx₅, Rx₆, Rx₇, and Rx₈ are independently hydrogen, halogen, cyano, unsubstituted alkyl, substituted alkyl, unsubstituted alkoxy, substituted alkoxy, unsubstituted aryl, substituted aryl, unsubstituted heteroaryl, or substituted heteroaryl, wherein each Rx₁, Rx₂,Rx₃, Rx₄, Rx₅, Rx₆, Rx₇, or Rx₈ is absent, when the corresponding X₁, X₂, X₃, X₄, X₅, X₆, X₇, or X₈ is nitrogen, or adjacent Rxn groups together with the atoms in the ring to which they are bonded, together independently form five- or six-membered substituted aryl, unsubstituted aryl, substituted heteroaryl, unsubstituted heteroaryl, substituted C₃-C₂₀ cycloalkenyl, unsubstituted C₃-C₂₀ cycloalkenyl, or a fused combination thereof, wherein the n in the adjacent Rxn groups are sequential pairs of integers from 1 to 4, or 5 to 8.

In some forms, the compound is as described above for any of Formula I to V, wherein when specified Rx₁, Rx₂, Rx₃, Rx₄, Rx₅, Rx₆, Rx₇, and Rx₈ are independently hydrogen, halogen, methyl, cyano, trifluoromethyl, tert-butyl, methoxy, phenyl, or pyridyl.

In some forms, the compound is as described above for any of Formula I-V, except that the compound has a structure:

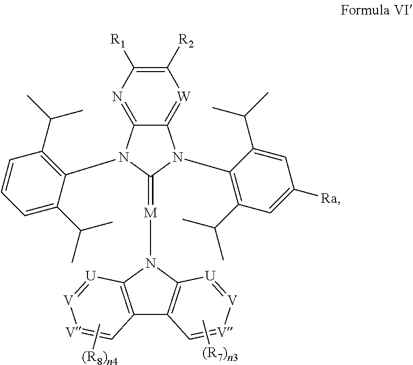

preferably

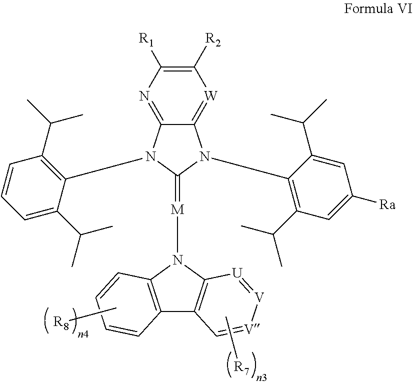

wherein:

V″ is carbon,

U is carbon and V is nitrogen, or U is nitrogen and V is carbon, wherein U, V, and V″ are bonded to one or no hydrogen atom according to valency,

Ra is hydrogen, unsubstituted alkyl, or substituted alkyl,

R₇ and R₈ are independently absent, hydrogen, substituted alkyl, unsubstituted alkyl, cyano, halogen, hydroxyl, thiol, nitro-, unsubstituted alkoxy, substituted alkoxy, unsubstituted aroxy, substituted aroxy, substituted aryl, unsubstituted aryl, or adjacent R₇ groups or adjacent R₈ groups together with the atoms in the ring to which they are bonded, together independently form five- or six-membered substituted aryl, unsubstituted aryl, substituted heteroaryl, unsubstituted heteroaryl, substituted C₃-C₂₀ cycloalkenyl, unsubstituted C₃-C₂₀ cycloalkenyl, or a fused combination thereof, and

n3 and n4 are independently integers between 0 and 5, such as 0, 1, 2, 3, 4, 5.

In some forms, the compound is as described above for Formula VI, except that the compound has a structure:

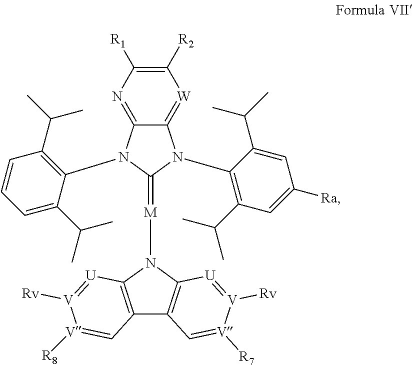

preferably

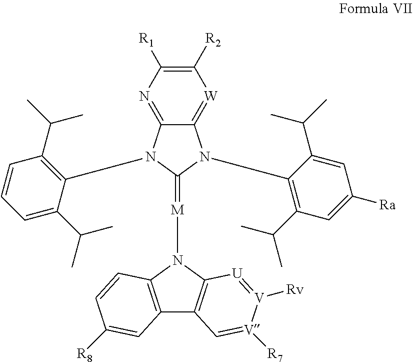

wherein:

Rv is absent, hydrogen, substituted alkyl, or unsubstituted alkyl, and

R₇ and R₈ are independently hydrogen, substituted alkyl, unsubstituted alkyl, unsubstituted aryl, halogen, cyano, or Rv and R₇ together with the atoms in the rings to which they are bonded form five- or six-membered substituted aryl, unsubstituted aryl, substituted heteroaryl, unsubstituted heteroaryl, substituted C₃-C₂₀ cycloalkenyl, unsubstituted C₃-C₂₀ cycloalkenyl, or a fused combination thereof.

In some forms, the compound is as described above for Formula VI or VII, except that:

Rv is absent or hydrogen, R₇ and R₈ are independently hydrogen, iso-propyl, tert-butyl, phenyl, fluorine, or cyano, or

Rv and R₇ together form

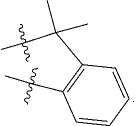 [SMILES: *c1ccccc1C(*)(C)C]

In some forms, the compound is as described above for any of Formula I-VII, except that R₁ and R₂ are independently hydrogen, substituted alkyl, unsubstituted alkyl, substituted alkenyl, unsubstituted alkenyl, substituted alkynyl, unsubstituted alkynyl, substituted aryl, unsubstituted aryl, or R₁ and R₂ with the atoms in the ring to which they are bonded together form unsubstituted aryl, substituted aryl, unsubstituted heteroaryl, or substituted heteroaryl. In some forms, R₁ and R₂ are hydrogen. In some forms, R₁ and R₂ together form the structure:

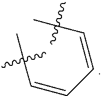 [SMILES: */C=C\C=C/*]

In some forms, the compound is as described above for any of Formula I-VII, except that the compound has a structure:

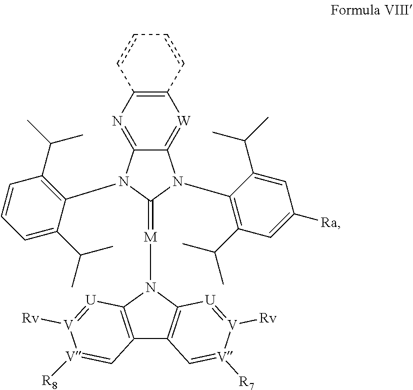

preferably

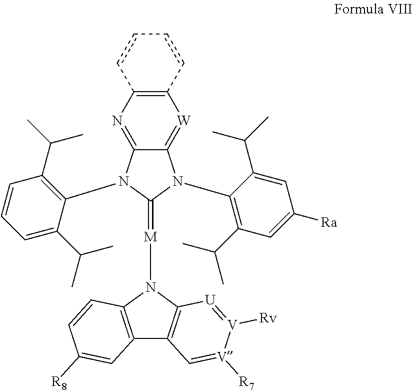

wherein:

(i) M=Cu(I); W=N; Ra=H; U=CH; V=V″=carbon; Rv=H; R₇=R₈=H;

(ii) M=Cu(I); W=N; Ra=H; U=CH; V=V″=carbon; Rv=H; R₇=H; R₈=CN;

(iii) M=Cu(I); W=N; Ra=H; U=CH; V=V″=carbon; Rv=H; R₇=R₈=tert-butyl;

(iv) M=Cu(I); W=N; Ra=H; U=CH; V=V″=carbon; Rv=H; R₇=R₈=phenyl;

(v) M=Cu(I); W=N; Ra=H; U=CH; V=N; V″=carbon; Rv=absent; R₇=R₈=H;

(vi) M=Cu(I); W=U=CH; V=V″=carbon; Rv=H; Ra=iso-propyl; R₇=R₈=H;

(vii) M=Cu(I); W=N; Ra=H; U=CH; V=V″=carbon; R₈=H; Rv and R₇ together form

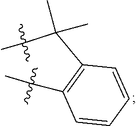 [SMILES: *c1ccccc1C(*)(C)C]

(viii) M=Cu(I); W=U=CH; Ra=iso-propyl; V=V″=carbon; R₈=H; Rv and R₇ together form

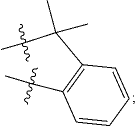 [SMILES: *c1ccccc1C(*)(C)C]

(ix) M=Cu(I); W=N; Ra=H; U=CH; V=V″=carbon; Rv=H; R₇=R₈=H;

(x) M=Cu(I); W=N; Ra=H; U=CH; V=V″=carbon; Rv=H; R₇=H; R₈=F;

(xi) M=Cu(I); W=N; Ra=H; U=CH; V=V″=carbon; Rv=H; R₇=R₈=methyl;

(xii) M=Au(I); W=N; Ra=H; U=CH; V=carbon; Rv=H; V″=carbon; R₇=R₈=H;

(xiii) M=Au(I); W=N; Ra=H; U=CH; V=carbon; Rv=H; V″=carbon; R₇=H, R₈=CN;

(xiv) M=Au(I); W=N; Ra=H; U=N; V=carbon; Rv=H; V″=carbon; R₇=R₈=H;

(xv) M=Au(I); W=U=CH; V=carbon; Rv=H; ; Ra=iso-propyl; V″=carbon; R₇=R₈=H;

(xvi) M=Au(I); W=N; Ra=H; U=CH; V=N; Rv=absent; V″=carbon; R₇=R₈=H;

(xvii) M=Au(I); W=N; Ra=H; U=CH; V=V″=carbon; Rv=H; R₇=R₈=CN;

(xviii) M=Au(I); W=N; Ra=hydrogen; U=CH; V=V″=carbon; R₈=H; Rv and R₇ together form

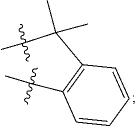 [SMILES: *c1ccccc1C(*)(C)C]

(xix) M=Au(I); W=U=CH; Ra=iso-propyl; V=V″=carbon; Rv=H; R₇=R₈=tert-butyl;

(xx) M=Au(I); W=U=CH; Ra=iso-propyl; V=V″=carbon; Rv=H; R₇=H; R₈=F;

(xxi) M=Au(I); W=N; U=CH; Ra=H; V=V″=carbon; Rv=H; R₇=R₈=H;

(xxii) M=Au(I); W=N; U=CH; Ra=H; V=V″=carbon; Rv=H; R₇=R₈=tert-butyl;

(xxiii) M=Ag(I); W=N; U=CH; Ra=H; V=V″=carbon; Rv=H; R₇=R₈=H;

for (i), (ii), (iii), (iv), (v), (vi), (vii), (viii), (xii), (xiii), (xiv), (xv), (xvi), (xvii), (xviii), (xix), (xx), and (xxiii), the dashed lines denote the absence of bonds, and

for (ix), (x), (xi), (xxi), and (xxii), the dashed lines denote the presence of bonds.

In some forms, the compound has a structure selected from:

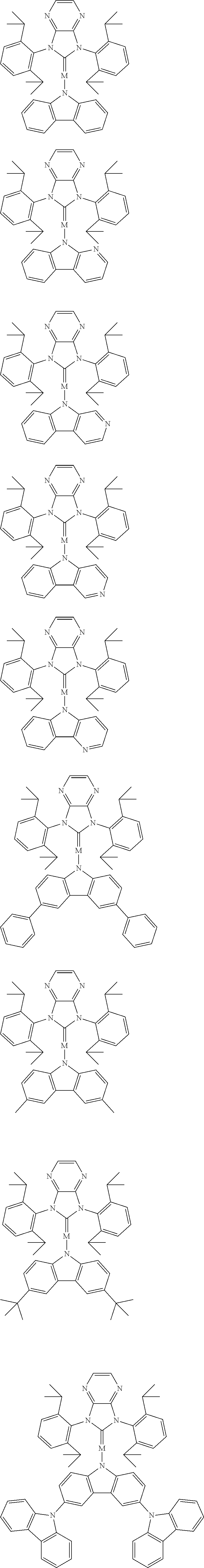

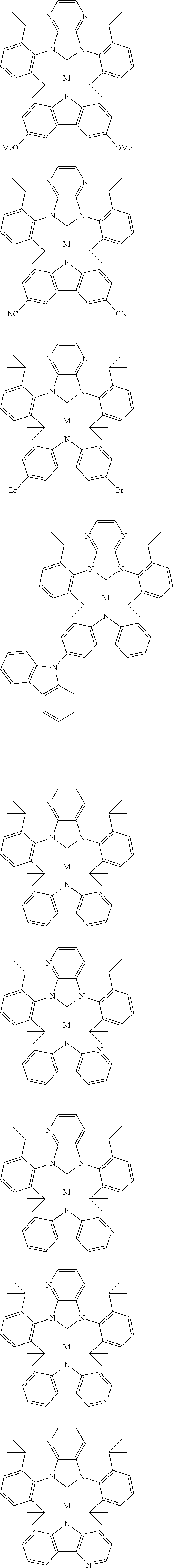

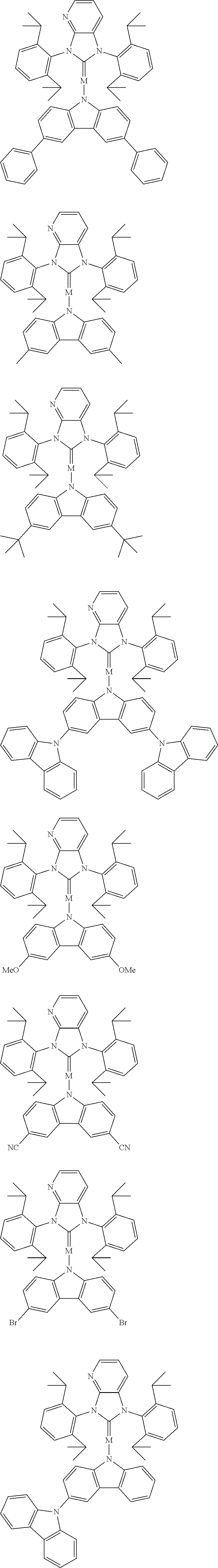

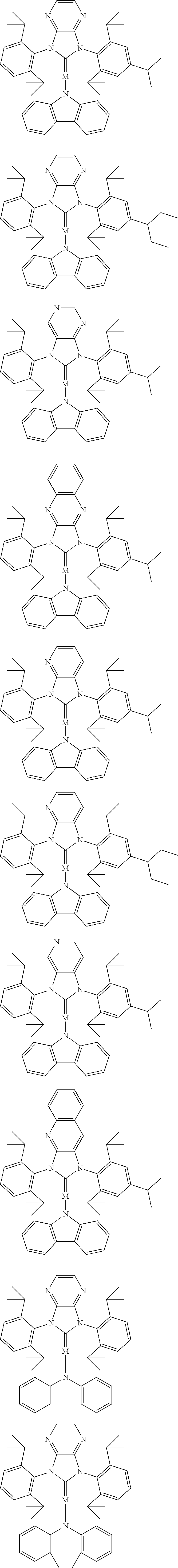

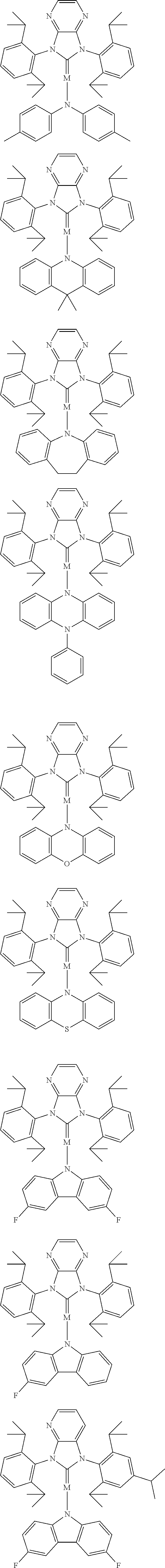

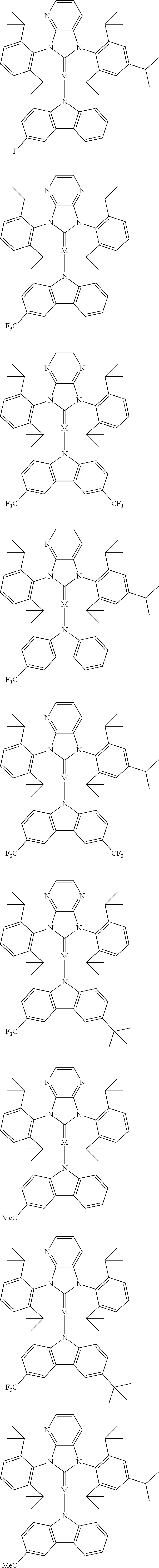

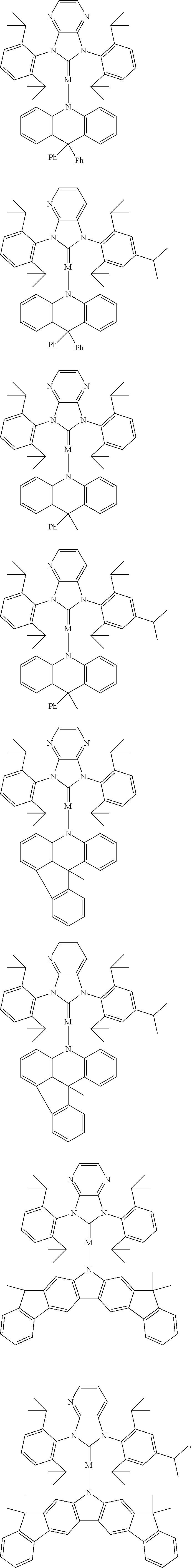

wherein M=Cu(I), Au(I), or Ag(I).

In some forms, the compound is as described above for any of Formula I-VII, except that substituted means substituted with one or more substituents selected from: halogen, hydroxyl, thiol, nitro-, unsubstituted alkyl, unsubstituted alkenyl, unsubstituted alkynyl, unsubstituted aryl, unsubstituted heteroaryl, unsubstituted arylalkyl, unsubstituted alkoxy, unsubstituted aroxy, unsubstituted alkylthio, unsubstituted arylthio, cyano, isocyano, unsubstituted carbonyl, unsubstituted carboxyl, oxo (═O), unsubstituted amino, unsubstituted amido, unsubstituted sulfonyl, unsubstituted sulfonic acid, unsubstituted phosphoryl, unsubstituted phosphonyl, unsubstituted polyaryl, or unsubstituted C₃-C₂₀ cycloalkyl, and unsubstituted heterocyclyl.

In some forms, the compounds have a photoluminescence quantum yield (PLQY) between 0.50 and 0.95, such as between 0.58 and 0.92 in thin films. In some forms, the compounds have an emission decay lifetime (τ) between 0.20 μs and 0.45 μs, such as between 0.23 μs and 42 μs, in thin films. In some forms, the compounds have a PLQY between 0.50 and 0.95, such as between 0.58 and 0.92, and an emission decay lifetime (τ) between 0.20 μs and 0.45 μs, such as between 0.23 μs and 42 μs, in thin films. In some forms, the compounds have a radiative rate constant between 10-35×10⁵ s⁻¹, such as between 15-21×10⁵ s⁻¹, or ˜29×10⁵ s⁻¹, in thin films. The films can also contain organic compounds. Exemplary organic compounds include, but are not limited to, host materials such as 1,3-bis(N-carbazolyl)benzene (mCP), 2,8-bis(diphenylphosphoryl)dibenzo[b,d]furan (PPF), bis[2-(diphenylphosphino)phenyl]ether oxide (DPEPO), 3,3′-di(9H-carbazol-9-yl)-1,1′-biphenyl (mCBP), poly(methyl methacrylate) (PMMA), polystyrene (PS), or a combination thereof.

In some forms, the compounds act as sensitizers to transfer energy (such as exciton energy or photon energy) to a pure organic emitter. In some forms, the compounds act as sensitizers to transfer energy (such as exciton energy or photon energy) to a pure organic emitter that exhibits thermally activated delayed fluorescence. In some forms, the compounds act as sensitizers to transfer energy (such as exciton energy or photon energy) to a pure organic emitter that is boron-based. The phrase “pure organic emitter” as used throughout this application refers to a light-emitting organic molecule formed exclusively from main group elements of the periodic table, such that the light-emitting organic molecule does not contain a covalent bond or a dative bond to a main group metal. Notably, the phrase is not intended to define or specify a level of purity of a composition containing the light-emitting organic molecule.

Every compound within the above definition is intended to be and should be considered to be specifically disclosed herein. Further, every subgroup that can be identified within the above definition is intended to be and should be considered to be specifically disclosed herein. As a result, it is specifically contemplated that any compound or subgroup of compounds can be either specifically included for or excluded from use or included in or excluded from a list of compounds. For example, any one or more of the compounds described herein, with a structure depicted herein, or referred to in the Tables or the Examples herein can be specifically included, excluded, or combined in any combination, in a set or subgroup of such compounds. Such specific sets, subgroups, inclusions, and exclusions can be applied to any aspect of the compositions and methods described here. For example, a set of compounds that specifically excludes one or more particular compounds can be used or applied in the context of compounds per se (for example, a list or set of compounds), compositions including the compound (including, for example, pharmaceutical compositions), any one or more of the disclosed methods, or combinations of these. Different sets and subgroups of compounds with such specific inclusions and exclusions can be used or applied in the context of compounds per se, compositions including one or more of the compounds, or any of the disclosed methods. All of these different sets and subgroups of compounds—and the different sets of compounds, compositions, and methods using or applying the compounds—are specifically and individual contemplated and should be considered as specifically and individually described.

### III. Methods of Making and Reagents Therefor

A. Compounds

The two-coordinated d10 metal carbene complexes and their ligands described herein can be synthesized using methods known in the art of organic chemical synthesis. The target compound can be synthesized by reacting the corresponding pyrazine-fused NHC ligand a corresponding pyrazine-fused NHC ligand precursor, or a combination thereof, with a d10 compound in a solvent or solution to form a complex precursor. Exemplary solvents include organic solvents, such as tetrahydrofuran and dichloromethane. The complex precursor can be reacted with a second ligand (e.g., a carbazole) over a suitable time to form the d10 metal carbene complex. Specific d10 metal carbene complexes, such as those containing Cu(I), Ag(I), and Au(I) are disclosed in the Examples. B. Organic light-emitting devices

Also described are methods of making organic light-emitting devices, such as OLEDs, containing one or more d10 metal carbene complexes described above for any of Formula I-VIII. A preferred method of making the OLEDs involves vacuum deposition or solution processing techniques such as spin-coating and ink printing (such as, ink-jet printing or roll-to-roll printing). A method of making an OLED including a d10 metal carbene complex described herein is disclosed in the Examples.

### IV. Methods of Using

Preferably, the d10 metal carbene complexes described herein are photo-stable, and are emissive at room temperatures, low temperatures, or a combination thereof. Accordingly, the compounds described herein can be incorporated into OLEDs, an organic photovoltaic cell (OPV), and organic field-effect transistor (OFET), or a light-emitting electrochemical cell (LEEC), and used in a stationary visual display unit, a mobile visual display unit, or an illumination device. Examples of units or devices include commercial applications such as smart phones, televisions, monitors, digital cameras, tablet computers, keyboards, clothes ornaments, garment accessories, wearable devices, medical monitoring devices, wall papers, advertisement panels, laptops, household appliances, office appliances, and lighting fixtures. Preferably, these units or devices are those that usually operate at room temperatures.

In some forms, the compounds can be included in a light-emitting layer. In some forms, one or more of the compounds can be included in a light-emitting layer containing a pure organic emitter, such that the one or more compounds act as a sensitizer to transfer energy (such as exciton energy or photon energy) to the pure organic emitter. In some forms, the one or more compounds have a higher-lying singlet state than the pure organic emitter. In some forms, the pure organic emitter exhibits thermally activated delayed fluorescence. In some forms, the pure organic emitter is boron-based. In some forms, the light-emitting layer can be included in an OLED.

The disclosed compounds, methods of using, and methods of making can be further understood through the following enumerated paragraphs or embodiments.

1. A compound having a structure:

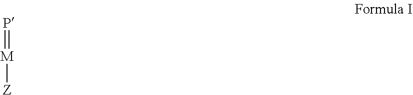

wherein:

the compound has an overall neutral, negative, or positive charge,

M is copper, silver, or gold with an oxidation state of 0, +1, +2, or +3, preferably +1,

P′ has the structure:

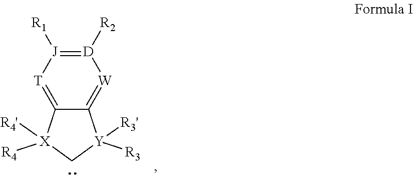

D is carbon,

T, J, and W are independently carbon or nitrogen, wherein at least one of T, J, and W is nitrogen, wherein when T is carbon, J is nitrogen, or when T is nitrogen, J is carbon, and T, J, and W are bonded to one or no hydrogen atom according to valency,

X and Y are independently carbon or nitrogen, wherein at least one of X and Y is nitrogen, and X and Y are bonded to one or no hydrogen atom according to valency,

R₁ and R₂ are independently hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, or R₁, J, D, and R₂ together form an unsubstituted aryl, substituted aryl, unsubstituted heteroaryl, or substituted heteroaryl,

R₃ and R₄ are independently hydrogen, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, R₃′ and R₄′ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C2⁻C20 heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, and

Z is substituted heteroaryl, unsubstituted heteroaryl, substituted polyheteroaryl, unsubstituted polyheteroaryl, substituted polyheterocyclyl, unsubstituted polyheterocyclyl, substituted heterocyclyl, or unsubstituted heterocyclyl, or —NRₐR_{b}, wherein Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl,

wherein (i) R₃ and R₄ are not both 3,5 dialkyl substituted aryl, (ii) R₃ and R₄ are not both 3,5 dialkyl substituted phenyl, (iii) R₃ and R₄ are not both 3,5 dimethylphenyl, (iv) R₃ and R₄ are not both 3,5 dimethylphenyl when M is Cu or Au, or (v) the compound is not

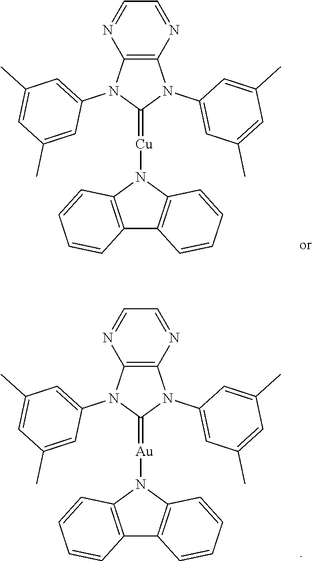

2. The compound of paragraph 1, having a structure:

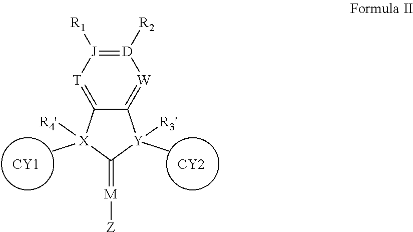

wherein CY1 and CY2 are independently substituted aryl, unsubstituted aryl, substituted polyaryl, unsubstituted polyaryl, substituted heteroaryl, unsubstituted heteroaryl, substituted polyheteroaryl, unsubstituted polyheteroaryl, substituted C₃-C₂₀ cycloalkyl, unsubstituted C₃-C₂₀ cycloalkyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl.

3. The compound of paragraph 1 or 2, wherein R₃′ and R₄′ are absent.

4. The compound of paragraph 2 or 3, wherein CY1 and CY2 are independently substituted aryl, unsubstituted aryl, substituted polyaryl, or unsubstituted polyaryl.

5. The compound of any one of paragraphs 2 to 4, wherein CY1 and CY2 are substituted aryl.

6. The compound of any one of paragraphs 1 to 5, having a structure:

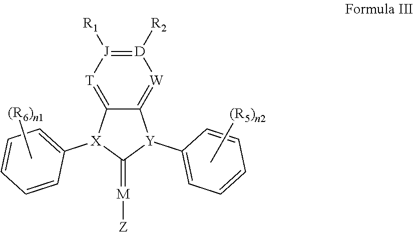

wherein:

R₅ and R₆ are independently substituted alkyl or unsubstituted alkyl, and

n1 and n2 are independently integers between 0 and 5; between 1 and 5; between 3 and 5, such as 3; or between 2 and 5; such as 2.

7. The compound of any one of paragraphs 1 to 6, having a structure:

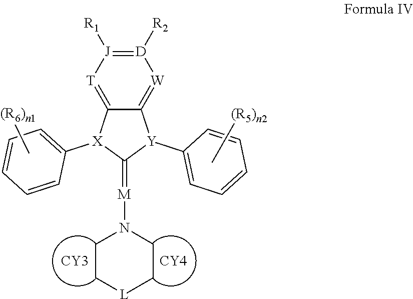

wherein:

n1 and n2 are independently integers between 1 and 5, between 2 and 5, or between 3 and 5,

L is absent, a single bond, substituted alkyl, —(CH₂)ₙₓ—, oxygen, sulfur, or NRx, wherein nx is an integer between 1 and 3 (such as 1, 2, or 3), and Rx is unsubstituted alkyl, substituted alkyl, unsubstituted aryl, or substituted aryl, and

CY3 and CY4 are independently unsubstituted aryl, substituted aryl, unsubstituted polyaryl, substituted polyaryl, unsubstituted heteroaryl, substituted heteroaryl, unsubstituted polyheteroaryl, substituted polyheteroaryl, unsubstituted C₃-C₂₀ cycloalkyl, substituted C₃-C₂₀ cycloalkyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, or a fused combination thereof.

8. The compound of any one of paragraphs 1 to 7, having a structure:

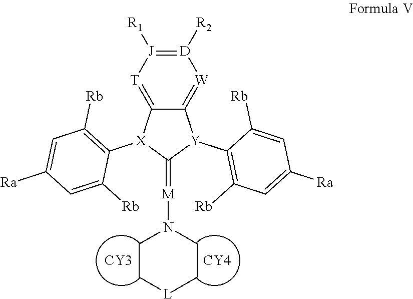

wherein:

each Ra is independently hydrogen, unsubstituted alkyl, or substituted alkyl,

each Rb is independently unsubstituted alkyl, or substituted alkyl,

L is absent, a single bond, substituted alkyl, —(CH₂)ₙₓ—, oxygen, sulfur, or NRx, wherein nx is an integer between 1 and 3 (such as 1, 2, or 3), and Rx is unsubstituted alkyl, substituted alkyl, unsubstituted aryl, or substituted aryl, and optionally wherein at least one of X and Y is nitrogen.

9. The compound of any one of paragraphs 1 to 8, wherein:

(i) T is nitrogen, J is carbon, and W is carbon,

(ii) T is nitrogen, J is carbon, and W is nitrogen,

(iii) T is carbon, J is nitrogen, and W is carbon, or

(iv) T is carbon, J is nitrogen, and W is nitrogen.

10. The compound of paragraph 8 or 9, wherein:

Ra is independently hydrogen, unsubstituted alkyl, or substituted alkyl, and

Rb is independently unsubstituted alkyl or substituted alkyl.

11. The compound of any one of paragraphs 1 to 10, wherein P′ is selected from:

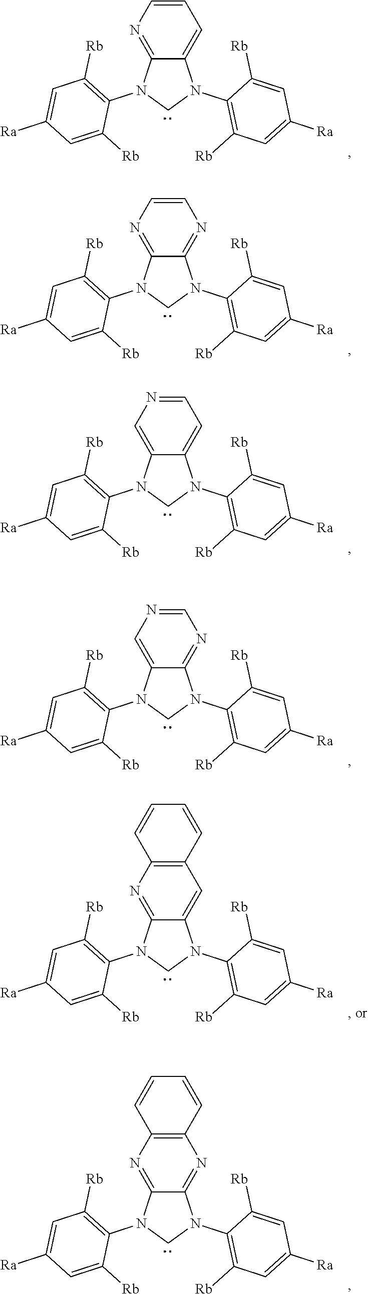

wherein:

Ra is independently hydrogen, unsubstituted alkyl, or substituted alkyl, and

Rb is independently unsubstituted alkyl or substituted alkyl.

12. The compound of any one of paragraphs 8 to 11, wherein:

Ra is independently hydrogen, methyl, iso-propyl, or —CH(C2H5)2, and

Rb is independently methyl, iso-propyl, or —CH(C₂H₅)₂.

13. The compound of any one of paragraphs 7 to 12, wherein CY3 and CY4 are independently unsubstituted aryl, substituted aryl, unsubstituted polyaryl, substituted polyaryl, unsubstituted heteroaryl, unsubstituted heteroaryl, substituted C₃-C₂₀ cycloalkenyl, unsubstituted C₃-C₂₀ cycloalkenyl, or a fused combination thereof.

14. The compound of any one of paragraphs 7 to 13, wherein CY3 and CY4 are independently unsubstituted aryl, substituted aryl, unsubstituted heteroaryl, unsubstituted heteroaryl, substituted C₃-C₂₀ cycloalkenyl, unsubstituted C₃-C₂₀ cycloalkenyl, or a fused combination thereof.

15. The compound of any one of paragraphs 1 to 14, wherein Z has a structure:

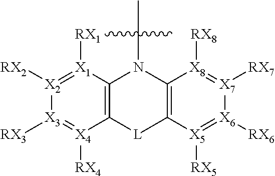

wherein:

X₁, X₂, X₃, X₄, X₅, X₆, X₇, and X₈ are independently carbon or nitrogen, Rx₁, Rx₂,Rx₃, Rx₄, Rxs, Rx₆, Rx₇, and Rx₈ are independently hydrogen, halogen, cyano, unsubstituted alkyl, substituted alkyl, unsubstituted alkoxy, substituted alkoxy, unsubstituted aryl, substituted aryl, unsubstituted heteroaryl, or substituted heteroaryl, wherein each Rx₁, Rx₂, Rx₃, Rx₄, Rxs, Rx₆, Rx₇, or Rx₈ is absent, when the corresponding X₁, X₂,X₃, X₄, X₅, X₆, X₇, or X₈ is nitrogen, or Rx₄ is a bond connected to a substituent on L, or adjacent Rxn groups together with the atoms in the ring to which they are bonded, together independently form five- or six-membered substituted aryl, unsubstituted aryl, substituted heteroaryl, unsubstituted heteroaryl, substituted C₃-C₂₀ cycloalkenyl, unsubstituted C₃-C₂₀ cycloalkenyl, or a fused combination thereof, wherein the n in the adjacent Rxn groups are sequential pairs of integers from 1 to 4, or 5 to 8, and

L is absent, a single bond, substituted alkyl, —(CH₂)ₙₓ—, oxygen, sulfur, or

NRx, wherein nx is an integer between 1 and 3 (such as 1, 2, or 3), and Rx is unsubstituted alkyl, substituted alkyl, unsubstituted aryl, or substituted aryl.

16. The compound of any one of paragraphs 1 to 15, wherein Z has a structure:

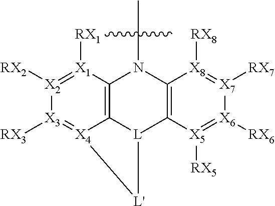

wherein:

L′ is substituted aryl, unsubstituted aryl, substituted heteroaryl, or unsubstituted heteroaryl, preferably substituted aryl or unsubstituted aryl, preferably substituted phenyl or unsubstituted phenyl.

17. The compound of paragraph 15, wherein Z has a structure:

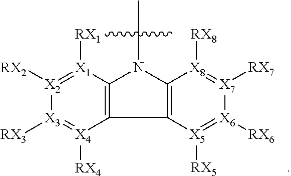

18. The compound of paragraph 15 or 17, wherein Rx₁, Rx₂, Rx₃, Rx₄, Rx₅, Rx₆, Rx₇, and Rx₈ are independently hydrogen, halogen, methyl, cyano, trifluoromethyl, tert-butyl, methoxy, phenyl, or pyridyl.

19. The compound of any one of paragraphs 1 to 18, wherein X and Y are nitrogen.

20. The compound of paragraph 1, having a structure:

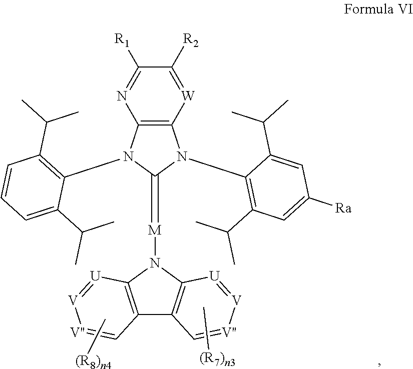

preferably

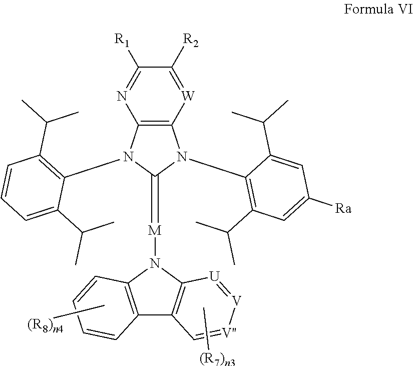

wherein:

V″ is carbon,

U is carbon and V is nitrogen, or U is nitrogen and V is carbon, wherein U, V, and V″ are bonded to one or no hydrogen atom according to valency,

Ra is hydrogen, unsubstituted alkyl, or substituted alkyl,

R₇ and R₈ are independently absent, hydrogen, substituted alkyl, unsubstituted alkyl, cyano, halogen, hydroxyl, thiol, nitro-, unsubstituted alkoxy, substituted alkoxy, unsubstituted aroxy, substituted aroxy, substituted aryl, unsubstituted aryl, or adjacent R₇ groups or adjacent R₈ groups together with the atoms in the ring to which they are bonded, together independently form five- or six-membered substituted aryl, unsubstituted aryl, substituted heteroaryl, unsubstituted heteroaryl, substituted C₃-C₂₀ cycloalkenyl, unsubstituted C₃-C₂₀ cycloalkenyl, or a fused combination thereof, and

n3 and n4 are independently integers between 0 and 5, such as 0, 1, 2, 3, 4, 5.

21. The compound of paragraph 19, having a structure:

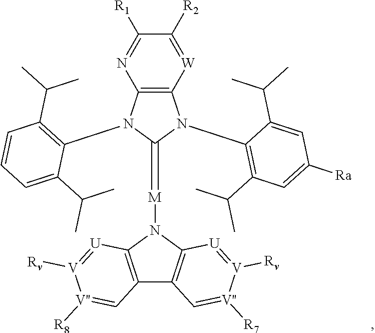

preferably

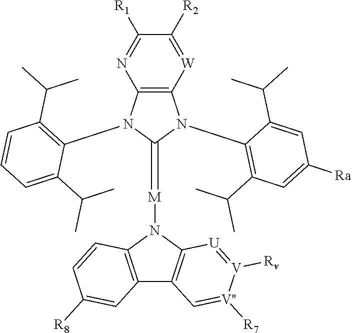

wherein:

Rv is absent, hydrogen, substituted alkyl, or unsubstituted alkyl, and

R₇ and R₈ are independently hydrogen, substituted alkyl, unsubstituted alkyl, unsubstituted aryl, halogen, or cyano, or

Rv and R₇ together with the atoms in the rings to which they are bonded form five- or six-membered substituted aryl, unsubstituted aryl, substituted heteroaryl, unsubstituted heteroaryl, substituted C₃-C₂₀ cycloalkenyl, unsubstituted C₃-C₂₀ cycloalkenyl, or a fused combination thereof.

22. The compound of paragraph 20 or 21, wherein:

Rv is absent or hydrogen,

R₇ and R₈ are independently hydrogen, iso-propyl, tert-butyl, phenyl, fluorine, or cyano, or

Rv and R₇ together form

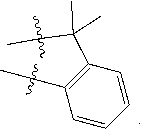 [SMILES: *c1ccccc1C(*)(C)C]

23. The compound of any one of paragraphs 20 to 22, wherein:

R₁ and R₂ are independently hydrogen, substituted alkyl, unsubstituted alkyl, substituted alkenyl, unsubstituted alkenyl, substituted alkynyl, unsubstituted alkynyl, substituted aryl, unsubstituted aryl, or

R₁ and R₂ with the atoms in the ring to which they are bonded together form unsubstituted aryl, substituted aryl, unsubstituted heteroaryl, or substituted heteroaryl.

24. The compound of any one of paragraphs 20 to 23, wherein:

R₁ and R₂ are hydrogen, or

R₁ and R₂ together form the structure:

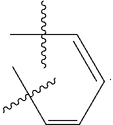 [SMILES: */C=C\C=C/*]

25. The compound of paragraph 24, having a structure:

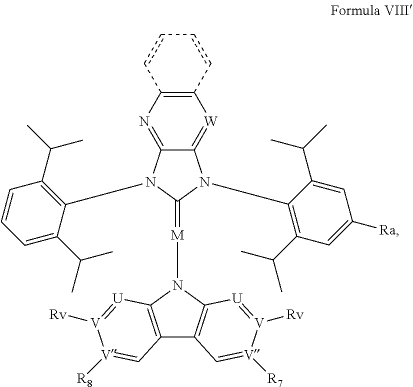

preferably

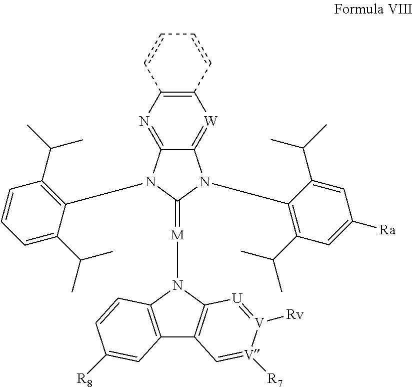

wherein:

(i) M=Cu(I); W=N; Ra=H; U=CH; V=V″=carbon; Rv=H; R₇=R₈=H;

(ii) M=Cu(I); W=N; Ra=H; U=CH; V=V″=carbon; Rv=H; R₇=H; R₈=CN;

(iii) M=Cu(I); W=N; Ra=H; U=CH; V=V″=carbon; Rv=H; R₇=R₈=tert-butyl;

(iv) M=Cu(I); W=N; Ra=H; U=CH; V=V″=carbon; Rv=H; R₇=R₈=phenyl;

(v) M=Cu(I); W=N; Ra=H; U=CH; V=N; V″=carbon; Rv=absent; R₇=R₈=H;

(vi) M=Cu(I); W=U=CH; V=V″=carbon; Rv=H; Ra=iso-propyl; R₇=R₈=H;

(vii) M=Cu(I); W=N; Ra=H; U=CH; V=V″=carbon; R₈=H; Rv and R₇ together form

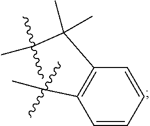 [SMILES: *c1ccccc1C(*)(C)C]

(viii) M=Cu(I); W=U=CH; Ra=iso-propyl; V=V″=carbon; R₈=H; Rv and R₇ together form

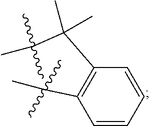 [SMILES: *c1ccccc1C(*)(C)C]

(ix) M=Cu(I); W=N; Ra=H; U=CH; V=V″=carbon; Rv=H; R₇=R₈=H;

(x) M=Cu(I); W=N; Ra=H; U=CH; V=V″=carbon; Rv=H; R₇=H; R₈=F;

(xi) M=Cu(I); W=N; Ra=H; U=CH; V=V″=carbon; Rv=H; R₇=R₈=methyl;

(xii) M=Au(I); W=N; Ra=H; U=CH; V=carbon; Rv=H; V″=carbon; R₇=R₈=H;

(xiii) M=Au(I); W=N; Ra=H; U=CH; V=carbon; Rv=H; V″=carbon; R₇=H, R₈=CN;

(xiv) M=Au(I); W=N; Ra=H; U=N; V=carbon; Rv=H; V″=carbon; R₇=R₈=H;

(xv) M=Au(I); W=U=CH; V=carbon; Rv=H; ; Ra=iso-propyl; V″ =carbon; R₇=R₈=H;

(xvi) M=Au(I); W=N; Ra=H; U=CH; V=N; Rv=absent; V″=carbon; R₇=R₈=H;

(xvii) M=Au(I); W=N; Ra=H; U=CH; V=V″=carbon; Rv=H; R₇=R₈=CN;

(xviii) M=Au(I); W=N; Ra=hydrogen; U=CH; V=V″=carbon; R₈=H; Rv and R₇ together form

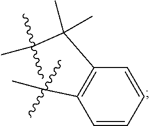 [SMILES: *c1ccccc1C(*)(C)C]

(xix) M=Au(I); W=U=CH; Ra=iso-propyl; V=V″=carbon; Rv=H; R₇=R₈=tert-butyl;

(xx) M=Au(I); W=U=CH; Ra=iso-propyl; V=V″=carbon; Rv=H; R₇=H; R₈=F;

(xxi) M=Au(I); W=N; U=CH; Ra=H; V=V″=carbon; Rv=H; R₇=R₈=H;

(xxii) M=Au(I); W=N; U=CH; Ra=H; V=V″=carbon; Rv=H; R₇=R₈=tert-butyl;

(xxiii) M=Ag(I); W=N; U=CH; Ra=H; V=V″=carbon; Rv=H; R₇=R₈=H;

for (i), (ii), (iii), (iv), (v), (vi), (vii), (viii), (xii), (xiii), (xiv), (xv), (xvi), (xvii), (xviii), (xix), (xx), and (xxiii), the dashed lines denote the absence of bonds, and

for (ix), (x), (xi), (xxi), and (xxii), the dashed lines denote the presence of bonds.

26. The compound of paragraph 1, having a structure:

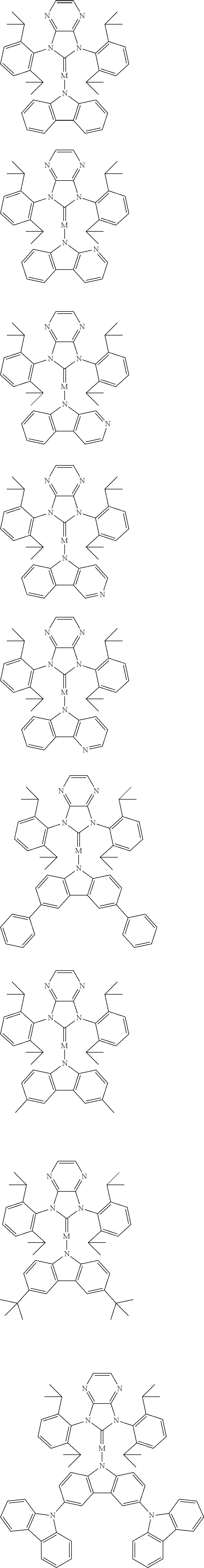

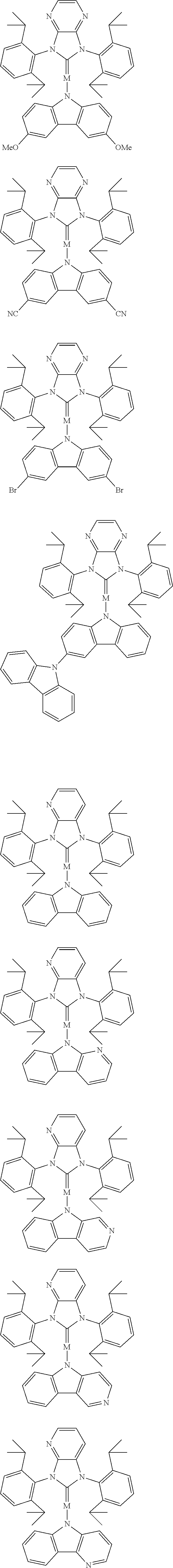

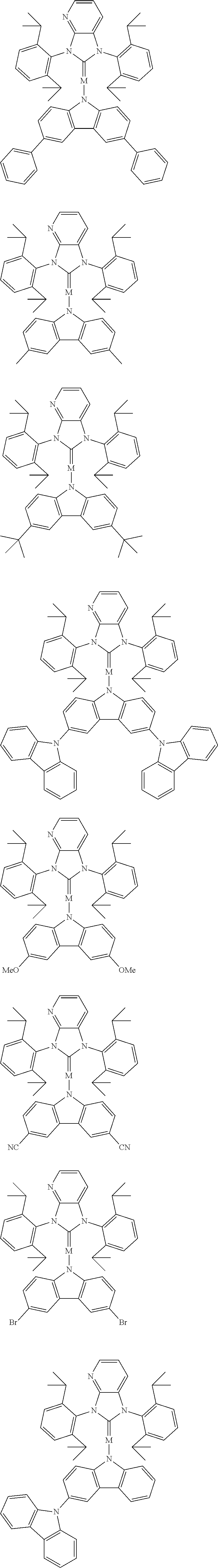

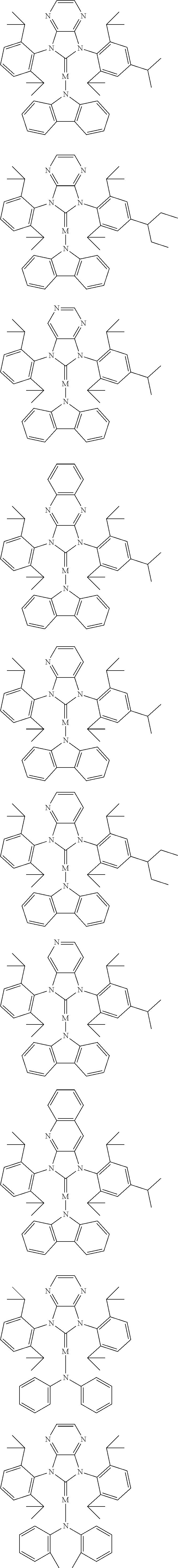

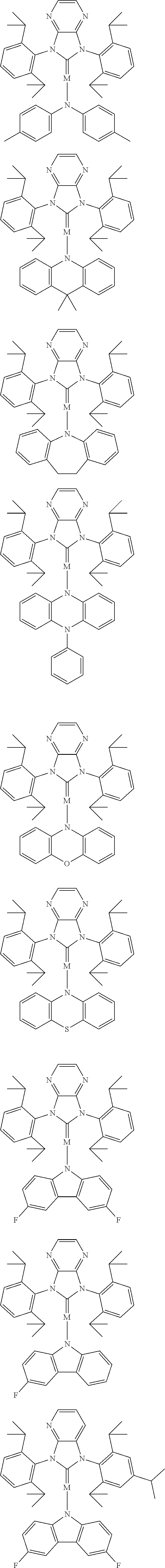

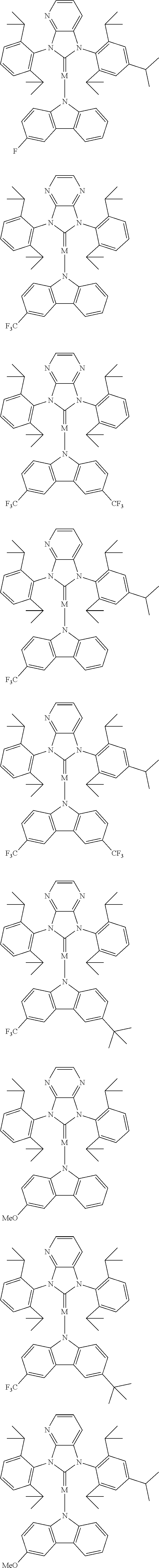

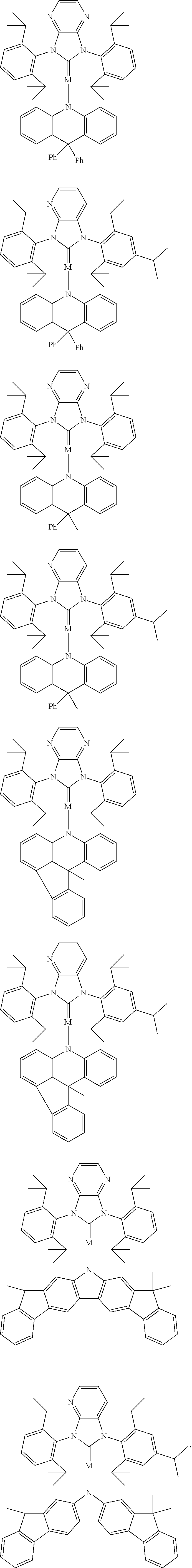

wherein M=Cu(I), Au(I), or Ag(I).

27. The compound of any one of paragraphs 1 to 25, wherein substituted means substituted with one or more substituents selected from: halogen, hydroxyl, thiol, nitro-, unsubstituted alkyl, unsubstituted alkenyl, unsubstituted alkynyl, unsubstituted aryl, unsubstituted heteroaryl, unsubstituted arylalkyl, unsubstituted alkoxy, unsubstituted aroxy, unsubstituted alkylthio, unsubstituted arylthio, cyano, isocyano, unsubstituted carbonyl, unsubstituted carboxyl, oxo, unsubstituted amino, unsubstituted amido, unsubstituted sulfonyl, unsubstituted sulfonic acid, unsubstituted phosphoryl, unsubstituted phosphonyl, unsubstituted polyaryl, or unsubstituted C₃-C₂₀ cycloalkyl, and unsubstituted heterocyclyl.

28. An organic electronic component containing the compound of any one of paragraphs 1 to 27.

29. The organic electronic component of paragraph 28, wherein the organic electronic component is an organic light-emitting diode (OLED) or a light-emitting electrochemical cell (LEEC).

30. The organic electronic component of paragraph 28 or 29, wherein the compounds are in a light-emitting layer.

31. The organic electronic component of any one of paragraphs 28 to 30, further containing an anode, a cathode, a hole transport region, and an electron transport region,

wherein the hole transport region contains a hole injection layer and/or a hole transport layer, and optionally an electron blocking layer,

wherein the electron transport region contains an electron transport layer and/or an electron injection layer, and optionally a hole blocking layer,

wherein the light emitting layer is located in between the anode and the cathode,

wherein the hole transport region is located between the anode and the light-emitting layer, and wherein the electron transport region is located in between the cathode and the light-emitting layer.

32. The organic electronic component of paragraph 29 or 30, wherein the light-emitting layer is fabricated by vacuum deposition, spin-coating or ink printing (such as, ink-jet printing or roll-to-roll printing).

33. A light-emitting layer containing the compound of any one of paragraphs 1 to 27.

34. A light-emitting layer comprising the compound of any one of paragraphs 1 to 27 and a pure organic emitter, wherein the compound acts as a sensitizer to transfer energy (such as exciton energy or photon energy) to the pure organic emitter.

35. A light-emitting layer comprising the compound of any one of claims 1 to 27 and a pure organic emitter, wherein the compound has a higher-lying singlet state than the pure organic emitter.

36. A light-emitting layer comprising the compound of any one of paragraphs 1 to 27 and a pure organic emitter, wherein the compound acts as a sensitizer to transfer energy (such as exciton energy or photon energy) to the pure organic emitter that exhibits thermally activated delayed fluorescence.

37. A light-emitting layer comprising the compound of any one of paragraphs 1 to 27 and a pure organic emitter, wherein the compound acts as a sensitizer to transfer energy (such as exciton energy or photon energy) to the pure organic emitter that is boron-based.

38. An OLED, containing the light-emitting layer of any one of paragraphs 33 to 37.

39. A device, containing the OLED of paragraph 38, wherein the device is selected from stationary visual display units, mobile visual display units, illumination units, keyboards, clothes, ornaments, garment accessories, wearable devices, medical monitoring devices, wall papers, tablet computers, laptops, advertisement panels, panel display units, household appliances, or office appliances.

### EXAMPLES

Several d10 metal (Cu(I), Ag(I) or Au(I)) carbene complexes supported by pyrazine-fused N-heterocyclic carbene (NHC) ligand and carbazole derivatives have been prepared. These complexes show efficient TADF properties with high photoluminescence quantum yield (0.58-0.92) and short emission decay lifetime (0.23-0.42 μs) in a 1,3-bis(N-carbazolyl)benzene (mCP) thin film. The radiative decay rate constants of these complexes are impressively high, with kᵣ of 15-21×10⁵ s⁻¹ for Cu(I) complexes and kᵣ of ˜29×10⁵ s⁻¹ for Au(I) complexes. Both are higher than those of the previously reported Cu(I) (kᵣ: 0.38-10×10⁵ s⁻¹) and Au(I) (0.53-22×10⁵ s⁻¹) counterparts supported by cyclic (alkyl)(amino)carbene (CAAC)(Nature Communications 2020, 11, 1758; Chem. Sci. 2020, 11, 435), monoamido-aminocarbene (MAC*)(J. Am. Chem. Soc. 2019, 141, 3576-3588) or diamidocarbene (DAC*)(J. Am. Chem. Soc. 2019, 141, 3576-3588).

It is believed that what the improved properties of the disclosed d10 metal carbene complexes are driven by the use of a pyrazine-fused NHC or a pyridine-fused NHC ligand decorated with bulky 2,6-diisopropylphenyl (DIPP) side groups in these two-coordinated d10 metal carbene complexes. The ligand structure increases the chemical and electrochemical stability, improves the electroluminescence performance as well as the photoluminescence quantum yield by suppressing the excited state structural distortions. The electroluminescence performance, i.e., ultra-high device brightness and remarkably long device lifetime, are unprecedented for d10 emitters. Further, the emission colors of this class of emitters are tunable by using carbazole derivatives with varying donor strength. For instance, green (Cu2 and Au2), yellow (Cu1, Au1, and Ag1), and red (Cu3) emitters have been prepared.

### Example 1: Synthesis and characterization of compounds

### Materials and Methods

The chemical reagents used for synthesis were purchased from commercial sources such as Dieckmann, Tiv Scientific, J & K Scientific, BLDpharm, Bidepharm. They were directly used without further processing.

The solvents used for synthesis were purchased from Duksan, RCI Labscan, Scharlau. They were directly used without further processing.
(i) Synthesis of pyrazine fused N-heterocyclic carbene ligand or pyridine fused N-heterocyclic carbene ligand

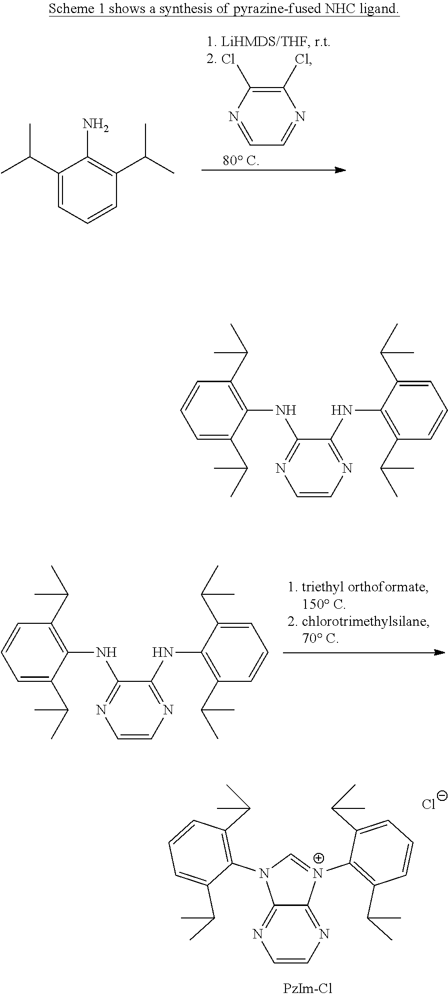

(a) Synthesis of N,N′-bis(2,6-diisopropylphenyl)pyrazine-2,3-diamine

To a 1-M solution of lithium hexamethyldisilazide (LiHMDS) in THF (3.5 eq.) in a sealed tube was added 2,6-diisopropylaniline (3.0 eq.). The resulting mixture was stirred under argon for 30 min. Then, 2,3-dichloropyrazine (1.0 eq.) was added into the reaction mixture and heated at 80° C. overnight. After reaction, the solvent was evaporated to dryness and the residue was extracted with DCM, which was then purified by column chromatography. ¹H NMR (500 MHz, CDCl₃) δ/ppm 7.49 (s, 1H), 7.34-7.30 (m, 1H), 7.24 (d, J=7.6 Hz, 2H), 5.72 (s, 1H), 3.10 (dt, J=13.5, 6.7 Hz, 2H), 1.19 (d, J=6.7 Hz, 16H). ¹³C NMR (100 MHz, CDCl₃) δ/ppm 146.10, 144.34, 133.84, 132.40, 127.98, 124.03, 28.98, 23.88. HRESI-MS [M+H]⁺ for [C₂₈H₃₈N_{4]}⁺, cal. m/z: 431.3169, found: 431.3168.
(b) Synthesis of 1,3-bis(2,6-diisopropylphenyl)imidazo[4,5-b]pyrazin-3-ium chloride (Pzlm-Cl)

To a round bottom flask was added N,N′-bis(2,6-diisopropylphenyl)pyrazine-2,3-diamine (1.2 mmol) in triethyl orthoformate. The mixture was heated at 150° C. for 6 hours. Then the mixture was cooled down to room temperature and excess chlorotrimethylsilane was added. The resulting reaction mixture was heated at 70° C. overnight. After reaction, the precipitate was collected by filtration, washed with Et₂O and dried under air to give an off-white solid. ¹H NMR (500 MHz, CDCl₃) δ/ppm 13.64 (br s, 1H), 8.87 (s, 2H), 7.66 (t, J=7.5 Hz, 2H), 7.42 (d, J=8.0 Hz, 4H), 2.99 (m, 4H), 1.30 — 1.12 (m, 24H). ¹³C NMR (100 MHz, CDCl₃) δ/ppm 145.66, 145.02, 137.87, 132.73, 126.21, 124.98, 30.04, 24.62, 23.53. HRESI-MS [M-Cl]⁺ for [C₂₉H₃₇N₄]⁺, cal. m/z: 441.3013, found: 441.3013.

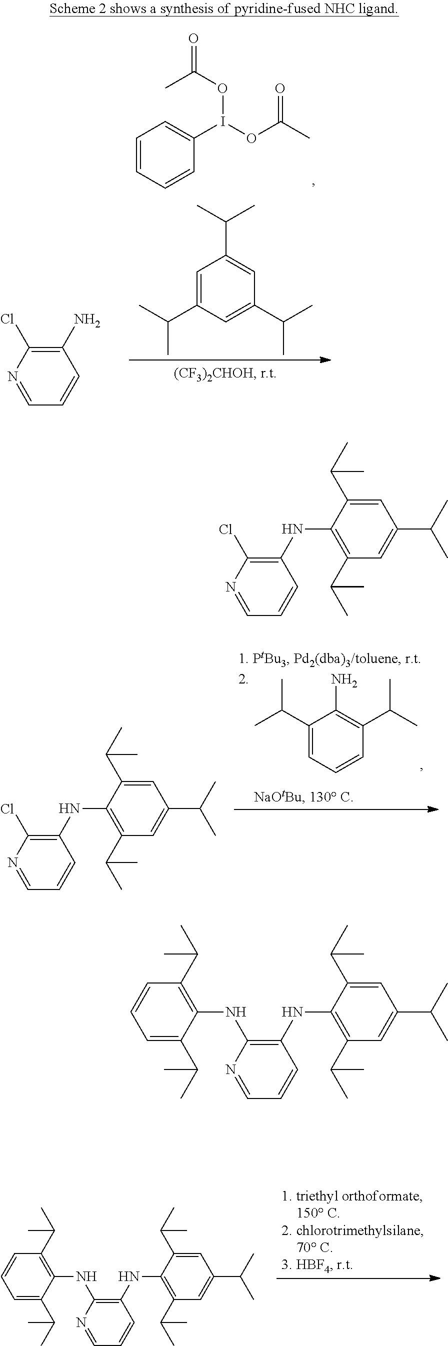

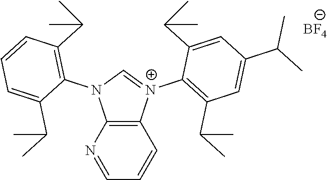

(c) Synthesis of 2-chloro-N-(2,4,6-triisopropylphenyl)pyridin-3-amine

A mixture of 2-chloropyridin-3-amine (1.28 g, 10 mmol), (diacetoxyiodo)benzene (15 mmol), and triisopropylbenzene (100 mmol) in 1,1,1,3,3,3-hexafluoro-2-propanpol (40 mL) was stirred at room temperature overnight. After reaction, solvent was evaporated and the residue was purified by column chromatography. Yield: 2.85 g, 86%. ¹H NMR (500 MHz, CDCl₃) δ/ppm 7.73 (d, J=4.2 Hz, 1H), 7.08 (s, 2H), 6.95 (dd, J=8.0, 4.6 Hz, 1H), 6.45 (d, J=7.9 Hz, 1H), 5.63 (s, 1H), 3.02 (dt, J=13.7, 6.9 Hz, 2H), 2.93 (dt, J=13.8, 6.9 Hz, 1H), 1.29 (d, J=6.9 Hz, 6H), 1.18 (s, 6H), 1.10 (d, J=6.8 Hz, 6H). ¹³C NMR (101 MHz, CDCl₃) δ/ppm 148.90, 147.37, 141.30, 137.21, 136.38, 130.83, 123.54, 122.29, 119.07, 77.55, 77.23, 76.91, 34.48, 28.66, 24.79, 24.29, 23.39. HRESI-MS: [M+H]⁺ for [C₂₀H₂₇N₂Cl]⁺, cal. m/z: 331.1936, found: 331.1933.
(d) Synthesis of N²-(2,6-diisopropylphenyl)-N³-(2,4,6-triisopropylphenyl)-pyridine-2,3-diamine

To a solution of P^{T}Bu₃ (100 mg, 0.50 mmol) in toluene (20 mL) was added Pd₂(dba)₃ (100 mg, 0.11 mmol). The dark red solution was stirred at room temperature for five minutes. Then 2,6-diisopropylaniline (355 mg, 2.0 eq.), 2-chloro-N-(2,4,6-triisopropylphenyl)pyridin-3-amine (330 mg, 1.0 eq.) and NaO^{t}Bu (289 mg, 3.0 eq.) were added into the solution in one port. The resulting suspension was heated at 130° C. for two days. After reaction, the solution was passed through a pad of celite and evaporated to dryness. The residue was purified by column chromatography on silica gel. Yield: 167 mg, 35%. ¹H NMR (500 MHz, CDCl₃) δ/ppm 7.69 (d, J=4.2 Hz, 1H), 7.36-7.31 (m, 1H), 7.29 (d, J=7.3 Hz, 2H), 7.13 (s, 2H), 6.58 — 6.49 (m, 2H), 6.06 (s, 1H), 4.82 (s, 1H), 3.25 (dt, J=13.7, 6.8 Hz, 2H), 3.13 (dt, J=13.6, 6.8 Hz, 2H), 2.98 (dt, J=13.8, 6.9 Hz, 1H), 1.26 (d, J=5.7 Hz, 24H), 1.20 (s, 6H). ¹³C NMR (101 MHz, CDCl₃) δ/ppm 149.50, 146.83, 145.88, 144.72, 139.01, 135.13, 133.35, 131.35, 127.06, 123.63, 121.94, 121.11, 114.82, 34.22, 28.77, 28.36, 24.20. HRESI-MS: [M+H]⁺ for [C₃₂H₄₅N_{3]}⁺, cal. m/z: 472.3686, found: 472.3680.
(e) Synthesis of 3-(2,6-diisopropylphenyl)-1-(2,4,6-triisopropylphenyl)-1H-imidazo [4,5-b]pyridin-3-ium tetrafluoroborate salt (PyIPr-BF₄)

A solution of N²-(2,6-diisopropylphenyl)-N³-(2,4,6-triisopropylphenyl)-pyridin-2,3-amine (500 mg, 1.06 mmol) in triethyl orthoformate. Then, the mixture was heated at 150° C. for several hours. Then the mixture was cooled down to room temperature and excess chlorotrimethylsilane was added. The resulting reaction mixture was heated at 70° C. overnight. After reaction, solvent was evaporated and HBF₄ in methanol was added and stirred at room temperature for 30 min. After that, the solution was extracted with dichloromethane and saturated NaHCO₃ aqueous solution. The organic layer was dried over MgSO₄ and evaporated to give a white solid as 3-(2,6-diisopropylphenyl)-1-(2,4,6-triisopropylphenyl)-1H-imidazo[4,5-b]pyridin-3-ium tetrafluoroborate salt. ¹H NMR (500 MHz, CDCl₃) δ/ppm 10.32 (s, 1H), 8.85 (d, J=4.4 Hz, 1H), 7.90 (d, J=8.3 Hz, 1H), 7.76 (dd, J=8.2, 4.6 Hz, 1H), 7.66 (d, J=7.8 Hz, 2H), 7.45 (d, J=7.8 Hz, 3H), 7.27 (s, 2H), 3.04 (dt, J=13.6, 6.8 Hz, 2H), 2.22 (td, J=13.4, 6.6 Hz, 5H), 1.35 (d, J=6.8 Hz, 7H), 1.28 (dd, J=6.5, 2.9 Hz, 15H), 1.13 (t, J=6.2 Hz, 15H). ¹⁹F NMR (471 MHz, CDCl₃) δ/ppm -151.89-151.94. ¹¹B NMR (160 MHz, CDCl₃) δ-1.31. ¹³C NMR (126 MHz, CDCl₃) δ/ppm 153.89, 151.06, 146.34, 145.86, 145.57, 144.31, 132.77, 126.57, 126.18, 125.08, 124.63, 124.29, 123.47, 123.06, 34.73, 30.01, 29.80, 24.55, 24.09, 24.02, 23.91. HRESI-MS: [M-BF₄]⁺ for [C₃₃H₄₄N₃]⁺, cal. m/z: 482.3529, found: 482.3516.
(ii) Synthesis of metal-carbene complexes

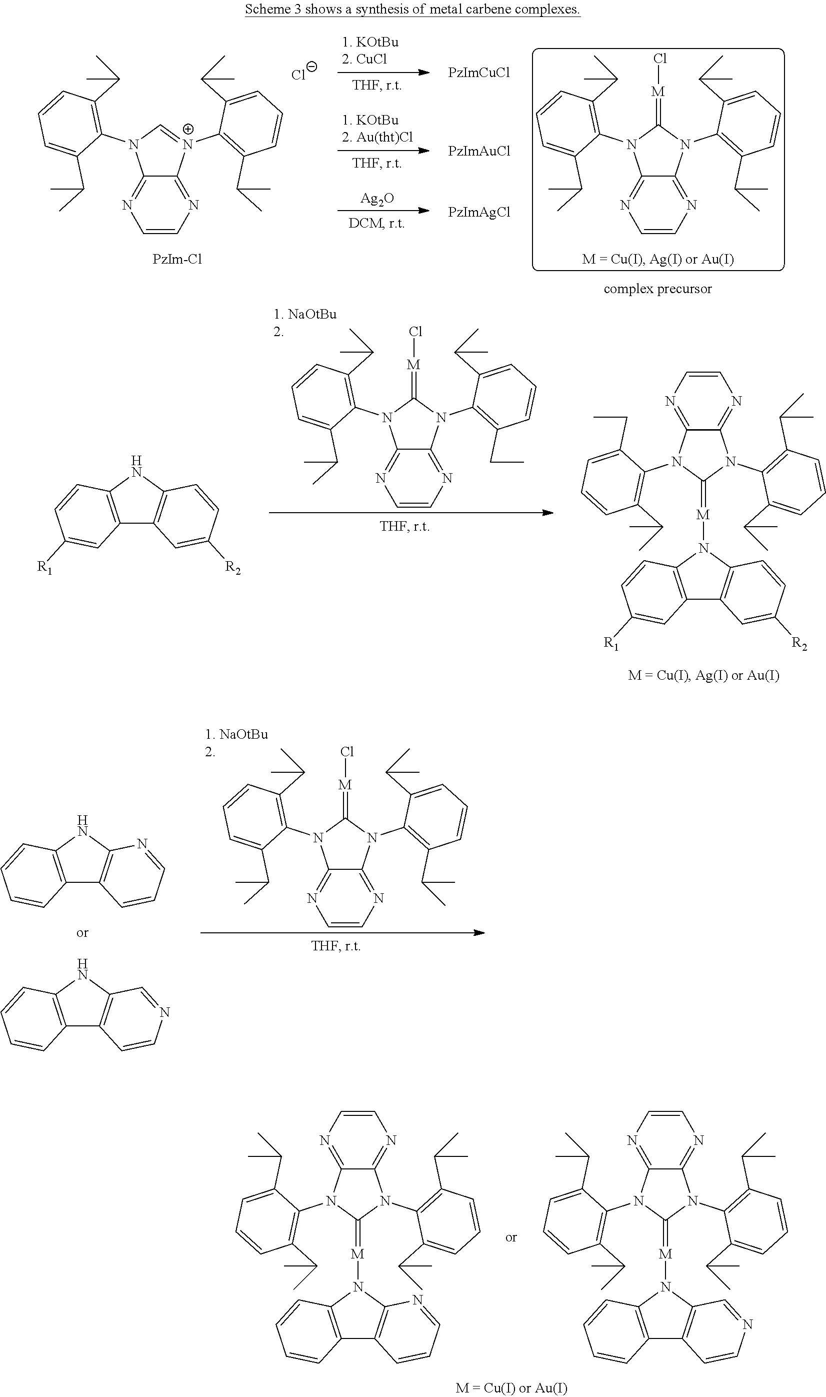

(a) Synthesis of complex precursor PzImCuCl

To a solution of KO^{t}Bu (1.2 eq.) in THF was added PzIm-Cl (1.0 eq.) and CuCl (1.2 eq.). The resulting mixture was stirred at room temperature under argon overnight. After reaction, the reaction mixture was passed through a layer of celite and then evaporated to dryness. The product was washed with EtOH and n-hexane. ¹H NMR (500 MHz, CDCl₃) δ/ppm ¹H NMR (500 MHz, CDCl₃) δ 8.52 (s, 2H), 7.62 (t, J=7.5 Hz, 2H), 7.42 (d, J=7.6 Hz, 4H), 2.38-2.27 (m, 4H), 1.30 (d, J=6.2 Hz, 12H), 1.12 (d, J=6.4 Hz, 12H). ¹³C NMR (126 MHz, CDCl₃) δ/ppm 193.51, 146.31, 141.20, 140.18, 131.81, 130.38, 124.93, 29.63, 24.94, 23.84.
(b) Synthesis of complex precursor PzImAuCl

To a suspension of PzIm-Cl (1.0 eq.) in THF was added KO^{t}Bu (1.2 eq.) and the resulting mixture was stirred at room temperature under argon for 1 hour during which time a solution was formed that turned clear gradually. Then Au(tht)Cl (1.2 eq.) was added and the reaction mixture was left to be stirred in dark for 16 h. After reaction, the mixture was filtered through a pad of celite and then evaporated to dryness. The product was washed with EtOH and n-hexane. Yield: 185 mg, 27%. ¹H NMR (500 MHz, CDCl₃) δ/ppm 8.55 (s, 2H), 7.63 (t, J=7.8 Hz, 2H), 7.41 (d, J=7.8 Hz, 4H), 2.33 (dt, J=13.8, 6.9 Hz, 4H), 1.34 (d, J=6.9 Hz, 12H), 1.10 (t, J=7.9 Hz, 12H). ¹³C NMR (126 MHz, CDCl₃) δ/ppm 188.22, 146.16, 141.49, 139.91, 131.70, 129.88, 124.75, 29.50, 24.40, 23.82.
(c) Synthesis of complex precursor PzImAgCl

To a solution of PzIm-Cl (1.0 eq.) in DCM was added Ag₂O (1.0 eq.). The resulting suspension was stirred in the dark at room temperature overnight. After reaction, the reaction mixture was filtered through a pad of celite then evaporated to dryness. The product was washed with EtOH and n-hexane. ¹H NMR (500 MHz, CDCl₃) δ/ppm 8.56 (s, 1H), 7.63 (t, J=7.7 Hz, 1H), 7.42 (d, J=7.8 Hz, 2H), 2.31 (dt, J=13.5, 6.8 Hz, 3H), 1.28 (d, J=6.8 Hz, 7H), 1.11 (d, J=6.7 Hz, 8H). ¹³C NMR (126 MHz, CDCl₃) δ/ppm 146.32, 141.47, 140.12, 131.97, 130.65, 125.06, 29.60, 24.86, 23.96.
(d) General procedure for the synthesis of complexes

To a solution of carbazole derivatives (1.5 eq.) in THF or a solution of pyrido[3,4-b]indole derivatives (1.5 eq.) in THF was added NaO^{t}Bu (1.5 eq.), and the mixture was stirred for 30 min at room temperature under argon. Then the NHC-M-Cl (1.0 eq.) was added and the reaction mixture was stirred in the dark overnight. After reaction, the mixture was passed through a pad of celite. The filtrate was evaporated to dryness and the product was washed with n-hexane.

Cu1: ¹H NMR (500 MHz, CD₂Cl₂) δ/ppm 8.59 (s, 2H), 7.85 (d, J=7.6 Hz, 4H), 7.59 (d, J=7.8 Hz, 2H), 6.96 (t, J=7.5 Hz, 2H), 6.85 (t, J=7.3 Hz, 2H), 6.23 (d, J=8.1 Hz, 2H), 2.54-2.45 (m, 4H), 1.26 (d, J=6.8 Hz, 12H), 1.18 (d, J=6.8 Hz, 12H). ¹³C NMR (126 MHz, CD₂Cl₂) δ/ppm 194.61, 149.71, 146.96, 141.06, 140.27, 131.49, 130.91, 124.84, 123.88, 123.40, 119.10, 115.44, 114.06, 29.52, 24.42, 23.50.

Cu2: ¹H NMR (500 MHz, CD₂Cl₂) δ/ppm 8.59 (s, 2H), 8.16 (s, 1H), 7.90-7.79 (m,3H), 7.58 (d, J=7.3 Hz, 4H), 7.17 (d, J=8.1 Hz, 1H), 7.05 (t, J=7.5 Hz, 1H), 6.95 (t, J=6.9 Hz, 1H), 6.27 (d, J=7.8 Hz, 1H), 6.12 (d, J=8.5 Hz, 1H), 2.46 (m, 4H), 1.22 (d, J=6.3 Hz, 12H), 1.16 (d, J=6.1 Hz, 12H). ¹³C NMR (151 MHz, CD₂Cl₂) δ/ppm 194.40, 152.20, 150.93, 147.54, 141.87, 140.72, 132.15, 131.40, 127.06, 125.54, 125.46, 124.98, 124.60, 123.85, 122.50, 120.14, 117.89, 115.16, 114.93, 97.47, 30.08, 25.02, 24.04.

Cu3: ¹H NMR (500 MHz, CD₂Cl₂) δ/ppm 8.58 (s, 2H), 7.87-7.80 (m, 4H), 7.60 (d, J=7.8 Hz, 4H), 7.02 (d, J=8.5 Hz, 2H), 6.17 (d, J=8.5 Hz, 2H), 2.50 (dt, J=13.5, 6.7 Hz, 4H), 1.37 (s, 18H), 1.28 (d, J=6.8 Hz, 12H), 1.18 (d, J=6.7 Hz, 12H).¹³C NMR (126 MHz, CD₂Cl₂) δ/ppm 195.21, 148.72, 147.33, 141.40, 140.69, 138.38, 131.88, 131.31, 125.22, 124.08, 121.55, 115.42, 113.75, 34.70, 32.36, 29.93, 24.89, 23.90.

Cu4: ¹H NMR (500 MHz, CD₂Cl₂) δ/ppm 8.61 (s, 2H), 8.18 (s, 2H), 7.87 (t, J=7.9 Hz, 2H), 7.68 (d, J=7.6 Hz, 4H), 7.62 (d, J=7.9 Hz, 4H), 7.42 (t, J=7.5 Hz, 4H), 7.30 (d, J=8.3 Hz, 2H), 7.25 (t, J=7.3 Hz, 2H), 6.30 (d, J=8.4 Hz, 2H), 2.52 (dq, J=13.8, 6.9 Hz, 4H), 1.30 (d, J=6.8 Hz, 12H), 1.20 (d, J=6.7 Hz, 12H).¹³C NMR (126 MHz, CD₂Cl₂) δ/ppm 194.85, 150.39, 147.42, 143.41, 141.56, 140.68, 131.98, 131.34, 129.28, 128.96, 127.16, 125.89, 125.31, 125.10, 123.66, 118.10, 114.85, 29.97, 24.90, 23.93. MALDI-TOF: [C₅₃H₅₂CuN₅] m/z cal. m/z: 821.35, found: 821.28. Anal. cal. for C53H52CuN₅+H₂O: C, 75.73; H, 6.48; N, 8.33; found: C, 75.71; H, 6.26; N, 8.10.

Cu5:¹H NMR (500 MHz, CD₂Cl₂) δ/ppm 8.64 (s, 2H), 8.03 (d, J=3.9 Hz, 1H), 7.96 (d, J=7.8 Hz, 1H), 7.89 (t, J=7.9 Hz, 2H), 7.77 (d, J=4.9 Hz, 1H), 7.70 (s, 1H), 7.63 (d, J=7.9 Hz, 4H), 7.12 (t, J=7.4 Hz, 1H), 6.96 (t, J=7.3 Hz, 1H), 6.30 (d, J=8.2 Hz, 1H), 2.52 (dt, J=13.7, 6.8 Hz, 4H), 1.29 (d, J=6.8 Hz, 12H), 1.21 (d, J=6.8 Hz, 12H).

Au1: ¹H NMR (400 MHz, CD₂Cl₂) δ/ppm 8.58 (s, 2H), 7.87 (d, J=7.6 Hz, 2H), 7.79 (t, J=7.9 Hz, 2H), 7.54 (d, J=7.9 Hz, 4H), 7.08-6.99 (m, 2H), 6.91-6.82 (m, 2H), 6.61 (d, J=8.1 Hz, 2H), 2.48 (dt, J=13.7, 6.9 Hz, 4H), 1.32 (d, J=6.9 Hz, 12H), 1.14 (d, J=6.9 Hz, 12H). ¹³C NMR (126 MHz, CD₂Cl₂) δ/ppm 149.77, 147.49, 141.94, 140.93, 132.07, 131.13, 125.29, 124.25, 124.14, 119.73, 116.70, 113.92, 30.15, 24.59, 24.31.

Au2: ¹H NMR (500 MHz, CD₂Cl₂) δ/ppm 8.61 (s, 1H), 8.20 (s, OH), 7.91 (d, J=7.7 Hz, 1H), 7.80 (t, J=7.8 Hz, 1H), 7.55 (d, J=7.8 Hz, 2H), 7.26 (d, J=8.4 Hz, OH), 7.13 (t, J=7.6 Hz, 1H), 6.99 (t, J=7.4 Hz, 1H), 6.66 (d, J=8.2 Hz,

OH), 6.56 (d, J=8.4 Hz, 1H), 2.46 (dt, J=13.6, 6.8 Hz, 2H), 1.31 (d, J=6.8 Hz, 6H), 1.15 (d, J=6.8 Hz, 6H). ¹³C NMR (126 MHz, CD₂Cl₂) δ/ppm 190.53, 151.14, 149.91, 146.94, 141.65, 140.23, 131.61, 130.47, 126.65, 125.11, 124.78, 124.51, 123.87, 123.08, 121.68, 119.63, 117.88, 113.96, 113.77, 97.74, 29.59, 24.04, 23.74.

Au3:¹H NMR (500 MHz, CD₂Cl₂) δ/ppm 8.62 (s, 2H), 8.19 (dd, J=10.7, 5.9 Hz, 2H), 7.92 (d, J=7.8 Hz, 1H), 7.77 (t, J=7.8 Hz, 2H), 7.55 (d, J=7.8 Hz, 4H), 7.16-7.09 (m, 1H), 6.98 (t, J=7.4 Hz, 1H), 6.90-6.83 (m, 1H), 6.72 (d, J=8.1 Hz, 1H), 2.55 (dt, J=13.1, 6.6 Hz, 4H), 1.44 (d, J=6.8 Hz, 12H), 1.18 (d, J=6.8 Hz, 12H). ¹³C NMR (126 MHz, CD₂Cl₂) δ/ppm 191.17, 148.59, 146.78, 145.01, 141.46, 140.29, 131.44, 130.46, 126.52, 124.69, 124.43, 121.92, 119.80, 116.83, 116.13, 113.65, 112.28, 29.59, 23.98, 23.67.

Ag1: ¹H NMR (500 MHz, CD₂Cl₂) δ/ppm 8.61 (s, 2H), 7.87 (d, J=7.5 Hz, 2H), 7.75 (t, J=7.7 Hz, 2H), 7.53 (d, J=7.7 Hz, 4H), 7.02 (t, J=7.4 Hz, 2H), 6.84 (t, J=7.2 Hz, 2H), 6.57 (d, J=8.0 Hz, 2H), 2.46 (dt, J=13.1, 6.5 Hz, 4H), 1.30 (d, J=6.6 Hz, 12H), 1.15 (d, J=6.6 Hz, 12H). ¹³C NMR (126 MHz, CD₂Cl₂) δ/ppm 150.27, 146.80, 141.55, 140.18, 131.69, 131.15, 124.93, 123.82, 123.41, 119.25, 115.08, 114.10, 29.57, 24.48, 23.71. Note: the ¹³C signal for carbenium carbon was not observed.

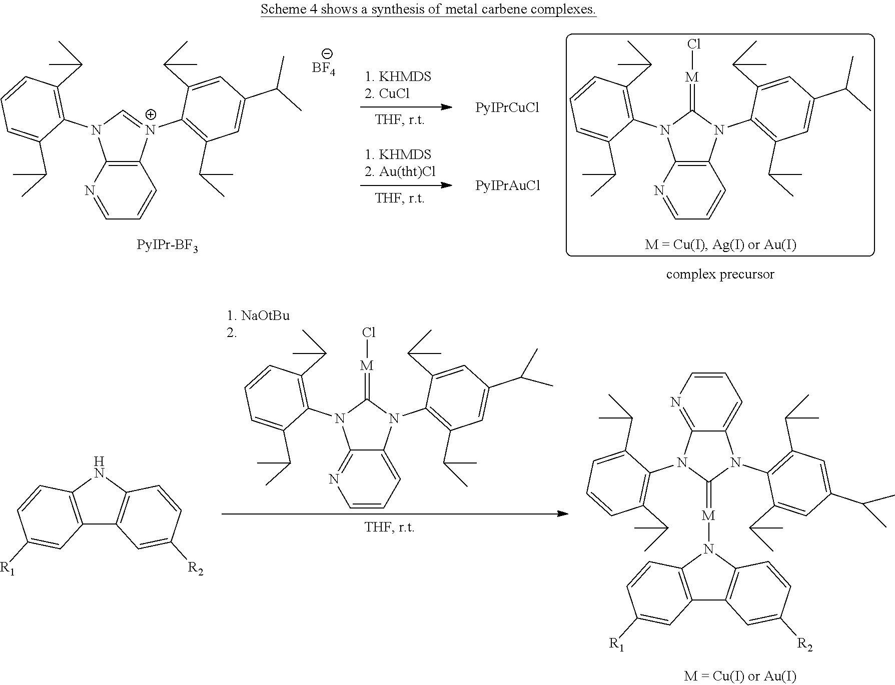

(e) General procedure for synthesis of complex precursor PyIPr-M-Cl

To a suspension of PyIPr-BF₄ (1.0 eq.) was added KHMDS (1.5 eq.) following by the addition of CuCl or Au(tht)Cl (1.5 eq.). The resulting mixture was stirred at room temperature under argon overnight. After reaction, the suspension was passed through a layer of celite and evaporated to dryness. The product was purified by recrystallization in DCM/EtOH.

PyIPrCuCl: ¹H NMR (500 MHz, CDCl₃) δ/ppm 8.52 (dd, J=4.7, 1.3 Hz, 1H), 7.58 (t, J=7.8 Hz, 1H), 7.49 (dd, J=8.1, 1.3 Hz, 1H), 7.40 (d, J=7.8 Hz, 2H), 7.35 (dd, J=8.2, 4.7 Hz, 1H), 7.21 (s, 2H), 3.03 (dt, J=13.8, 6.9 Hz, 1H), 2.36 (tt, J=13.6, 6.8 Hz, 4H), 1.36 (d, J=6.9 Hz, 6H), 1.29 (d, J=6.8 Hz, 12H), 1.11 (dd, J=6.7, 5.7 Hz, 12H). ¹³C NMR (101 MHz, CDCl₃) δ/ppm 190.09, 151.93, 147.00, 146.75, 146.39, 146.08, 131.39, 130.95, 129.02, 127.64, 124.73, 122.94, 120.29, 120.18, 34.65, 29.46, 29.25, 25.28, 24.95, 24.14, 24.01, 23.76. HRESI-MS: [M-Cl+MeCN]⁺ for [C₃₅H₄₆N₄Cu]⁺, cal. m/z: 585.3013, found: 585.3026.

PyIPrAuCl: ¹H NMR (500 MHz, CDCl₃) δ/ppm 8.54-8.51 (m, 1H), 7.59 (t, J=7.8 Hz, 1H), 7.51-7.48 (m, 1H), 7.42-7.35 (m, 4H), 7.22-7.18 (m, 3H), 3.02 (dt, J=13.8, 6.9 Hz, 1H), 2.40-2.28 (m, 6H), 1.37 (d, J=6.9 Hz, 8H), 1.33 (d, J=6.9 Hz, 16H), 1.09 (t, J=6.4 Hz, 17H). ¹³C NMR (101 MHz, CDCl₃) δ/ppm 184.52, 151.83, 146.90, 146.44, 146.22, 145.89, 131.29, 130.48, 128.43, 127.37, 124.55, 122.80, 120.58, 120.20, 34.43, 29.32, 29.11, 24.73, 24.41, 24.01, 23.92, 23.71. HRESI-MS: [M-Cl+MeCN]+for [C₃₅H₄₆N₄Au]⁺, cal. m/z: 719.3388, found: 719.3378.
(f) General procedure for the synthesis of complexes

To a solution of carbazole derivatives (1.5 eq.) in THF or a solution of pyrido[3,4-b]indole derivatives (1.5 eq.) in THF was added NaO^{t}Bu (1.5 eq.), and the mixture was stirred for 30 min at room temperature under argon. Then PyIPr-M-Cl (1.0 eq.) was added and the reaction mixture was stirred in dark overnight. After reaction, the mixture was passed through a pad of celite. The filtrate was evaporated to dryness and the product was washed with n-hexane.

Cu6: ¹H NMR (500 MHz, acetone-d₆) δ/ppm 8.63 (dd, J=4.7, 1.2 Hz, 1H), 7.98 (dd, J=8.1, 1.2 Hz, 1H), 7.86 (t, J=7.8 Hz, 1H), 7.81 (d, J=7.6 Hz, 2H), 7.69 — 7.62 (m, 3H), 7.58 (s, 2H), 6.92 — 6.87 (m, 2H), 6.77 (t, J=7.1 Hz, 2H), 6.32 (d, J=8.1 Hz, 2H), 3.25 (dt, J=13.8, 6.9 Hz,1H), 2.63 (ddt, J=13.7, 10.6, 6.8 Hz, 4H), 1.50 (d, J=6.9 Hz, 6H), 1.28 (dd, J=14.1, 6.9 Hz, 12H), 1.22 (d, J=6.9 Hz, 6H), 1.18 (d, J=6.9 Hz, 6H). ¹³C NMR (126 MHz, acetone-d₆) δ/ppm 191.90, 153.21, 150.92, 148.10, 148.06, 147.77, 147.63, 132.81, 131.89, 130.58, 128.62, 125.50, 125.12, 124.18, 123.77, 121.83, 121.55, 119.83, 116.16, 115.05, 35.49, 25.34, 24.98, 24.59, 24.11, 23.98.

Cu7: ¹H NMR (500 MHz, acetone-d₆) δ/ppm=8.73 (s, 2H), 8.22 (s, 1H), 7.99-7.93 (m, 2H), 7.87 (d, J=7.6 Hz, 1H), 7.74 (d, J=7.8 Hz, 4H), 7.70 (d, J=7.6 Hz, 1H), 7.40 (d, J=7.4 Hz, 1H), 7.26-7.20 (m, 1H), 7.16-7.10 (m, 1H), 6.90-6.85 (m, 1H), 6.83-6.77 (m, 1H), 6.54 (s, 1H), 6.13 (d, J=7.7 Hz, 1H), 2.73 (dd, J=14.0, 7.3 Hz, 4H), 1.43 (s, 6H), 1.32 (d, J=6.8 Hz, 12H), 1.20 (d, J=6.7 Hz, 12H).

Cu8: ¹H NMR (500 MHz, acetone-d₆) δ/ppm 8.63 (d, J=4.6 Hz, 1H), 8.23 (s, 1H), 7.94 (t, J=7.6 Hz, 2H), 7.88 (d, J=7.6 Hz, 1H), 7.71 (dd, J=12.6, 7.7 Hz, 3H), 7.65 (dd, J=8.0, 4.4 Hz, 1H), 7.60 (s, 2H), 7.40 (d, J=7.3 Hz, 1H), 7.22 (t, J=7.3 Hz, 1H), 7.12 (t, J=7.3 Hz, 1H), 6.89 (t, J=7.4 Hz, 1H), 6.79 (t, J=7.3 Hz, 1H), 6.60 (s, 1H), 6.24 (d, J=8.0 Hz, 1H), 3.27 (dt, J=13.7, 6.8 Hz, 1H), 2.72-2.61 (m, 4H), 1.51 (d, J=6.9 Hz, 6H), 1.41 (s, 6H), 1.32 (d, J=6.8 Hz, 12H), 1.21 (dd, J=14.6, 6.8 Hz, 12H).

Au4: ¹H NMR (500 MHz, CD₂Cl₂) δ/ppm 8.57 (dd, J=4.7, 1.1 Hz, 1H), 7.89 (d, J=7.6 Hz, 2H), 7.78 (t, J=7.8 Hz, 1H), 7.66 (dd, J=8.1, 1.1 Hz, 1H), 7.54 (d, J=7.9 Hz, 2H), 7.48 (dd, J=8.1, 4.7 Hz, 1H), 7.39 (s, 2H), 7.03 (t, J=7.6 Hz, 2H), 6.87 (t, J=7.3 Hz, 2H), 6.67 (d, J=8.1 Hz, 2H), 3.15 (dt, J=13.8, 6.9 Hz, 1H), 2.59 — 2.45 (m, 4H), 1.46 (d, J=6.9 Hz, 6H), 1.34 (t, J=6.6 Hz, 12H), 1.16 (t, J=7.0 Hz, 12H). ¹³C NMR (126 MHz, CD₂Cl₂) δ/ppm 188.61, 152.72, 149.71, 147.44, 147.34, 147.05, 147.02, 131.61, 131.43, 129.34, 128.10, 124.88, 124.01, 123.91, 123.13, 121.08, 120.45, 119.52, 116.29, 113.80, 35.14, 29.82, 29.66, 24.72, 24.45, 24.35, 24.31, 24.05.

Au5: ¹H NMR (500 MHz, acetone-d₆) δ/ppm 8.77 (s, 2H), 8.16 (s, 1H), 8.04 (d, J=5.1 Hz, 1H), 8.00 (d, J=7.8 Hz, 1H), 7.87 (t, J=7.9 Hz, 2H), 7.81 (d, J=5.0 Hz, 1H), 7.68 (d, J=7.9 Hz, 4H), 7.16 (t, J=7.6 Hz, 1H), 6.94 (t, J=7.2 Hz, 1H), 6.75 (d, J=8.3 Hz, 1H), 2.70 (dt, J=13.7, 6.8 Hz, 4H), 1.39 (d, J=6.9 Hz, 12H), 1.18 (d, J=6.8 Hz, 12H). ¹³C NMR (126 MHz, acetone-d₆) δ/ppm 190.94, 151.06, 148.05, 146.42, 142.95, 141.50, 137.61, 136.85, 132.54, 131.88, 129.14, 126.83, 125.70, 123.10, 121.65, 117.91, 115.57, 114.42, 24.73, 24.32.

Au6: ¹H NMR (500 MHz, acetone-d₆) δ/ppm 8.80 (s, 2H), 8.51 (s, 2H), 7.93 (t, J=7.8 Hz, 2H), 7.71 (d, J=7.9 Hz, 4H), 7.44 (d, J=8.5 Hz, 2H), 6.73 (d, J=8.5 Hz, 2H), 2.69 (dt, J=13.7, 6.9 Hz, 4H), 1.36 (d, J=6.8 Hz, 12H), 1.18 (d, J=6.8 Hz, 12H). ¹³C NMR (126 MHz, CD₂Cl₂) δ/ppm 189.43, 151.88, 146.95, 141.89, 140.12, 131.70, 130.40, 128.06, 124.97, 124.83, 123.23, 120.89, 114.51, 99.90, 29.60, 24.06, 23.73.

Au7: ¹H NMR (500 MHz, acetone-d₆) δ/ppm 8.75 (s, 2H), 8.28 (s, 1H), 7.95-7.80 (m, 3H), 7.85-7.69 (m, 5H), 7.42 (d, J=7.5 Hz, 1H), 7.24 (t, J=7.5 Hz, 1H), 7.14 (t, J=7.5 Hz, 1H), 6.98 (t, J=8.0 Hz, 1H), 6.85 (t, J=7.0 Hz, 1H), 6.65 (d, J=8.0 Hz, 1H), 2.74-2.65 (m, 4H), 1.44 (s, 6H), 1.40 (d, J=7.0 Hz, 12H), 1.18 (d, J=7.0 Hz, 12H).

Au8: ¹H NMR (500 MHz, acetone-d₆) δ/ppm 8.65 (dd, J=4.7, 1.2 Hz, 1H), 8.00 (dd, J=8.1, 1.2 Hz, 1H), 7.93 (d, J=1.8 Hz, 2H), 7.82 (t, J=7.8 Hz, 1H), 7.68 (dd, J=8.1, 4.8 Hz, 1H), 7.63 (d, J=7.9 Hz, 2H), 7.56 (s, 2H), 7.08 (dd, J=8.5, 2.0 Hz, 2H), 6.66 (d, J=8.5 Hz, 2H), 3.24 (dt, J=13.8, 6.9 Hz,1H), 2.63 (tt, J=13.7, 6.9 Hz, 4H), 1.50 (d, J=6.9 Hz, 6H), 1.38 (t, J=6.9 Hz, 12H), 1.35 (s, 18H), 1.21 (d, J=6.9 Hz, 6H), 1.17 (d, J=6.9 Hz, 6H). ¹³C NMR (126 MHz, acetone-d₆) δ/ppm 189.11, 153.17, 148.99, 147.94, 147.77, 139.02, 132.48, 131.90, 130.26, 128.71, 125.33, 124.77, 123.72, 122.18, 122.01, 121.60, 115.81, 113.74, 35.52, 35.00, 32.67, 24.93, 24.66, 24.52, 24.42, 24.19.

Au9: ¹H NMR (500 MHz, acetone-d₆) δ/ppm 8.66 (dd, J=4.7, 1.1 Hz, 1H), 8.02 (dd, J=8.1, 1.1 Hz, 1H), 7.91-7.81 (m, 2H), 7.70 (dd, J=8.2, 4.7 Hz, 1H), 7.64 (d, J=7.9 Hz, 2H), 7.61-7.53 (m, 3H), 7.02 (t, J=7.2 Hz, 1H), 6.83 (t, J=7.3 Hz, 1H), 6.81-6.76 (m, 1H), 6.73 (d, J=8.2 Hz, 1H), 6.61 (dd, J=8.8, 4.6 Hz, 1H), 3.23 (dq, J=14.0, 7.0 Hz, 1H), 2.62 (tt, J=13.6, 6.8 Hz, 4H), 1.49 (d, J=6.9 Hz, 6H), 1.36 (dd, J=11.9, 6.9 Hz, 12H), 1.19 (dd, J=20.0, 6.9 Hz, 12H). ¹⁹F NMR (471 MHz, acetone-d₆) δ/ppm -129.97. ¹³C NMR (126 MHz, acetone-d₆) δ/ppm 188.42, 157.63, 155.81, 153.29, 151.43, 148.02, 147.92, 147.87, 147.80, 146.74, 132.47, 131.96, 130.17, 128.69, 125.39, 124.98, 124.80, 124.72, 124.65, 124.61, 123.70, 122.30, 121.74, 120.43, 116.86, 114.58, 114.52, 114.45, 111.85, 111.65, 105.07, 104.88, 35.48, 24.91, 24.58, 24.54, 24.40, 24.22.

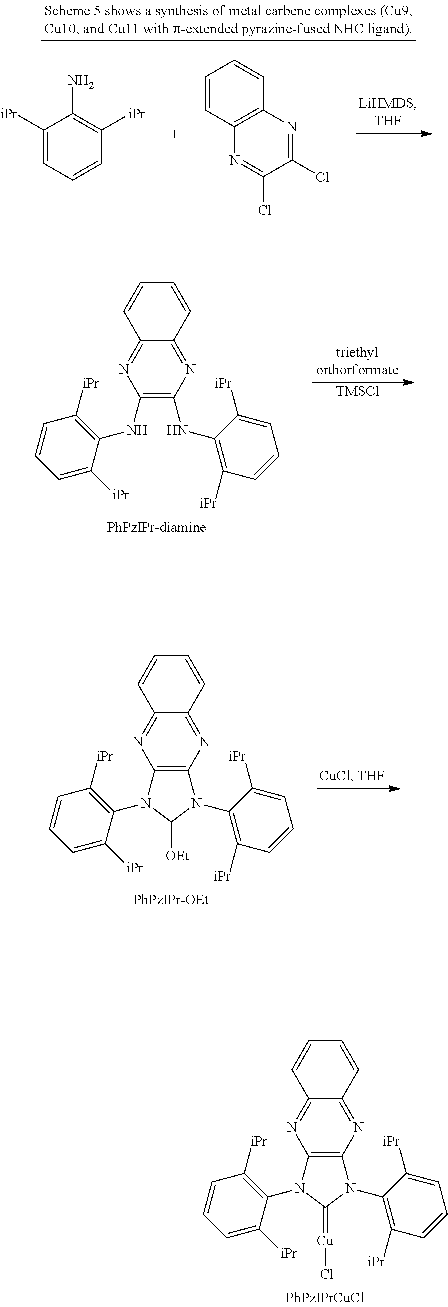

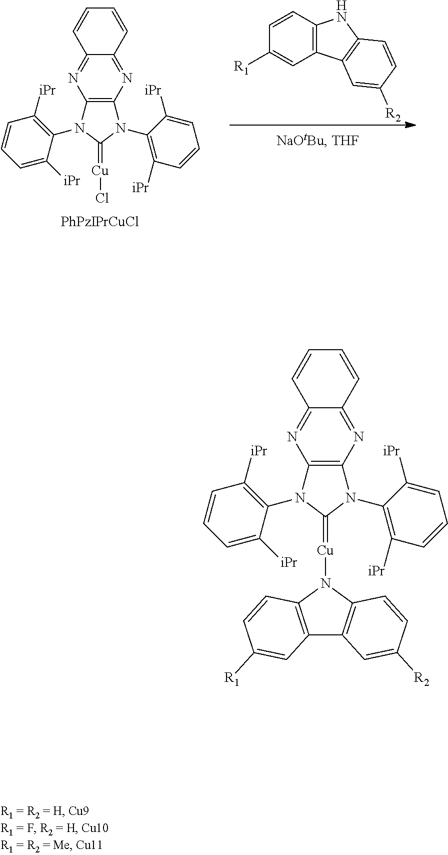

Cu9: ¹H NMR (500 MHz, acetone-d₆) δ/ppm 8.23 (dd, J=6.5, 3.5 Hz, 2H), 8.00-7.96 (m, 2H), 7.95 (t, J=7.9 Hz, 2H), 7.82 (d, J=7.6 Hz, 2H), 7.74 (d, J=7.9 Hz, 4H), 6.96-6.90 (m, 2H), 6.83-6.77 (m, 2H), 6.28 (d, J=8.1 Hz, 2H), 2.86 (dt, J=13.7, 6.8 Hz, 4H), 1.30 (d, J=6.9 Hz, 12H), 1.19 (d, J=6.8 Hz, 12H).

Cu10: ¹H NMR (500 MHz, CD₂Cl₂) δ/ppm 8.27 (dd, J=6.5, 3.5 Hz, 2H), 7.95-7.86 (m, 4H), 7.80 (d, J=7.6 Hz, 1H), 7.64 (d, J=7.9 Hz, 4H), 7.50 (dd, J=9.5, 2.5 Hz, 1H), 6.99 (t, J=7.1 Hz, 1H), 6.85 (t, J=7.3 Hz, 1H), 6.77-6.71 (m, 1H), 6.23 (d, J=8.1 Hz, 1H), 6.09 (dd, J=8.8, 4.5 Hz, 1H), 2.60 (dt, J=13.6, 6.7 Hz, 4H), 1.27 (d, J=6.9 Hz, 12H), 1.19 (d, J=6.8 Hz, 12H).

Cu11: ¹H NMR (500 MHz, CD₂Cl₂) δ/ppm 8.26 (dd, J=6.4, 3.5 Hz, 2H), 7.93-7.85 (m, 4H), 7.68-7.59 (m, 4H), 6.79 (d, J=7.6 Hz, 2H), 6.09 (d, J=8.2 Hz, 2H), 2.60 (dt, J=13.6, 6.8 Hz, 4H), 1.27 (d, J=6.8 Hz, 12H), 1.19 (d, J=6.8 Hz, 12H).

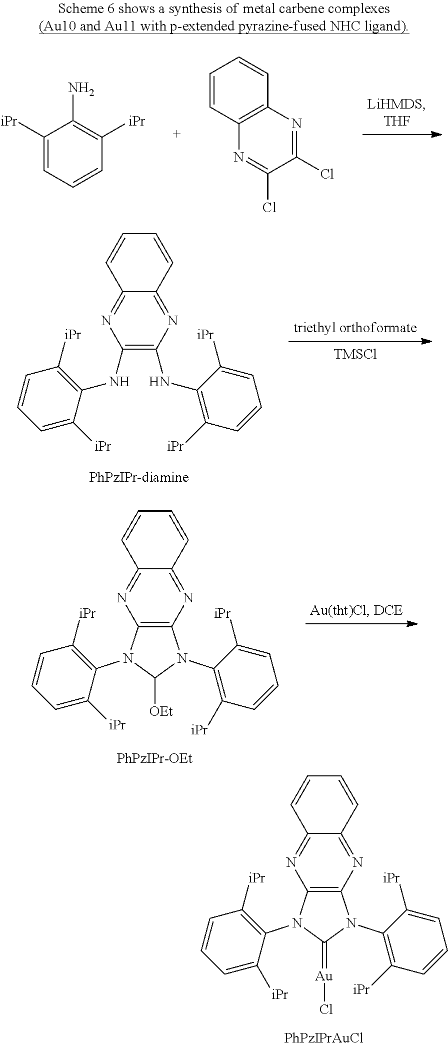

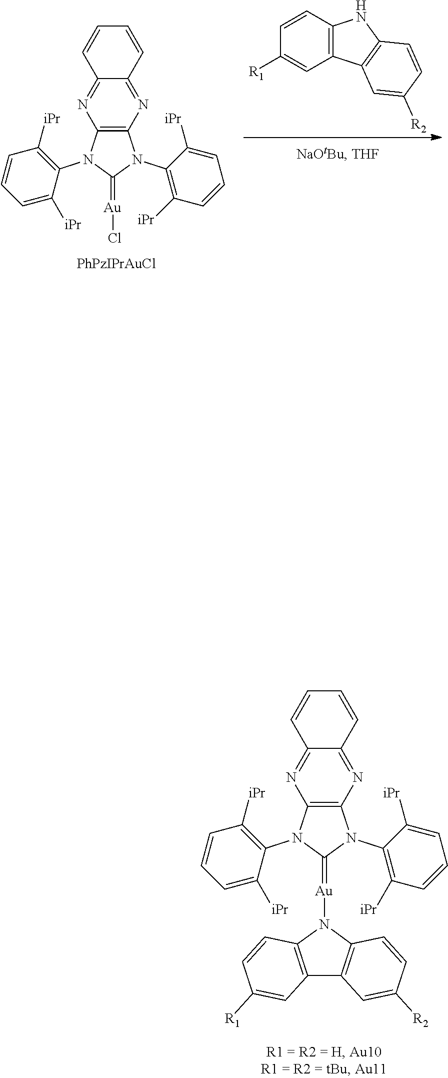

Au10: ¹H NMR (500 MHz, CD₂Cl₂) δ/ppm 8.26 (dd, J=6.4, 3.5 Hz, 1H), 7.89 (ddd, J=20.1, 11.2, 5.6 Hz, 3H), 7.62 (d, J=7.9 Hz, 2H), 7.06 (t, J=7.4 Hz, 1H), 6.90 (t, J=7.3 Hz, 1H), 6.61 (d, J=8.1 Hz, 1H), 2.60 (dt, J=13.6, 6.8 Hz, 2H), 1.36 (d, J=6.8 Hz, 7H), 1.18 (d, J=6.8 Hz, 7H).¹³C NMR (126 MHz, CD₂Cl₂) δ/ppm 198.43, 149.76, 147.78, 141.36, 140.88, 132.14, 131.37, 130.90, 129.76, 125.44, 124.37, 124.20, 119.75, 116.87, 113.97, 30.25, 24.61, 24.42.

Au11: ¹H NMR (400 MHz, CD₂Cl₂) δ/ppm 8.26 (dd, J=6.5, 3.5 Hz, 2H), 7.94-7.83 (m, 6H), 7.62 (d, J=7.9 Hz, 4H), 7.12 (dd, J=8.5, 1.8 Hz, 2H), 6.53 (d, J=8.5 Hz, 2H), 2.60 (dt, J=13.7, 6.8 Hz, 4H), 1.38 (s, 18H), 1.37 (d, J=7.0 Hz, 12H), 1.18 (d, J=6.8 Hz, 12H).¹³C NMR (101 MHz, CD₂Cl₂) δ/ppm 198.71, 148.28, 147.74, 141.33, 140.94, 139.53, 132.12, 131.38, 130.82, 129.73, 125.41, 124.16, 121.96, 115.67, 113.26, 34.91, 32.50, 30.24, 24.66, 24.42.

The structures of Cu7-Cu11 and Au5-Aull are shown below:

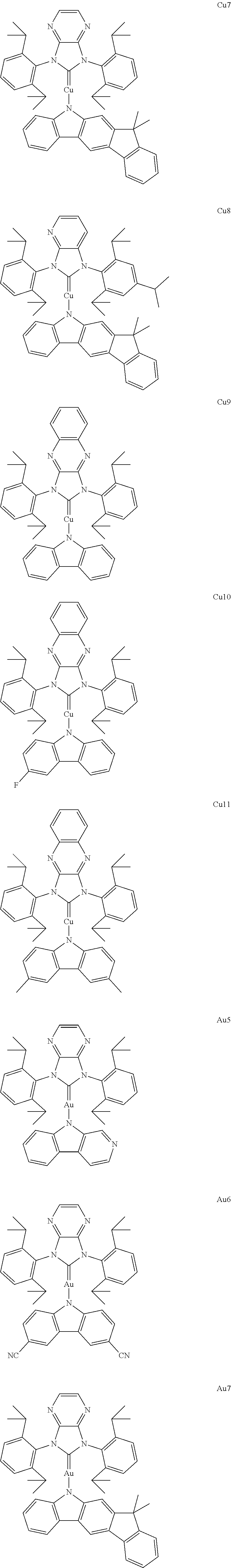

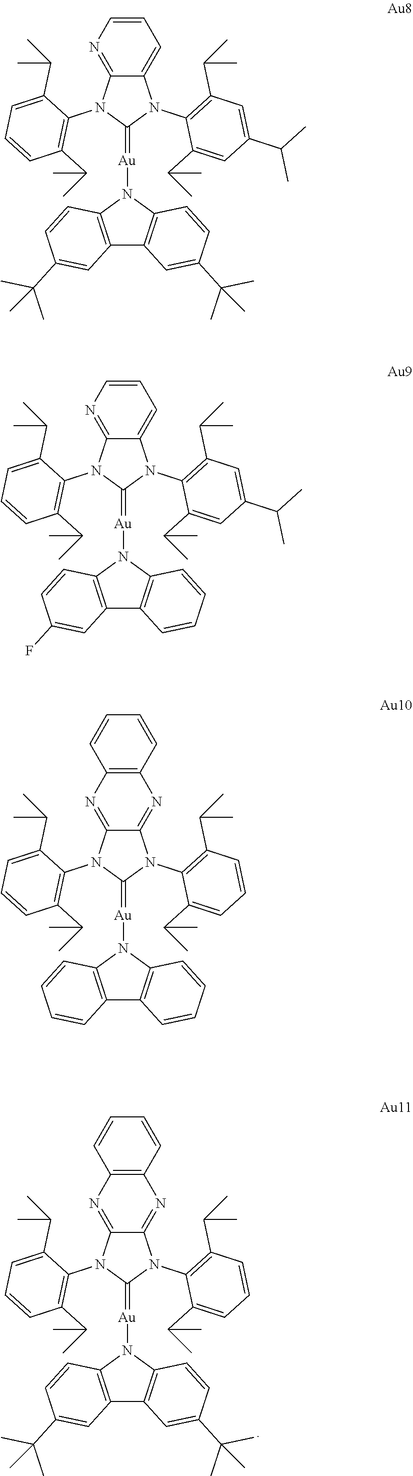

### Results

The results of the instant work are presented below. The photophysical properties of complexes can be evaluated by maximum emission wavelength (λₑₘ), emission lifetime (τₑₘ), emission quantum yield (Φₑₘ), radiative decay rate (kᵣ), and non-radiative decay rate (kₙᵣ). The tem values of complexes in degassed toluene and MCP (1,3-bis(N-carbazolyl)benzene) thin films were directly obtained by absolute measurement using Hamamatsu C11347 Quantaurus-QY Absolute PL quantum yield spectrometer (PL stands for photoluminescence). Maximum emission wavelength λₑₘ, are read from the emission spectra. The emission lifetime (τₑₘ) measurement was performed on a Quanta Ray GCR 150-10 pulsed Nd:YAG laser system (pulse output: 355 nm). The intensity of emission decay was monitored as a function of time.

$$I ( t ) = {I}_{0} {e}^{- t / τ}$$

I₀ is the initial emission intensity, I(t) is the emission intensity at time t, τ is the emission lifetime and t is the time. The emission lifetime was determined by fitting the exponential decay using Origin software. The kᵣ and kₙᵣ of complex can be calculated using equations kᵣ=Φₑₘ and kₙᵣ=(1-Φₑₘ)/τₑₘ, respectively.
Photophysical characterization of the compounds

TABLE 1
Summary of photophysical properties measured in different media

| | | | | | |
|---|---|---|---|---|---|
| Complex | λₑₘ/nm | τₑₘ/μs | Φₑₘ | kᵣ(×10⁵)/s⁻¹ | kₙᵣ(×10⁵)/s⁻¹ |

Degassed toluene at 298 K

| | | | | | |
|---|---|---|---|---|---|
| Cu1 | 620 | 0.18 | 0.29 | 16.1 | 39.4 |
| Cu2 | 555 | 0.36 | 0.58 | 16.1 | 11.6 |
| Cu3 | 660 | 0.11^{a} | 0.14 | 12.7 | 78.2 |
| Cu4 | 635 | 0.12 | 0.15 | 12.2 | 70.8 |
| Cu6 | 502 | 0.55 | 0.74 | 13.5 | 4.7 |
| Cu9 | 721 | <0.1 | 0.13 | — | — |
| Au1 | 620 | 0.17 | 0.17 | 10.0 | 8.3 |
| Au2 | 550 | 0.33^{a} | 0.73 | 22.1 | 8.2 |
| Au3 | 553 | 0.45 | 0.53 | 11.7 | 10.4 |
| Au4 | 500 | 0.45 | 0.76 | 16.9 | 5.3 |
| Au5 | 570 | 0.36 | 0.60 | 16.6 | 11.1 |
| Au6 | 485 | 0.36 | 0.72 | 20.0 | 7.8 |
| Au8 | 526 | 0.54 | 0.75 | 13.9 | 4.6 |
| Au9 | 500 | 0.58 | 0.82 | 14.1 | 3.1 |
| Ag1 | 676 | <0.1 | 0.06 | — | — |

2 wt/wt % in MCP film at 298 K

| | | | | | |
|---|---|---|---|---|---|
| Cu1 | 576 | 0.42 | 0.80 | 19.0 | 4.8 |
| Cu2 | 525 | 0.41 | 0.89 | 21.7 | 2.7 |
| Cu3 | 610 | 0.39 | 0.58 | 14.9 | 10.8 |
| Cu4 | 568 | 0.36 | 0.76 | 21.1 | 6.6 |
| Cu5 | 525 | 0.44 | 0.40 | 9.1 | 13.6 |
| Cu9 | 637 | 0.35 | 0.67 | 19.1 | 9.4 |
| Cu10 | 630 | 0.34 | 0.61 | 17.9 | 11.5 |
| Cu11 | 677 | 0.27 | 0.39 | 14.4 | 22.6 |
| Au1 | 557 | 0.33 | 0.92 | 27.9 | 2.4 |
| Au2 | 516 | 0.27 | 0.80 | 29.6 | 7.4 |
| Au3 | 504 | 0.47 | 0.69 | 14.6 | 6.6 |
| Au10 | 642 | 0.32 | 0.69 | 21.6 | 9.7 |
| Au11 | 685 | 0.27 | 0.51 | 18.8 | 18.1 |
| Ag1 | 565 | 0.23 | 0.72 | 31.3 | 12.2 |

5 wt/wt % in MCP film at 298 K

| | | | | | |
|---|---|---|---|---|---|
| Cu6 | 470 | 0.47 | 0.52 | 11.1 | 10.2 |
| Cu7 | 592 | 0.32 | 0.76 | 23.8 | 7.5 |
| Cu8 | 491 | 0.77^{a} | 0.51 | 6.6 | 6.4 |
| Cu9 | 651 | 0.32 | 0.57 | 17.8 | 13.4 |
| Cu10 | 653 | 0.27 | 0.54 | 20.0 | 17.0 |
| Cu11 | 709 | 0.20 | 0.29 | 14.5 | 35.5 |
| Au10 | 658 | 0.29 | 0.73 | 25.2 | 9.3 |
| Au11 | 706 | 0.23 | 0.41 | 17.8 | 25.7 |

2 wt/wt % in PMMA film at 298 K

| | | | | | |
|---|---|---|---|---|---|
| Au4 | 468 | 0.75^{a} | 0.74 | 9.9 | 3.5 |
| Au5 | 520 | 0.56 | 0.96 | 17.1 | 0.7 |
| Au6 | 466 | 0.70^{a} | 0.43 | 6.1 | 8.1 |
| Au7 | 568 | 0.24 | 0.47 | 19.6 | 22.1 |
| Au8 | 480 | 0.64 | 0.85 | 13.3 | 2.3 |
| Au9 | 470 | 1.23^{a} | 0.63 | 5.1 | 3.0 |

2-MeTHF at 77 K

| Cu1 | 500 | 185 | — | — | — |
|---|---|---|---|---|---|
| Cu2 | 429 {398 (60%), | | — | — | — |
| | 2063 (40%)}, | | | | |
| | 455 (250) | | | | |
| Cu3 | 535 | 104 | — | — | — |
| Cu6 | 429 | 4000 | — | — | — |
| Au1 | 497 | 78 | — | — | — |
| Au2 | 424 (162.4), | | — | — | — |
| | 450 (75.9) | | | | |
| Au3 | 428 (1122), 455 | | — | — | — |
| | {78 (95%), | | | | |
| | 984 (5%)} | | | | |
| Au4 | 424 | 268 | — | — | — |
| Au5 | 473 | 505 | — | — | — |
| Au6 | 418 | 278 | — | — | — |
| Au8 | 427 (201), 436 (212), | | — | — | — |
| | 452 {62(58%), | | | | |
| | 280 (42%)} | | | | |
| Au9 | 441 (660); | | — | — | — |
| | 470 (730) | | | | |
| Ag1 | 504 | 2.2 | — | — | — |

^{a}weighted average lifetime

TABLE 2
Device data for Cu1

| | | CE [cd A⁻¹] | | PE [lm W⁻¹] | | EQE [%] | | | |
|---|---|---|---|---|---|---|---|---|---|
| | Lₘₐₓ | | at 1000 | | at 1000 | | at 1000 | CIE | λₘₐₓ |
| Cu1 | [cd m⁻²] | Max | cd m⁻² | Max | cd m⁻² | Max | cd m⁻² | (x, y) | [nm] |
| 2 wt/wt % | 153400 | 60.00 | 55.83 | 62.83 | 42.48 | 20.00 | 18.65 | (0.43, 0.55) | 556 |
| 6 wt/wt % | 177400 | 48.48 | 45.75 | 50.78 | 31.94 | 18.76 | 17.72 | (0.49, 0.50) | 573 |
| 8 wt/wt % | 222200 | 44.69 | 43.66 | 46.20 | 29.06 | 18.72 | 18.31 | (0.51, 0.48) | 582 |

TABLE 3
Device lifetime measurement for Cu1. Device structure: ITO/HAT-CN
(5 nm)/PT-301 (160 nm)/PT-603I (5 nm)/Cu1:LLP604 (20 nm)/PT74M
(5 nm)/LET321:Liq (1:1, 25 nm)/Liq (1 nm)/Al (100 nm)

| | 1 mA cm⁻² | | 3 mA cm⁻² | | 5 mA cm⁻² | | | LT@1000 cd m⁻² | |
|---|---|---|---|---|---|---|---|---|---|
| | L₀ | LT50 | L₀ | LT50 | L₀ | LT50 | | LT90 | LT50 |
| Conc. | [cd m⁻²] | [h] | [cd m⁻²] | [h] | [cd m⁻²] | [h] | n | [h] | [h] |
| 2 wt/wt % | 5200 | 396.6 | 13000 | 59 | 20000 | 28.02 | 1.97 | 362 | 9233 |
| 4 wt/wt % | 4300 | 500 | 11000 | 79.3 | 17000 | 35.2 | 1.94 | 410 | 8326 |
| 6 wt/wt % | 4000 | 1000 | 10000 | 82.7 | 16000 | 37.41 | 2.01 | 415 | 8462 |

n denotes for acceleration factor in LT(L₁) = LT(L₀) × (L₀/L₁)ⁿ

TABLE 4
Device data for Cu2

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Cu2 | [cd m⁻²] | Max | cd m⁻² | Max | cd m⁻² | Max | cd m⁻² | (x, y) | [nm] |
| 2 wt/wt % | 12100 | 49.49 | 41.55 | 38.87 | 23.69 | 21.13 | 17.68 | (0.19, 0.42) | 492 |
| 4 wt/wt % | 14400 | 53.37 | 48.02 | 39.72 | 27.16 | 20.76 | 18.63 | (0.22, 0.46) | 495 |
| 6 wt/wt % | 17300 | 57.22 | 49.96 | 48.76 | 26.20 | 20.89 | 18.22 | (0.25, 0.51) | 504 |

TABLE 5a
Device lifetime measurement for Cu2. Device structure: ITO/HAT-CN
(5 nm)/PT-301 (160 nm)/PT-603I (5 nm)/Cu2:LLP604 (20 nm)/PT74M
(5 nm)/LET321:Liq (1:1, 25 nm)/Liq (1 nm)/Al (100 nm)

| | 1 mA cm⁻² | | 3 mA cm⁻² | | 5 mA cm⁻² | | | LT@1000 cd m⁻² | |
|---|---|---|---|---|---|---|---|---|---|
| | L₀ | LT50 | L₀ | LT50 | L₀ | LT50 | | LT90 | LT50 |
| Conc. | [cd m⁻²] | [h] | [cd m⁻²] | [h] | [cd m⁻²] | [h] | n | [h] | [h] |
| 2 wt/wt % | 3600 | 132 | 11000 | 31.13 | 19500 | 14.14 | 1.32 | 52.97 | 713.4 |
| 4 wt/wt % | 4500 | 112 | 12300 | 26.4 | 21000 | 12.2 | 1.44 | 64.94 | 978.0 |

n denotes for acceleration factor in LT(L₁) = LT(L₀) × (L₀/L₁)ⁿ

TABLE 5b
Device data for Cu2 (same device structure as Table 5a)

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Cu2 | [cd m⁻²] | Max | cd m⁻² | Max | cd m⁻² | Max | cd m⁻² | (x, y) | [nm] |
| 2 wt/wt % | 210000 | 51.54 | 49.69 | 63.89 | 44.98 | 16.15 | 15.60 | (0.30, 0.57) | 512 |

TABLE 6
Device data for Cu3

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Cu3 | [cd m⁻²] | Max | cd m⁻² | Max | cd m⁻² | Max | cd m⁻² | (x, y) | [nm] |
| 2 wt/wt % | 72500 | 30.63 | 24.94 | 32.08 | 11.73 | 16.51 | 13.44 | (0.54, 0.45) | 601 |
| 4 wt/wt % | 46400 | 19.49 | 14.83 | 17.87 | 5.82 | 14.48 | 11.02 | (0.59, 0.41) | 622 |
| 6 wt/wt % | 35000 | 15.92 | 11.37 | 14.47 | 4.17 | 13.81 | 9.87 | (0.60, 0.40) | 624 |

TABLE 7
Device lifetime measurement for Cu3. Device structure: ITO/HAT-CN
(5 nm)/PT-301 (160 nm)/PT-603I (5 nm)/Cu3: LLP604 (20 nm)/PT74M
(5 nm)/LET321: Liq (1:1, 25 nm)/Liq (1 nm)/Al (100 nm).

| | |
|---|---|
| 1 mA cm⁻² | LT@1000 cd m⁻² |

| | L₀ | LT90 | | LT95 | LT90 |
|---|---|---|---|---|---|
| Conc. | [cd m⁻²] | [h] | n | [h] | [h] |
| 1 wt/wt % | 2600 | 75.2 | 1.78 | 161 | 412 |
| 2 wt/wt % | 2600 | 101 | 1.78 | 236 | 553 |
| 4 wt/wt % | 1880 | 146 | 1.78 | 157 | 450 |

n denotes for acceleration factor in LT(L₁) = LT(L₀) × (L₀/L₁)ⁿ

TABLE 8
Device data for Au1

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Au1 | [cd m⁻²] | Max | cd m⁻² | Max | cd m⁻² | Max | cd m⁻² | (x, y) | [nm] |
| 2 wt/wt % | 176000 | 61.63 | 61.05 | 72.83 | 45.19 | 19.66 | 19.47 | (0.42, 0.55) | 554 |
| 4 wt/wt % | 198000 | 60.29 | 57.26 | 72.07 | 39.98 | 21.28 | 20.21 | (0.47, 0.52) | 566 |
| 6 wt/wt % | 202200 | 52.37 | 51.93 | 56.29 | 35.53 | 16.70 | 16.26 | (0.49, 0.50) | 572 |

TABLE 9
Device lifetime measurement for Au1. Device structure: ITO/HAT-CN
(5 nm)/PT-301 (160 nm)/PT-603I (5 nm)/Au1:LLP604 (30 nm)/PT74M
(5 nm)/LET321:Liq (1:1, 25 nm)/Liq (1 nm)/Al (100 nm)

| | 1 mA cm⁻² | | 3 mA cm⁻² | | 5 mA cm⁻² | | | LT@1000 cd m⁻² | |
|---|---|---|---|---|---|---|---|---|---|
| | L₀ | LT50 | L₀ | LT50 | L₀ | LT50 | | LT90 | LT50 |
| Conc. | [cd m⁻²] | [h] | [cd m⁻²] | [h] | [cd m⁻²] | [h] | n | [h] | [h] |
| 2 wt/wt % | 3600 | 135 | 11000 | 19.7 | 17000 | 8.96 | 1.74 | 1278 | 15763 |
| 4 wt/wt % | 3200 | 76.1 | 8900 | 19.4 | 15000 | 9.68 | 1.33 | 355 | 3763 |
| 6 wt/wt % | 3400 | 80.7 | 11000 | 17.9 | 17000 | 10.2 | 1.29 | 395 | 4972 |
| 8 wt/wt % | 3300 | 69.3 | 11200 | 14.2 | 17000 | 8.76 | 1.27 | 305 | 3913 |

n denotes for acceleration factor in LT(L₁) = LT(L₀) × (L₀/L₁)ⁿ

TABLE 9a
Device lifetime measurement for Au1. Device structure:
ITO/HAT-CN (10 nm)/FSFA (60 nm)/NPB-BC (5 nm)/Au1:NPB-
BC:Al (30 nm)/ANT-Biz (5 nm)/ANT-Biz:Liq (1:1,
25 nm)/Liq (2 nm)/Al (100 nm).

| | | | LT@L₀ | | | LT@1000 cd m⁻² | |
|---|---|---|---|---|---|---|---|
| | | L₀ | LT97 | LT90 | | LT97 | LT90 |
| Conc. | | [cd m⁻²] | [h] | [h] | n | [h] | [h] |
| 6 | wt/wt % | 26000 | 4.63 | 18.3 | 1.7 | 1176 | 4648 |
| 10 | wt/wt % | 26000 | 3.87 | 20.0 | 1.7 | 984 | 5080 |

n denotes for acceleration factor in LT(L₁) = LT(L₀) × (L₀/L₁)ⁿ

TABLE 10
Device data for Au2 in Device structure (I)

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Au2 | [cd m⁻²] | Max | cd m⁻² | Max | cd m⁻² | Max | cd m⁻² | (x, y) | [nm] |
| 2 wt/wt % | 32600 | 52.47 | 41.36 | 58.87 | 29.53 | 18.05 | 14.22 | (0.26, 0.57) | 518 |
| 4 wt/wt % | 50100 | 61.54 | 53.15 | 66.17 | 39.08 | 20.49 | 17.73 | (0.28, 0.58) | 519 |
| 6 wt/wt % | 59100 | 59.82 | 53.87 | 66.95 | 39.34 | 18.55 | 16.76 | (0.29, 0.59) | 521 |

TABLE 11
Device data for Au2 in Device structure (II)

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Au2 | [cd m⁻²] | Max | cd m⁻² | Max | cd m⁻² | Max | cd m⁻² | (x, y) | [nm] |
| 2 wt/wt % | 10300 | 38.00 | 30.85 | 35.11 | 23.44 | 16.15 | 13.18 | (0.18, 0.35) | 488 |
| 4 wt/wt % | 13400 | 38.00 | 35.36 | 35.02 | 27.78 | 13.56 | 12.63 | (0.23, 0.45) | 496 |
| 8 wt/wt % | 22700 | 44.82 | 38.76 | 41.74 | 28.96 | 16.27 | 14.05 | (0.22, 0.45) | 494 |

TABLE 12
Comparison with other Au(I) emitters

| | | | Current | Current | Current |
|---|---|---|---|---|---|
| | Reported | Reported | data | data | data for |
| | Gold(I) | Gold(I) | for Gold(I), | for Gold(I), | for Gold(I), |
| | emitter | emitter | Au1 | Au2 | Au2 |
| CIE (x, y) | EL λₘₐₓ | EL λₘₐₓ | yellow | blue green | green |
| | ~510 nm | ~530 nm | (0.47, 0.52) | (0.22, 0.45) | (0.34, 0.55) |
| Maximum | 44700 | 73100 | 198000 | 22700 | 230000 |
| Brightness | | | | | |
| (cd/m²) | | | | | |
| Current | 73.0 | 77.9 | 57.3 | 38.8 | 51.7 |
| efficiency | | | | | |
| @1000 | | | | | |
| cd/m² | | | | | |
| (cd/A) | | | | | |
| Power | 37.0 | 35.5 | 40.0 | 29.0 | 54.1 |
| efficiency | | | | | |
| @1000 | | | | | |
| cd/m² | | | | | |
| (lm/W) | | | | | |
| External | 25.2 | 24.5 | 20.2 | 14.1 | 15.9 |
| quantum | | | | | |
| efficiency | | | | | |
| @1000 | | | | | |
| cd/m² | | | | | |
| (%) | | | | | |
| LT | @100 cd | NA | @1000 cd | NA | @1000 cd |
| | m⁻² | | m⁻² | | m⁻² |
| | LT95 ~2 h | | LT90 ~5080 h | | LT90 ~117 h |
| | | | | | LT50 ~1446 h |
| Reference | Science | Science | | | |
| | 2017, 356, 159-163; | 2017, 356, 159-163 | | | |
| | Nat | | | | |
| | commun | | | | |
| | 2020, 11, 1758 | | | | |

TABLE 13
Comparison with other Cu(I) emitters

| | Reported | Reported | Current | Current | Current |
|---|---|---|---|---|---|
| | Copper(I) | Copper(I) | data | data | data |
| | emitter | emitter | for Cu1 | for Cu2 | for Cu3 |
| CIE (x, y) | EL λₘₐₓ | EL λₘₐₓ | yellow | green | orange |
| | ~543 nm | ~505 nm | (0.43, 0.55) | (0.30, 0.57) | (0.58, 0.42) |
| Maximum | 54000 | 7790 | 153400; | 210000 | 155000 |
| Brightness | | | 222200 | | |
| (cd/m²) | | | | | |
| Current | NA | 29.0 | 55.8; | 49.69 | 21.3 |
| efficiency | | | 43.7 | | |
| @1000 | | | | | |
| cd/m² | | | | | |
| (cd/A) | | | | | |
| Power | NA | 9.3 | 42.5; | 44.98 | 12.4 |
| efficiency | | | 29.1 | | |
| @1000 | | | | | |
| cd/m² | | | | | |
| (lm/W) | | | | | |
| External | −19 | 9.2 | 18.7; | 15.60 | 13.8 |
| quantum | | | 18.3 | | |
| efficiency | | | | | |
| @1000 | | | | | |
| cd/m² | | | | | |
| (%) | | | | | |
| LT | NA | NA | @1000 cd | @1000 cd | @1000 cd |
| | | | m⁻² | m⁻² | m⁻² |
| | | | LT90 ~362 h | LT90 ~65 h | LT90 ~1160 h |
| | | | LT50 ~9230 h | LT50 ~978h | |
| Reference | J. Am. | Science | | | |
| | Chem. Soc. | 2017, 356, | | | |
| | 2019, 141, | 159-163 | | | |
| | 3576-3588 | | | | |

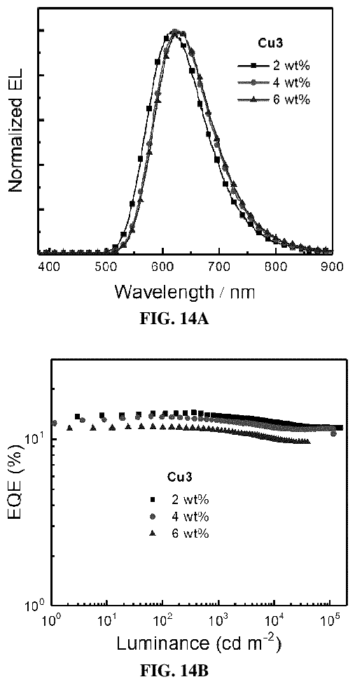

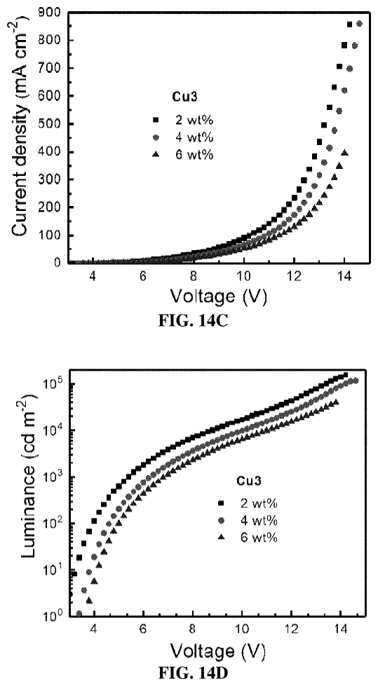

TABLE 14
Device data for Cu3 in Device structure (II): ITO/HAT-CN (5 nm)/PT-
301 (160 nm)/EB (5 nm)/Cu3:RH (40 nm)/HB (5 nm)/ZADN:Liq (35:65,
35 nm)/Liq (1 nm)/Al (100 nm). (cf. FIGS. 14A-14D)

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Cu3 | [cd m⁻²] | Max | cd m⁻² | Max | cd m⁻² | Max | cd m⁻² | (x, y) | [nm] |
| 2 wt/wt % | 155000 | 22.11 | 21.29 | 21.98 | 12.39 | 14.35 | 13.82 | (0.58, 0.42) | 619 |
| 4 wt/wt % | 117000 | 17.28 | 16.28 | 14.45 | 8.12 | 13.72 | 12.93 | (0.61, 0.39) | 627 |
| 6 wt/wt % | 40000 | 14.16 | 13.46 | 11.90 | 6.13 | 11.85 | 11.26 | (0.61, 0.39) | 628 |

TABLE 15
Device lifetime measurement for Cu3. Device structure (II):
ITO/HAT-CN (5 nm)/PT-301 (160 nm)/EB (5 nm)/Cu3:RH (40 nm)/HB
(5 nm)/ZADN:Liq (35:65, 35 nm)/Liq (1 nm)/Al (100 nm)

| | 5 mA cm⁻² | | | | LT@1000 cd m⁻² | |
|---|---|---|---|---|---|---|
| | L₀ | LT95 | LT90 | | LT95 | LT90 |
| Conc. | [cd m⁻²] | [h] | [h] | n | [h] | [h] |
| 2 wt/wt % | 9800 | 13.3 | 32.3 | 1.57 | 478 | 1160 |

n denotes for acceleration factor in LT(L₁) = LT(L₀) × (L₀/L₁)ⁿ

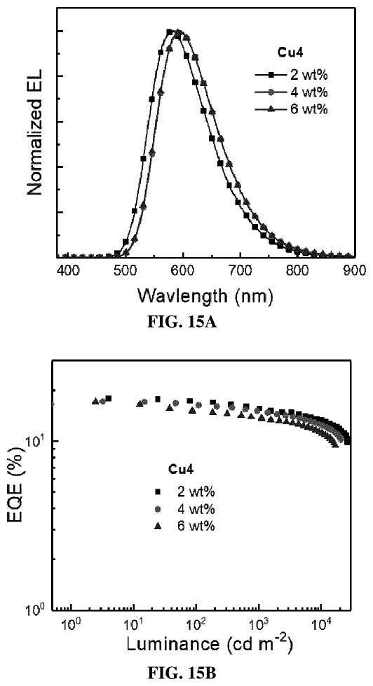

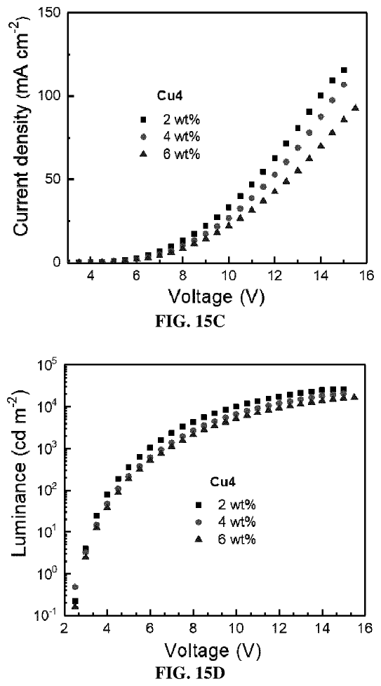

TABLE 16
Device data for Cu4 in Device structure (I): ITO/HAT-CN
(5 nm)/TAPC (40 nm)/TCTA (10 nm)/TCTA:TPBi:Cu4 (20 nm)/TPBi
(50 nm)/LiF (1 nm)/Al (100 nm). (cf FIGS. 15A-15D)

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Cu4 | [cd m⁻²] | Max | cd m⁻² | Max | cd m⁻² | Max | cd m⁻² | (x, y) | [nm] |
| 2 wt/wt % | 26300 | 40.99 | 35.74 | 46.00 | 18.71 | 17.95 | 15.65 | (0.50, 0.49) | 580 |
| 4 wt/wt % | 21000 | 32.51 | 28.59 | 39.37 | 13.82 | 17.23 | 15.15 | (0.54, 0.46) | 595 |
| 6 wt/wt % | 16800 | 32.67 | 26.30 | 33.11 | 12.27 | 17.15 | 13.88 | (0.54, 0.46) | 593 |

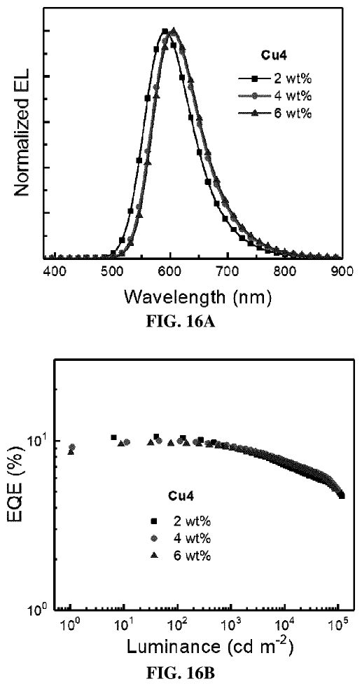

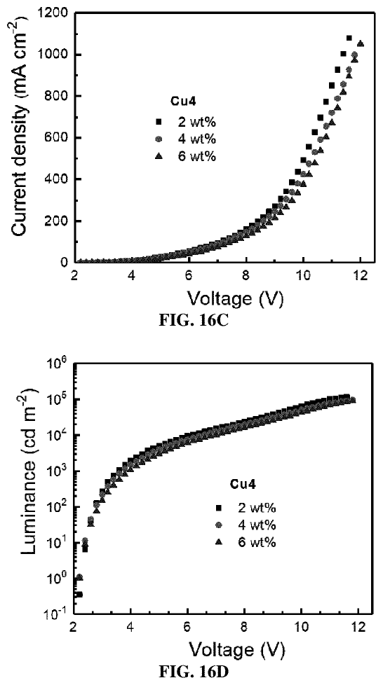

TABLE 17
Device data for Cu4 in Device structure (II): ITO/HAT-CN (5 nm)/PT-
301 (160 nm)/PT-603I (5 nm)/Cu4:LLP604 (20 nm)/PT74M (5 nm)/LET321:Liq
(1:1, 25 nm)/Liq (1 nm)/Al (100 nm). (cf. FIGS. 16A-16D)

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Cu4 | [cd m⁻²] | Max | cd m⁻² | Max | cd m⁻² | Max | cd m⁻² | (x, y) | [nm] |
| 2 wt/wt % | 118000 | 24.46 | 21.20 | 31.71 | 18.47 | 10.57 | 9.15 | (0.53, 0.46) | 593 |
| 4 wt/wt % | 97000 | 18.82 | 17.51 | 24.70 | 14.45 | 9.98 | 9.33 | (0.57, 0.43) | 603 |
| 6 wt/wt % | 91000 | 17.43 | 16.25 | 22.43 | 12.92 | 9.69 | 9.05 | (0.58, 0.42) | 604 |

TABLE 18
Device lifetime measurement for Cu4. Device structure
(II): ITO/HAT-CN (5 nm)/PT-301 (160 nm)/PT-603I
(5 nm)/Cu4:LLP604 (20 nm)/PT74M (5 nm)/LET321:Liq
(1:1, 25 nm)/Liq (1 nm)/Al (100 nm).

| | 1 mA cm⁻² | | | | LT@1000 cd m⁻² | |
|---|---|---|---|---|---|---|
| | L₀ | LT95 | LT90 | | LT95 | LT90 |
| Conc. | [cd m⁻²] | [h] | [h] | n | [h] | [h] |
| 2 wt/wt % | 1400 | 15.2 | 53.3 | 1.80 | 27.9 | 79.5 |
| 4 wt/wt % | 1100 | 6.69 | 41.4 | 1.48 | 7.71 | 47.6 |
| 6 wt/wt % | 1000 | 4.01 | 27.8 | 1.22 | 4.01 | 27.8 |

n denotes for acceleration factor in LT(L₁) = LT(L₀) × (L₀/L₁)ⁿ

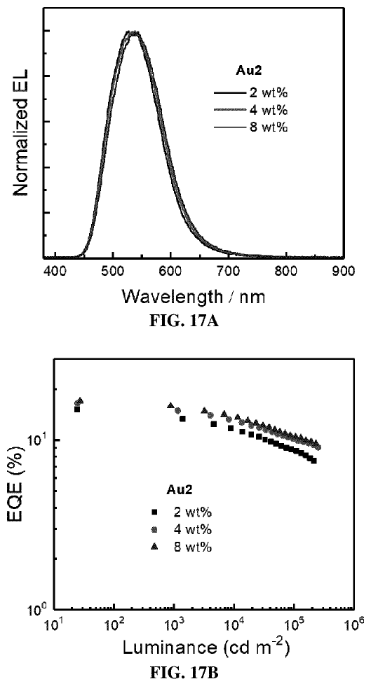

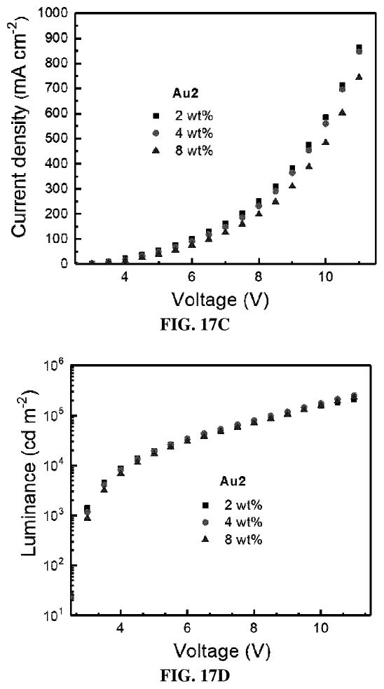

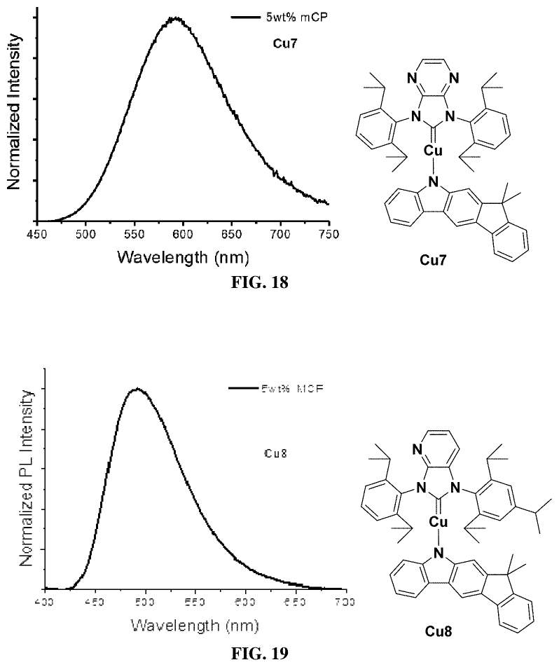

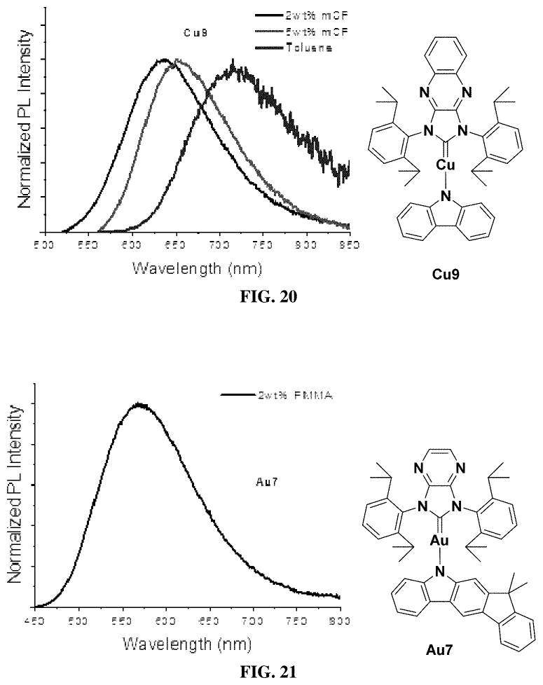

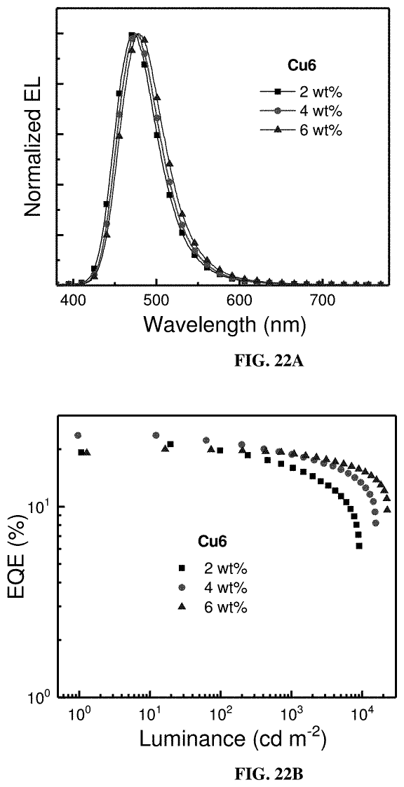

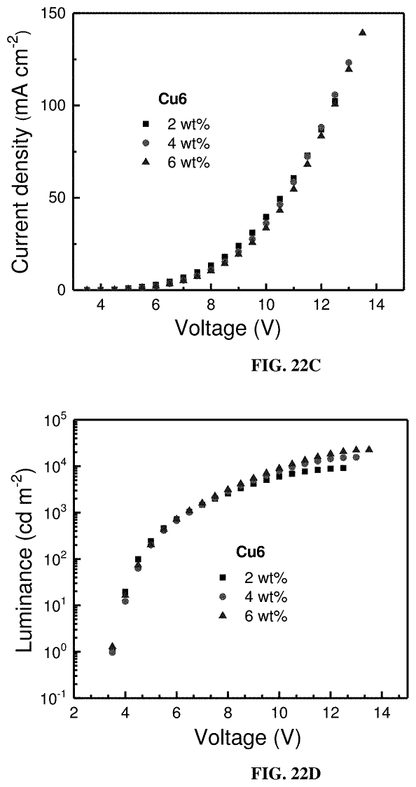

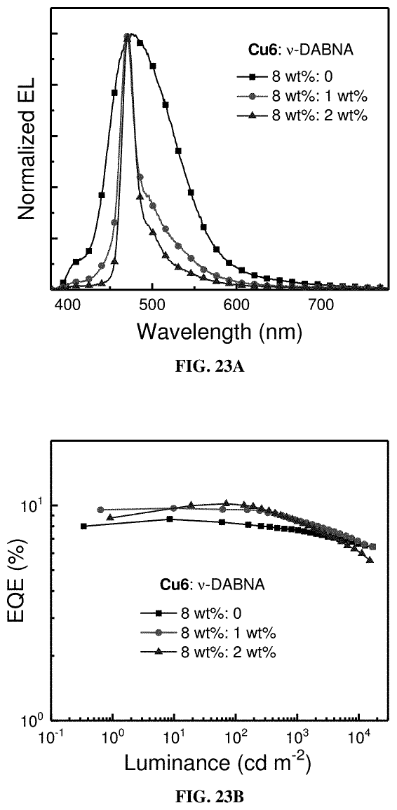

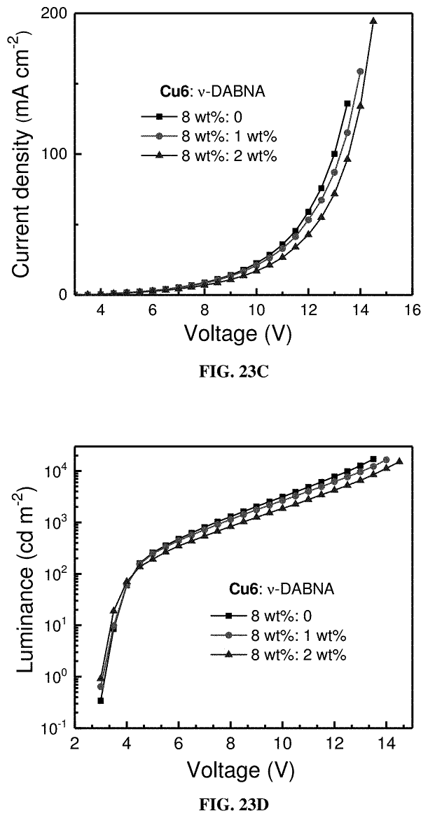

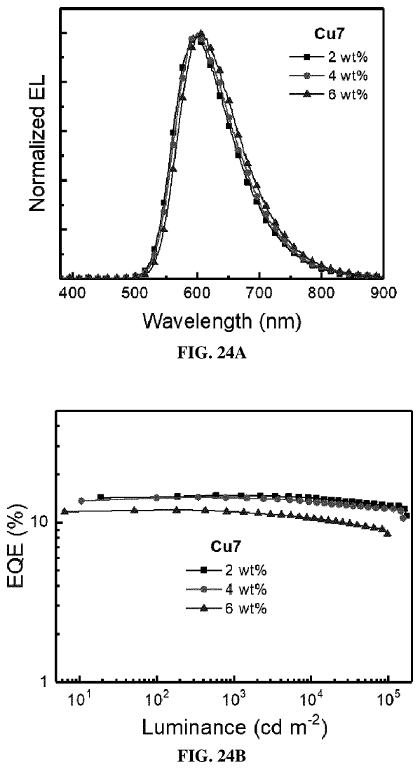

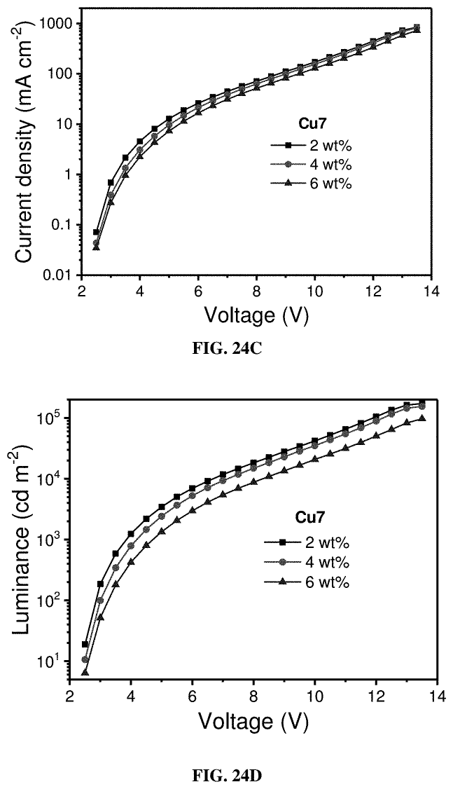

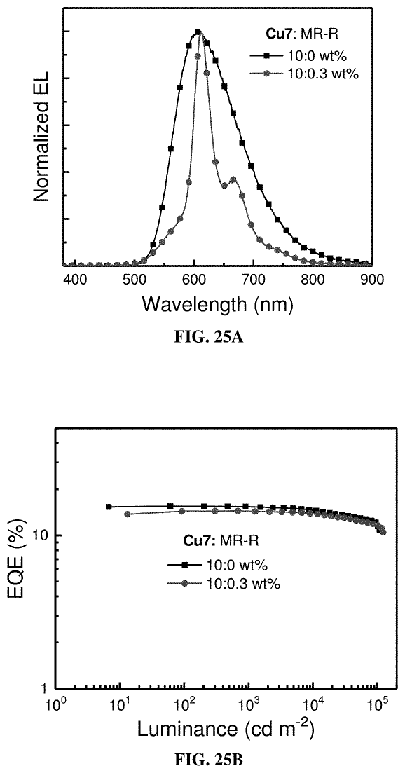

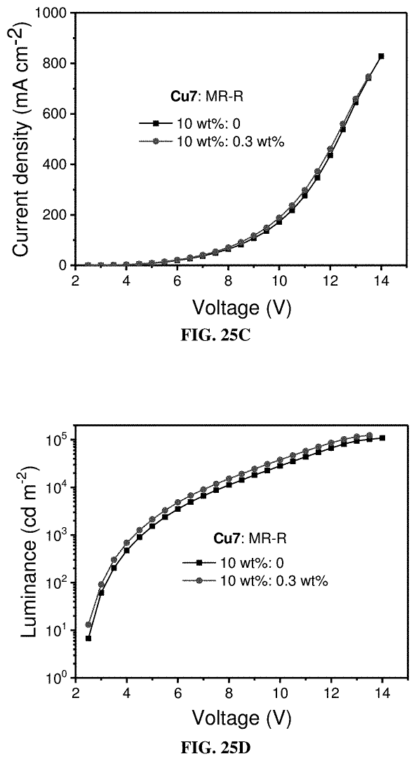

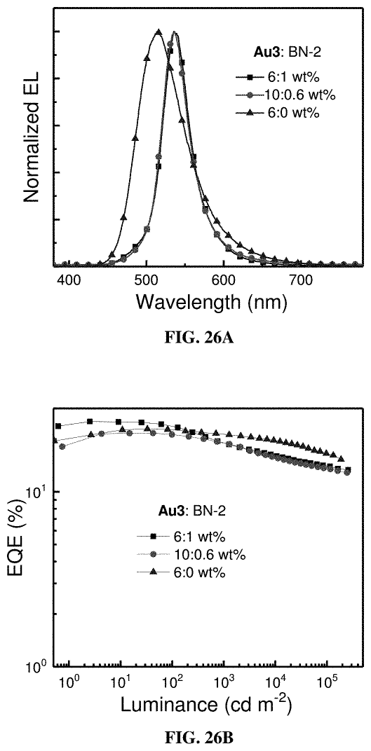

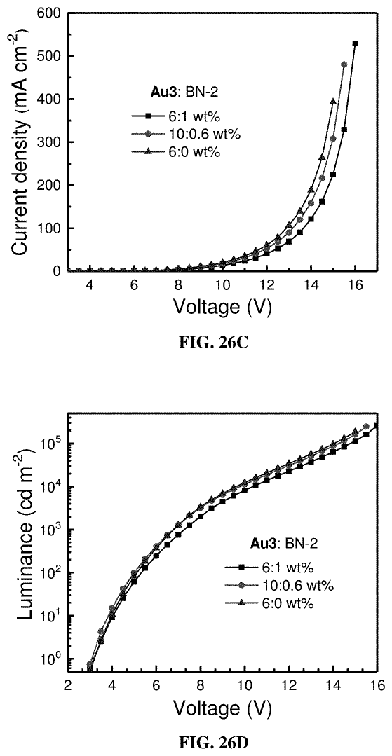

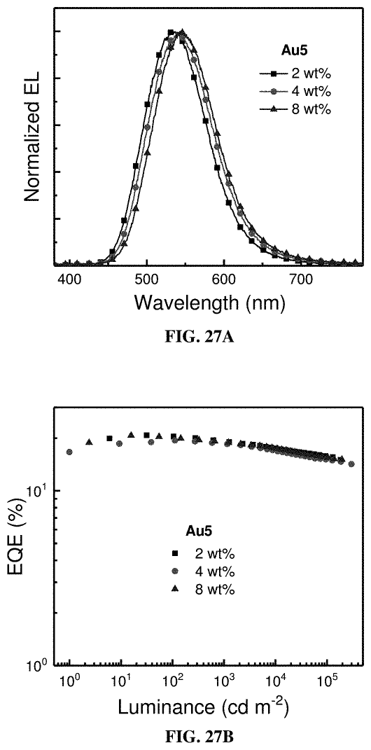

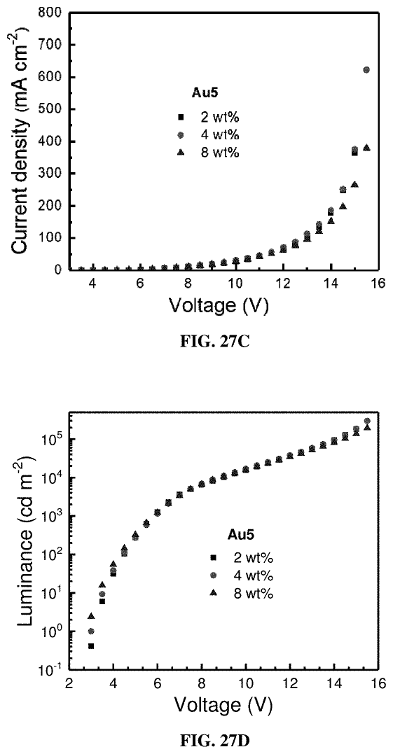

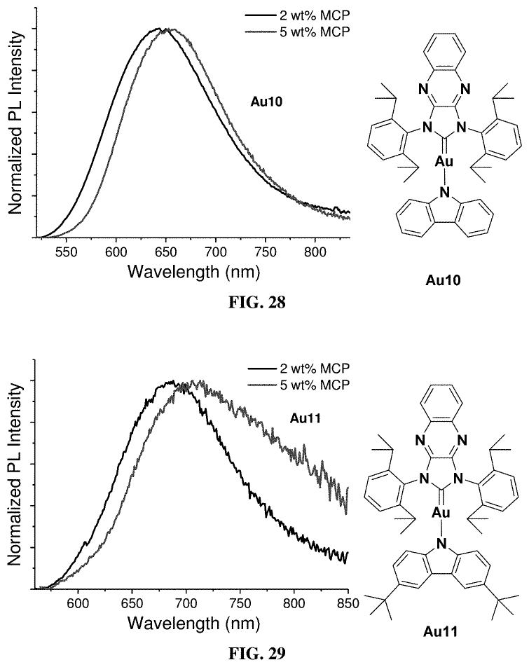

TABLE 19
Device data for Au2 in Device structure (III): ITO/HAT-CN (5 nm)/PT-
301 (160 nm)/PT-603I (5 nm)/Au2:LLP604 (20 nm)/PT74M (5 nm)/LET321:Liq
(1:1, 25 nm)/Liq (1 nm)/Al (100 nm). (cf. FIGS. 17A-17D)

| | | CE [cd A⁻¹] | | PE [lm W⁻¹] | | EQE [%] | | | |
|---|---|---|---|---|---|---|---|---|---|
| | L | | at 1000 | | at 1000 | | at 1000 | CIE | λₘₐₓ |
| Au2 | [cd m⁻²] | Max | cd m⁻² | Max | cd m⁻² | Max | cd m⁻² | (x, y) | [nm] |
| 2 wt/wt % | 212000 | 49.34 | 44.40 | 62.02 | 49.45 | 15.15 | 13.92 | (0.32, 0.55) | 532 |
| 4 wt/wt % | 250000 | 53.77 | 49.95 | 67.58 | 52.95 | 16.51 | 15.57 | (0.33, 0.55) | 534 |
| 8 wt/wt % | 230000 | 55.23 | 51.68 | 69.41 | 54.13 | 16.96 | 15.86 | (0.34, 0.55) | 538 |

TABLE 20
Device lifetime measurement for Au2. Device structure (III): ITO/HAT-CN
(5 nm)/PT-301 (160 nm)/PT-603I (5 nm)/Au2:LLP604 (20 nm)/PT74M
(5 nm)/LET321:Liq (1:1, 25 nm)/Liq (1 nm)/Al (100 nm).

| | | | | | | LT@1000 cd m⁻² | | |
|---|---|---|---|---|---|---|---|---|
| | L₀ | LT95 | LT90 | LT50 | | LT95 | LT90 | LT50 |
| Conc. | [cd m⁻²] | [h] | [h] | [h] | n | [h] | [h] | [h] |
| 2 wt/wt % | 17500 | 0.67 | 1.56 | 19.2 | 1.51 | 50.47 | 117.5 | 1446 |
| 4 wt/wt % | 21000 | 0.86 | 1.96 | 22.8 | 1.31 | 46.41 | 105.7 | 1230 |
| 8 wt/wt % | 21200 | 0.66 | 1.55 | 18.9 | 1.28 | 32.90 | 77.28 | 940 |

n denotes for acceleration factor in LT(L₁) = LT(L₀) × (L₀/L₁)ⁿ

TABLE 21
Device lifetime measurement for Au complex with 3,5-
dimethylphenyl group.^{a} Device structure: ITO/HAT-CN (5 nm)/
PT-301 (160 nm)/Spiro-3-BFP (15 nm)/
Au complex: DMIC-TRz:DMIC-Cz (15 nm)/LET003
(20 nm)/Liq (1 nm)/Al (100 nm)

| | L₀ | LT95 | LT50 | | LT@1000 cd m⁻² | |
|---|---|---|---|---|---|---|
| | [cd m⁻²] | [h] | [h] | n | LT95 [h] | LT50 [h] |
| 2wt/wt % | 5400 | 2.43 | 97 | 1.7 | 42.7 | 1705 |

n denotes for acceleration factor in LT(L₁) = LT(L₀) × (L₀/L₁)ⁿ
^{a}

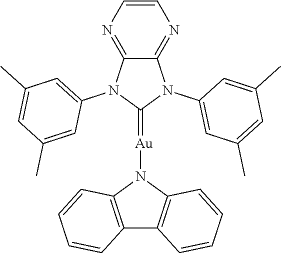

TABLE 22
Device data for Cu6 in TCTA:DPEPO co-host. Device structure:
ITO/HAT-CN (5 nm)/TAPC (40 nm)/TCTA (10 nm)/TCTA:DPEPO:Cu6
(20 nm)/DPEPO(10 nm)/TPBi (40 nm)/LiF (1.2 nm)/Al (100 nm).

| | | CE [cd A⁻¹] | | PE [lm W⁻¹] | | EQE [%] | | | |
|---|---|---|---|---|---|---|---|---|---|
| | Lₘₐₓ | | at 1000 | | at 1000 | | at 1000 | CIE | λₘₐₓ |
| Cu6 | [cd m⁻²] | Max | cd m⁻² | Max | cd m⁻² | Max | cd m⁻² | (x, y) | [nm] |
| 2 wt/wt % | 9110 | 30.3 | 22.8 | 24.7 | 11.1 | 21.2 | 15.9 | (0.14, 0.19) | 472 |
| 4 wt/wt % | 15600 | 36.4 | 28.8 | 32.6 | 13.9 | 23.6 | 18.7 | (0.14, 0.22) | 474 |
| 6 wt/wt % | 22700 | 33.9 | 32.1 | 29.1 | 15.5 | 20.0 | 18.9 | (0.14, 0.25) | 478 |

TABLE 23
Device lifetime measurement for Cu6. Device
structure: ITO/HAT-CN (10 nm)/BPBPA (120
nm)/mCBP (10 nm)/mCBP:SiCzTrz:Cu6 (30
nm)/SF3-TRz (5 nm)/SF3-TRz:Liq (1:1,
25 nm)/Liq (2 nm)/Al (100 nm).

| | | LT@L₀ | | | LT@1000 cd m⁻² | |
|---|---|---|---|---|---|---|
| | L₀ | LT90 | LT50 | | LT90 | LT50 |
| Conc. | [cd m⁻²] | [h] | [h] | n | [h] | [h] |
| 2 wt/wt % | 6100 | 0.36 | 5.31 | 1.51 | 5.52 | 81.5 |
| 4 wt/wt % | 6600 | 0.36 | 5.86 | 1.56 | 6.84 | 111 |
| 8 wt/wt % | 7600 | 0.4 | 7.46 | 1.66 | 11.6 | 216 |

n denotes for acceleration factor in LT(L₁) = LT(L₀) × (L₀/L₁)ⁿ

TABLE 24
Device data for hyper-fluorescence OLED based on Cu6 and ν-DABNA in mCBP.
Device structure: ITO/HAT-CN (10 nm)/BPBPA (120 nm)/mCBP (10 nm)/mCBP:Cu6:ν-DABNA
(20 nm)/SF3-TRz (5 nm)/SF3-TRz:Liq (1:1, 25 nm)/Liq (2 nm)/Al (100 nm).

| | | | | EQE [%] | | | | | |
|---|---|---|---|---|---|---|---|---|---|
| | Lₘₐₓ | CEₘₐₓ | PEₘₐₓ | | at 1000 | at 10000 | CIE | λₘₐₓ | FWHM |
| Cu6:ν-DABNA | [cd m⁻²] | [cd A⁻1] | [lm W⁻¹] | Max | cd m⁻² | cd m⁻² | (x, y) | [nm] | [nm] |
| 8:0 wt/wt % | 17000 | 16.8 | 16.3 | 8.63 | 7.66 | 6.63 | (0.18, 0.29) | 477 | 92 |
| 8:1 wt/wt % | 16500 | 15.6 | 16.1 | 9.70 | 8.51 | 6.82 | (0.16, 0.24) | 470 | 23 |
| 8:2 wt/wt % | 15200 | 14.3 | 12.8 | 10.2 | 8.42 | 6.13 | (0.15, 0.20) | 470 | 19 |

TABLE 25
Device lifetime measurement for hyper-fluorescence
OLED based on Cu6 and ν-DABNA in mCBP. Device
structure: ITO/HAT-CN (10 nm)/BPBPA (120 nm)/mCBP
(10 nm)/mCBP: Cu6: ν-DABNA (20 nm)/SF3-TRz (5
nm)/SF3-TRz: Liq (1:1, 25 nm)/Liq (2 nm)/Al (100 nm).

| Cu6: | L₀ | LT90@L₀ | | LT90@1000 cd |
|---|---|---|---|---|
| ν-DABNA | [cd m⁻²] | [h] | n | m⁻² [h] |
| 8:0 wt/wt % | 4000 | 0.48 | 1.64 | 4.7 |
| 8:1 wt/wt % | 6100 | 0.33 | 1.66 | 6.6 |
| 8:2 wt/wt % | 5000 | 0.76 | 1.72 | 12.2 |

n denotes for acceleration factor in LT(L₁) = LT(L₀) × (L₀/L₁)ⁿ

TABLE 26
Device data for Cu7 in DMIC-Cz:DMIC-Trz co-host. Device structure:
ITO/HAT-CN (10 nm)/BPBOA (80 nm)/FSF4A (5 nm)/DMIC-Cz:DMIC-Trz:Cu7
(30 nm)/ANT-Biz (5 nm)/ANT-Biz:Liq (25 nm)/Liq (2 nm)/Al (100 nm).

| | | CE [cd A⁻¹] | | | EQE [%] | | | | |
|---|---|---|---|---|---|---|---|---|---|
| | Lₘₐₓ | | at 1000 | at 10000 | | at 1000 | at 10000 | CIE | |
| Cu7 | [cd m⁻²] | Max | cd m⁻² | cd m⁻² | Max | cd m⁻² | cd m⁻² | (x, y) | λₘₐₓ |
| 2 wt/wt % | 190000 | 27.3 | 27.2 | 26.3 | 14.7 | 14.7 | 14.2 | (0.56, 0.44) | 600 |
| 4 wt/wt % | 160000 | 25.6 | 25.4 | 24.1 | 14.4 | 14.2 | 13.5 | (0.57, 0.43) | 601 |
| 6 wt/wt % | 113000 | 18.9 | 18.4 | 16.8 | 11.9 | 11.6 | 10.6 | (0.58, 0.42) | 604 |

TABLE 27
Device data for hyper-fluorescence OLED based on Cu7 and MR-R in RH. Device structure: ITO/HAT-CN (10
nm)/HT (40 nm)/EB (5 nm)/Cu7:MR-R:RH (40 nm)/HB (5 nm)/ZADN:Liq (35:65) (35 nm)/Liq (2 nm)/Al (100 nm)

| | | | CE [cd A⁻¹] | | | EQE [%] | | | | | |
|---|---|---|---|---|---|---|---|---|---|---|---|
| | | Lₘₐₓ | | at 1000 | at 10000 | | at 1000 | at 10000 | CIE | λₘₐₓ | FWHM |
| Cu7:MR-R | | [cd m⁻²] | Max | cd m⁻² | cd m⁻² | Max | cd m⁻² | cd m⁻² | (x, y) | [nm] | [nm] |
| 10:0 | wt/wt % | 109000 | 18.7 | 18.5 | 17.6 | 15.5 | 15.4 | 14.6 | (0.59, 0.41) | 612 | 125 |
| 10:0.3 | wt/wt % | 124000 | 22.7 | 22.6 | 21.7 | 14.5 | 14.4 | 13.8 | (0.61, 0.39) | 613 | 36 |

TABLE 28
Device lifetime measurement for OLEDs based on Cu7
and MR-R in RH. Device structure: ITO/HAT-CN (10 nm)/HT
(40 nm)/EB (5 nm)/Cu7:MR-R:RH (40 nm)/HB (5 nm)/ZADN:Liq
(35:65) (35 nm)/Liq (2 nm)/Al (100 nm).

| | | | LT@L₀ | | | LT@1000 cd m⁻² | |
|---|---|---|---|---|---|---|---|
| | | L₀ | LT95 | LT90 | | LT95 | LT90 |
| Cu7:MR-R | | [cd m⁻²] | [h] | [h] | n | [h] | [h] |
| 10:0 | wt/wt % | 8000 | 29.9 | 72 | 1.7 | 1026 | 2462 |
| 10:0.3 | wt/wt % | 8000 | 46.5 | 109 | 1.7 | 1595 | 3740 |

n denotes for acceleration factor in LT(L₁) = LT(L₀) × (L₀/L₁)ⁿ

TABLE 29
Device data for hyper-fluorescence OLEDs based on Au3 and BN-2 in mCBP.
Device structure: ITO/HAT-CN (5 nm)/TAPC (40 nm)/mCBP (10 nm)/Au3:BN-
2:mCBP (20 nm)/PPF (10 nm)/TmPyPb (40 nm)/LiF (1.2 nm)/Al (100 nm).

| | | | | | EQE [%] | | | | | |
|---|---|---|---|---|---|---|---|---|---|---|
| | | Lₘₐₓ | CEₘₐₓ | PEₘₐₓ | | at 1000 | at 10000 | CIE | λₘₐₓ | FWHM |
| Au3:BN-2 | | [cd m^{-2]} | [cd A⁻¹] | [lm W⁻¹] | Max | cd m⁻² | cd m⁻² | (x, y) | [nm] | [nm] |
| 6:1 | wt/wt % | 256000 | 92.2 | 90.9 | 25.3 | 19.1 | 16.2 | (0.29, 0.65) | 41 | 535 |
| 10:0.6 | wt/wt % | 247000 | 86.4 | 76.8 | 21.7 | 19.0 | 15.7 | (0.29, 0.66) | 41 | 536 |
| 6:0 | wt/wt % | 187000 | 71.2 | 63.6 | 23.0 | 21.4 | 19.6 | (0.25, 0.57) | 72 | 514 |

TABLE 30
Device data for OLEDs based on Au5 in mCBP:CzSiTrz co-host. Device structure:
ITO/HAT-CN (10 nm)/FSFA (120 nm)/mCBP (10 nm)/mCBP:CzSiTrz:Au5 (30
nm)/SF3-Trz (5 nm)/SF3-Trz:Liq (25 nm)/Liq (2 nm)/Al (100 nm).

| | | | | EQE [%] | | | | | |
|---|---|---|---|---|---|---|---|---|---|
| | Lₘₐₓ | CEₘₐₓ | PEₘₐₓ | | at 1000 | at 10000 | CIE | λₘₐₓ | FWHM |
| Au5 | [cd m⁻²] | [cd A⁻¹] | [lm W⁻¹] | Max | cd m⁻² | cd m⁻² | (x, y) | [nm] | [nm] |
| 2 wt/wt % | 183000 | 69.3 | 66.0 | 20.8 | 19.1 | 17.5 | (0.32, 0.56) | 533 | 94 |
| 4 wt/wt % | 300000 | 65.6 | 58.9 | 19.4 | 18.6 | 16.9 | (0.35, 0.57) | 543 | 96 |
| 8 wt/wt % | 195000 | 70.8 | 67.4 | 20.7 | 19.0 | 17.4 | (0.37, 0.57) | 543 | 94 |

TABLE 31
Device lifetime measurement for Au5.
Device structure: ITO/HAT-CN (10 nm)/FSFA
(120 nm)/mCBP (10 nm)/mCBP:CzSiTrz:Au5
(30 nm)/SF3-Trz (5 nm)/SF3-Trz:Liq (25
nm)/Liq (2 nm)/Al (100 nm).

| | | LT@L₀ | | | LT@1000 cd m⁻² | |
|---|---|---|---|---|---|---|
| | L₀ | LT90 | LT70 | | LT90 | LT70 |
| Conc. | [cd m⁻²] | [h] | [h] | n | [h] | [h] |
| 2 wt/wt % | 17500 | 0.99 | 5.87 | 1.74 | 144 | 854 |
| 4 wt/wt % | 6000 | 2.36 | 15.0 | 1.69 | 49 | 310 |
| 8 wt/wt % | 18000 | 0.60 | 3.13 | 1.56 | 54 | 284 |

n denotes for acceleration factor in LT(L₁) = LT(L₀) × (L₀/L₁)ⁿ

Unless defined otherwise, all technical and scientific terms used herein have the same meanings as commonly understood by one of skill in the art to which the disclosed invention belongs. Publications cited herein and the materials for which they are cited are specifically incorporated by reference. Further, unless otherwise indicated, use of the expression “wt %” refers to “wt/wt %.”

Those skilled in the art will recognize, or be able to ascertain using no more than routine experimentation, many equivalents to the specific embodiments of the invention described herein. Such equivalents are intended to be encompassed by the following claims.

We claim:

1. A compound having a structure: 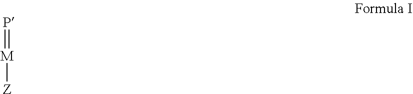
wherein:
the compound has an overall neutral, negative, or positive charge,
M is copper, silver, or gold with an oxidation state of 0, +1, +2, or +3, preferably +1,
P′ has the structure: 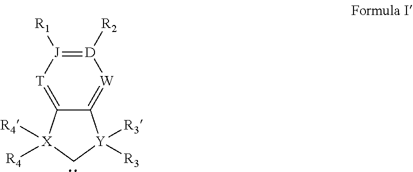
D is carbon,
T, J, and W are independently carbon or nitrogen, wherein at least one of T, J, and W is nitrogen, wherein when T is carbon, J is nitrogen, or when T is nitrogen, J is carbon, and T, J, and W are bonded to one or no hydrogen atom according to valency,
X and Y are independently carbon or nitrogen, wherein at least one of X and Y is nitrogen, and X and Y are bonded to one or no hydrogen atom according to valency,
R₁ and R₂ are independently hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, or R₁, J, D, and R₂ together form an unsubstituted aryl, substituted aryl, unsubstituted heteroaryl, or substituted heteroaryl,
R₃ and R₄ are independently hydrogen, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,
R₃′ and R4′ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, and
Z is substituted heteroaryl, unsubstituted heteroaryl, substituted polyheteroaryl, unsubstituted polyheteroaryl, substituted polyheterocyclyl, unsubstituted polyheterocyclyl, substituted heterocyclyl, or unsubstituted heterocyclyl, or —NRₐR_{b}, wherein Rₐ and R_{b} are independently hydrogen, substituted aryl, unsubstituted aryl, substituted heteroaryl, unsubstituted heteroaryl, substituted C3⁻C20 cycloalkyl, unsubstituted C₃-C₂₀ cycloalkyl, substituted heterocyclyl, unsubstituted heterocyclyl, substituted alkyl, or unsubstituted alkyl,
wherein (i) R₃ and R₄ are not both 3,5 dialkyl substituted aryl, (ii) R₃ and R₄ are not both 3,5 dialkyl substituted phenyl, (iii) R₃ and R₄ are not both 3,5 dimethylphenyl, (iv) R₃ and R₄ are not both 3,5 dimethylphenyl when M is Cu or Au, or (v) the compound is not

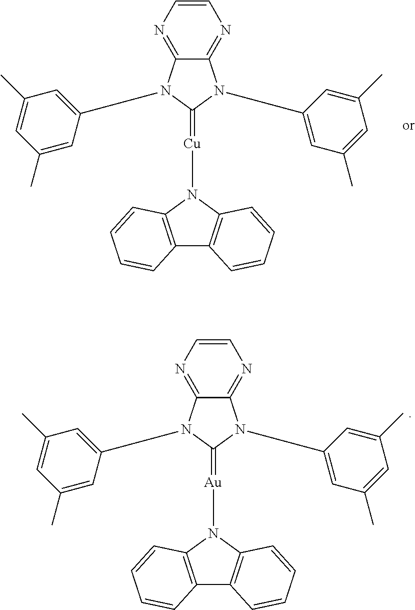

2. The compound of claim 1, having a structure: 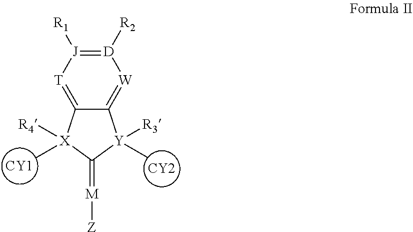
wherein CY1 and CY2 are independently substituted aryl, unsubstituted aryl, substituted polyaryl, unsubstituted polyaryl, substituted heteroaryl, unsubstituted heteroaryl, substituted polyheteroaryl, unsubstituted polyheteroaryl, substituted C₃-C₂₀ cycloalkyl, unsubstituted C₃-C₂₀ cycloalkyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl.

3. The compound of claim 1, wherein R₃′ and R₄′ are absent.

4. The compound of claim 2, wherein CY1 and CY2 are independently substituted aryl, unsubstituted aryl, substituted polyaryl, or unsubstituted polyaryl.

5. The compound of claim 2, wherein CY1 and CY2 are substituted aryl.

6. The compound of claim 1, having a structure: 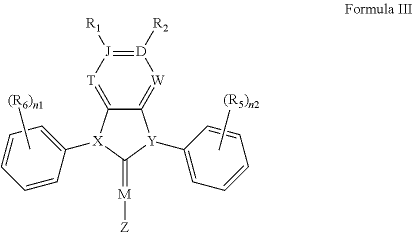
wherein:
R₅ and R₆ are independently substituted alkyl or unsubstituted alkyl, and
n1 and n2 are independently integers between 0 and 5; between 1 and 5; between 3 and 5, such as 3; or between 2 and 5; such as 2.

7. The compound of claim 1, having a structure: 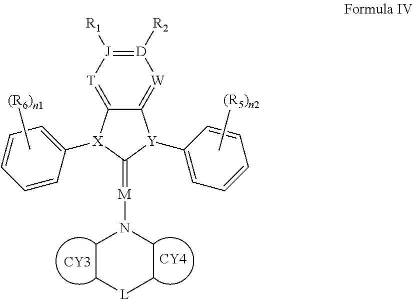
wherein:
n1 and n2 are independently integers between 1 and 5, between 2 and 5, or between 3 and 5,
L is absent, a single bond, substituted alkyl, —(CH₂)ₙₓ—, oxygen, sulfur, or NRx, wherein nx is an integer between 1 and 3 (such as 1, 2, or 3), and Rx is unsubstituted alkyl, substituted alkyl, unsubstituted aryl, or substituted aryl, and
CY3 and CY4 are independently unsubstituted aryl, substituted aryl, unsubstituted polyaryl, substituted polyaryl, unsubstituted heteroaryl, substituted heteroaryl, unsubstituted polyheteroaryl, substituted polyheteroaryl, unsubstituted C₃-C₂₀ cycloalkyl, substituted C₃-C₂₀ cycloalkyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, or a fused combination thereof.

8. The compound of claim 1, having a structure: 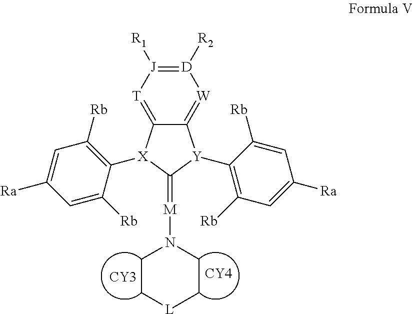
wherein:
each Ra is independently hydrogen, unsubstituted alkyl, or substituted alkyl,
each Rb is independently unsubstituted alkyl, or substituted alkyl, L is absent, a single bond, substituted alkyl, —(CH₂)ₙₓ—, oxygen, sulfur, or NRx, wherein nx is an integer between 1 and 3 (such as 1, 2, or 3), and Rx is unsubstituted alkyl, substituted alkyl, unsubstituted aryl, or substituted aryl, and
optionally wherein at least one of X and Y is nitrogen.

9. The compound of claim 1, wherein:
(i) T is nitrogen, J is carbon, and W is carbon,
(ii) T is nitrogen, J is carbon, and W is nitrogen,
(iii) T is carbon, J is nitrogen, and W is carbon, or
(iv) T is carbon, J is nitrogen, and W is nitrogen.

10. The compound of claim 8, wherein:
Ra is independently hydrogen, unsubstituted alkyl, or substituted alkyl, and
Rb is independently unsubstituted alkyl or substituted alkyl.

11. The compound of claim 1, wherein P′ is selected from: 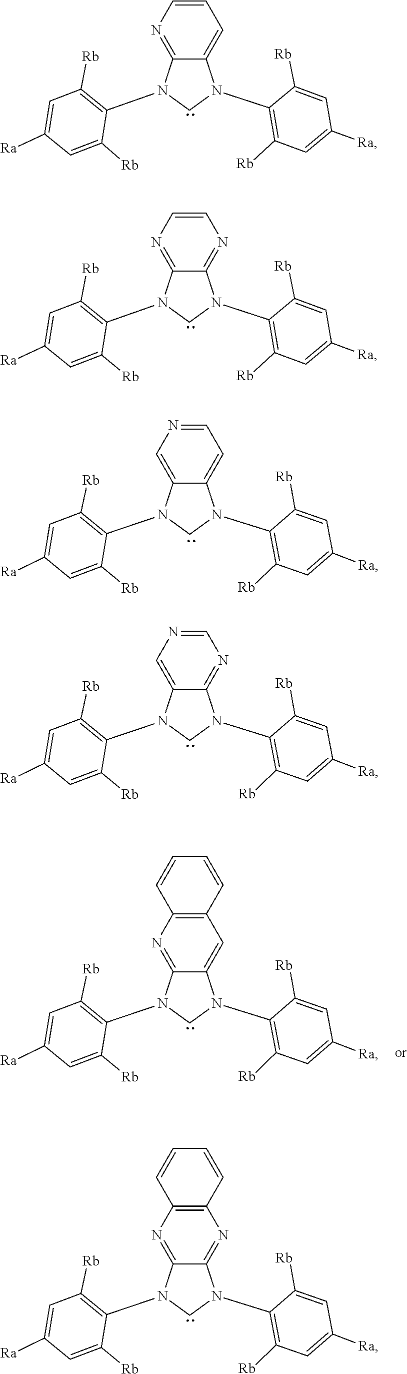
wherein:
Ra is independently hydrogen, unsubstituted alkyl, or substituted alkyl, and
Rb is independently unsubstituted alkyl or substituted alkyl.

12. The compound of claim 8, wherein:
Ra is independently hydrogen, methyl, iso-propyl, or —CH(C₂H₅)₂, and
Rb is independently methyl, iso-propyl, or —CH(C₂H₅)₂.

13. The compound of claim 7, wherein CY3 and CY4 are independently unsubstituted aryl, substituted aryl, unsubstituted polyaryl, substituted polyaryl, unsubstituted heteroaryl, unsubstituted heteroaryl, substituted C₃-C₂₀ cycloalkenyl, unsubstituted C₃-C₂₀ cycloalkenyl, or a fused combination thereof.

14. The compound of claim 7, wherein CY3 and CY4 are independently unsubstituted aryl, substituted aryl, unsubstituted heteroaryl, unsubstituted heteroaryl, substituted C₃-C₂₀ cycloalkenyl, unsubstituted C₃-C₂₀ cycloalkenyl, or a fused combination thereof.

15. The compound of claim 1, wherein Z has a structure: 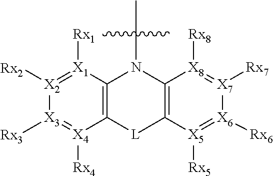
wherein:
X₁, X₂, X₃, X₄, X₅, X₆, X₇, and X₈ are independently carbon or nitrogen,
Rx₁, Rx₂,Rx₃, Rx₄, Rx₅, Rx₆, Rx₇, and Rx₈ are independently hydrogen, halogen, cyano, unsubstituted alkyl, substituted alkyl, unsubstituted alkoxy, substituted alkoxy, unsubstituted aryl, substituted aryl, unsubstituted heteroaryl, or substituted heteroaryl, wherein each Rx₁, Rx₂, Rx₃, Rx₄, Rx₅, Rx₆, Rx₇, or Rx₈ is absent, when the corresponding X₁, X₂, X₃, X₄, X₅, X₆, X₇, or X₈ is nitrogen, or Rx₄ is a bond connected to a substituent on L, or adjacent Rxn groups together with the atoms in the ring to which they are bonded, together independently form five- or six-membered substituted aryl, unsubstituted aryl, substituted heteroaryl, unsubstituted heteroaryl, substituted C₃-C₂₀ cycloalkenyl, unsubstituted C₃-C₂₀ cycloalkenyl, or a fused combination thereof, wherein the n in the adjacent Rxn groups are sequential pairs of integers from 1 to 4, or 5 to 8, and
L is absent, a single bond, substituted alkyl, —(CH₂)ₙₓ—, oxygen, sulfur, or NRx, wherein nx is an integer between 1 and 3 (such as 1, 2, or 3), and Rx is unsubstituted alkyl, substituted alkyl, unsubstituted aryl, or substituted aryl.

16. The compound of claim 1, wherein Z has a structure: 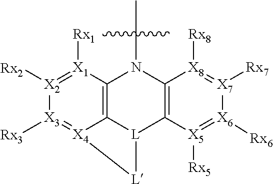
wherein:
L′ is substituted aryl, unsubstituted aryl, substituted heteroaryl, or unsubstituted heteroaryl, preferably substituted aryl or unsubstituted aryl, preferably substituted phenyl or unsubstituted phenyl.

17. The compound of claim 15, wherein Z has a structure:

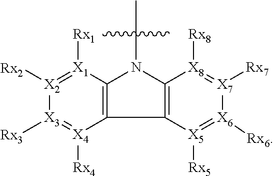

18. The compound of claim 15, wherein Rx₁, Rx₂, Rx₃, Rx₄, Rx₅, Rx₆, Rx₇, and Rx₈ are independently hydrogen, halogen, methyl, cyano, trifluoromethyl, tert-butyl, methoxy, phenyl, or pyridyl.

19. The compound of claim 1, wherein X and Y are nitrogen.

20. The compound of claim 1, having a structure: 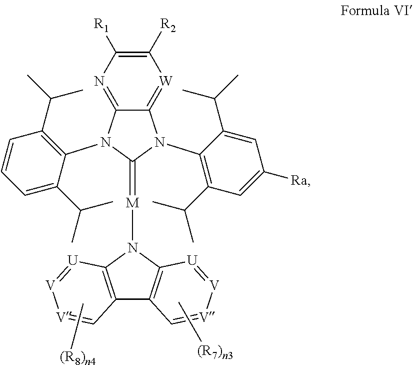
preferably 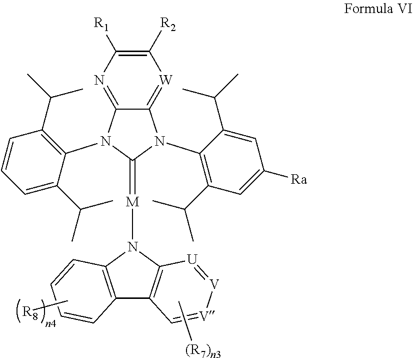
wherein:
V″ is carbon,
U is carbon and V is nitrogen, or U is nitrogen and V is carbon, wherein U, V, and V″ are bonded to one or no hydrogen atom according to valency,
Ra is hydrogen, unsubstituted alkyl, or substituted alkyl,
R₇ and R₈ are independently absent, hydrogen, substituted alkyl, unsubstituted alkyl, cyano, halogen, hydroxyl, thiol, nitro-, unsubstituted alkoxy, substituted alkoxy, unsubstituted aroxy, substituted aroxy, substituted aryl, unsubstituted aryl, or adjacent R₇ groups or adjacent Rs groups together with the atoms in the ring to which they are bonded, together independently form five- or six-membered substituted aryl, unsubstituted aryl, substituted heteroaryl, unsubstituted heteroaryl, substituted C₃-C₂₀ cycloalkenyl, unsubstituted C₃-C₂₀ cycloalkenyl, or a fused combination thereof, and
n3 and n4 are independently integers between 0 and 5, such as 0, 1, 2, 3, 4, 5.

21. The compound of claim 20, having a structure: 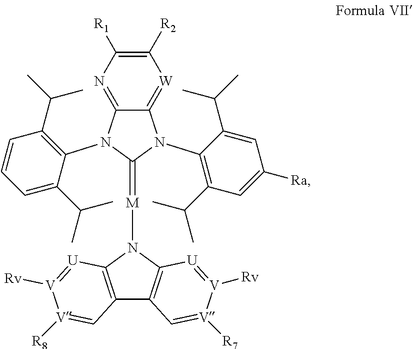
preferably 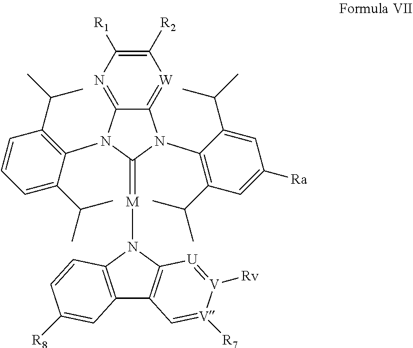
wherein:
Rv is absent, hydrogen, substituted alkyl, or unsubstituted alkyl, and
R₇ and R₈ are independently hydrogen, substituted alkyl, unsubstituted alkyl, unsubstituted aryl, halogen, cyano, or
Rv and R₇ together with the atoms in the rings to which they are bonded form five- or six-membered substituted aryl, unsubstituted aryl, substituted heteroaryl, unsubstituted heteroaryl, substituted C₃-C₂₀ cycloalkenyl, unsubstituted C3⁻C20 cycloalkenyl, or a fused combination thereof.

22. The compound of claim 20, wherein:
Rv is absent or hydrogen,
R₇ and R₈ are independently hydrogen, iso-propyl, tert-butyl, phenyl, fluorine, or cyano, or
Rv and R₇ together form

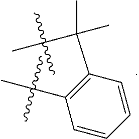 [SMILES: *c1ccccc1C(*)(C)C]

23. The compound of claim 20, wherein:
R₁ and R₂ are independently hydrogen, substituted alkyl, unsubstituted alkyl, substituted alkenyl, unsubstituted alkenyl, substituted alkynyl, unsubstituted alkynyl, substituted aryl, unsubstituted aryl, or
R₁ and R₂ with the atoms in the ring to which they are bonded together form unsubstituted aryl, substituted aryl, unsubstituted heteroaryl, or substituted heteroaryl.

24. The compound of claim 20, wherein:
R₁ and R₂ are hydrogen, or
R₁ and R₂ together form the structure:

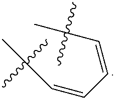 [SMILES: */C=C\C=C/*]

25. The compound of claim 24, having a structure: 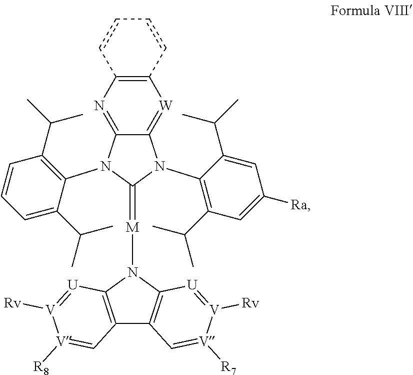
preferably 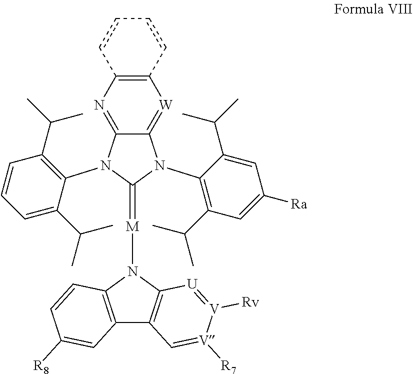
wherein:
(i) M=Cu(I); W=N; Ra=H; U=CH; V=V″=carbon; Rv=H; R₇=R₈=H;
(ii) M=Cu(I); W=N; Ra=H; U=CH; V=V″=carbon; Rv=H; R₇=H; R₈=CN;
(iii) M=Cu(I); W=N; Ra=H; U=CH; V=V″=carbon; Rv=H; R₇=R₈=tert-butyl;
(iv) M=Cu(I); W=N; Ra=H; U=CH; V=V″=carbon; Rv=H; R₇=R₈=phenyl;
(v) M=Cu(I); W=N; Ra=H; U=CH; V=N; V″=carbon; Rv=absent; R₇=R₈=H;
(vi) M=Cu(I); W=U=CH; V=V″=carbon; Rv=H; Ra=iso-propyl; R₇=R₈=H;
(vii) M=Cu(I); W=N; Ra=H; U=CH; V=V″=carbon; R₈=H; Rv and R₇ together form 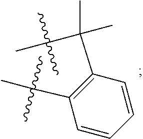 [SMILES: *c1ccccc1C(*)(C)C]
(viii) M=Cu(I); W=U=CH; Ra=iso-propyl; V=V″=carbon; R₈=H; Rv and R₇ together form 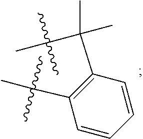 [SMILES: *c1ccccc1C(*)(C)C]
(ix) M=Cu(I); W=N; Ra=H; U=CH; V=V″=carbon; Rv=H; R₇=R₈=H;
(x) M=Cu(I); W=N; Ra=H; U=CH; V=V″=carbon; Rv=H; R₇=H; R₈=F;
(xi) M=Cu(I); W=N; Ra=H; U=CH; V=V″=carbon; Rv=H; R₇=R₈=methyl;
(xii) M=Au(I); W=N; Ra=H; U=CH; V=carbon; Rv=H; V″=carbon; R₇=R₈=H;
(xiii) M=Au(I); W=N; Ra=H; U=CH; V=carbon; Rv=H; V″=carbon; R₇=H, R₈=CN;
(xiv) M=Au(I); W=N; Ra=H; U=N; V=carbon; Rv=H; V″=carbon; R₇=R₈=H;
(xv) M=Au(I); W=U=CH; V=carbon; Rv=H; ; Ra=iso-propyl; V″=carbon; R₇=R₈=H;
(xvi) M=Au(I); W=N; Ra=H; U=CH; V=N; Rv=absent; V″=carbon; R₇=R₈=H;
(xvii) M=Au(I); W=N; Ra=H; U=CH; V=V″=carbon; Rv=H; R₇=R₈=CN;
(xviii) M=Au(I); W=N; Ra=hydrogen; U=CH; V=V″=carbon; R₈ =H; Rv and R₇ together form 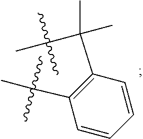 [SMILES: *c1ccccc1C(*)(C)C]
(xix) M=Au(I); W=U=CH; Ra=iso-propyl; V=V″=carbon; Rv=H; R₇=R₈=tert-butyl;
(xx) M=Au(I); W=U=CH; Ra=iso-propyl; V=V″=carbon; Rv=H; R₇=H; R₈=F;
(xxi) M=Au(I); W=N; U=CH; Ra=H; V=V″=carbon; Rv=H; R₇=R₈ =H;
(xxii) M=Au(I); W=N; U=CH; Ra=H; V=V″=carbon; Rv=H; R₇=R₈ =tert-butyl;
(xxiii) M=Ag(I); W=N; U=CH; Ra=H; V=V″=carbon; Rv=H; R₇=R₈ =H;
for (i), (ii), (iii), (iv), (v), (vi), (vii), (viii), (xii), (xiii), (xiv), (xv), (xvi), (xvii), (xviii), (xix), (xx), and (xxiii), the dashed lines denote the absence of bonds, and
for (ix), (x), (xi), (xxi), and (xxii), the dashed lines denote the presence of bonds.

26. The compound of claim 1, having a structure: 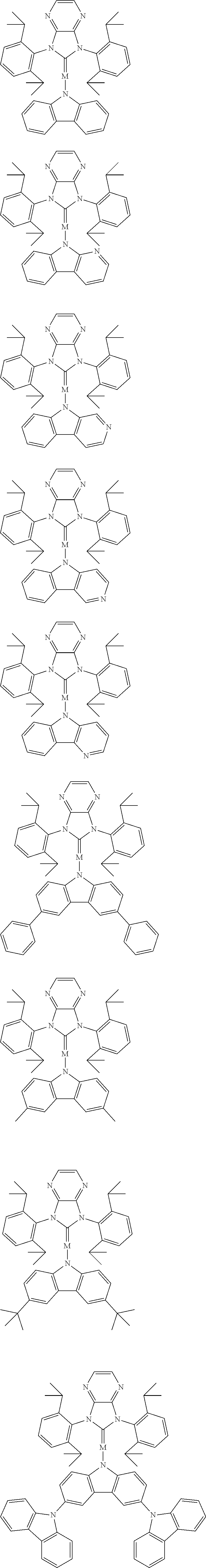 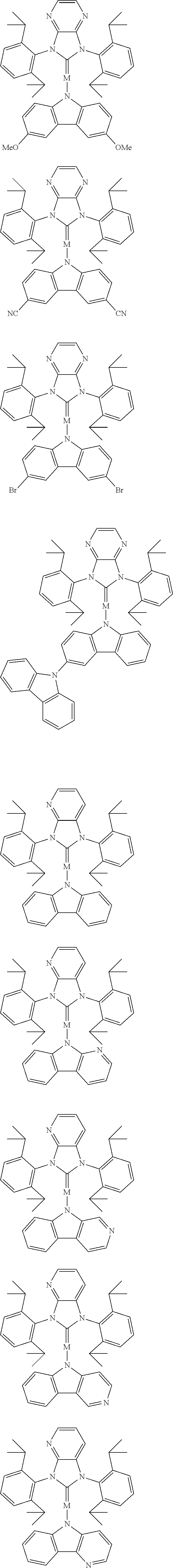 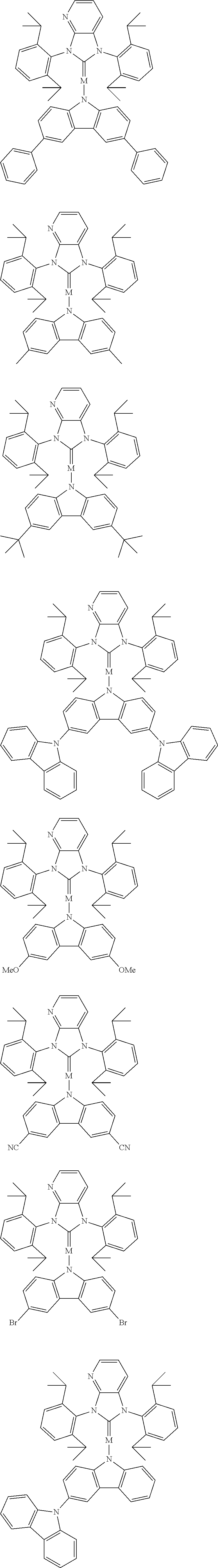 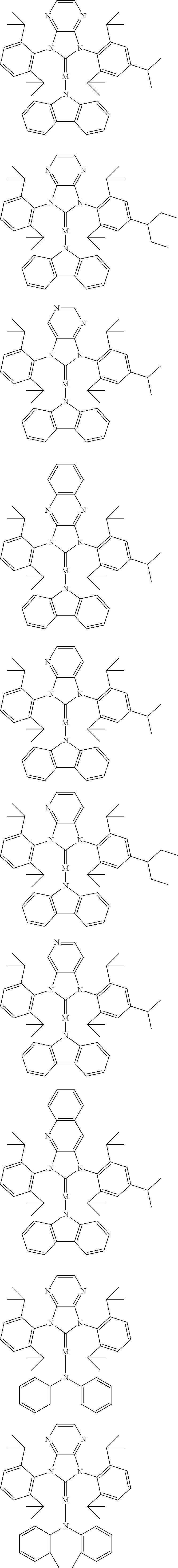 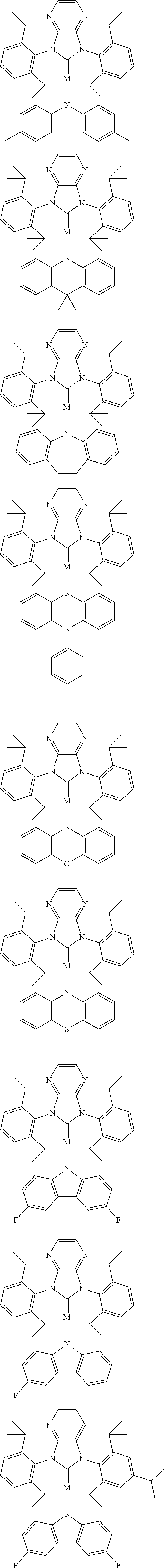 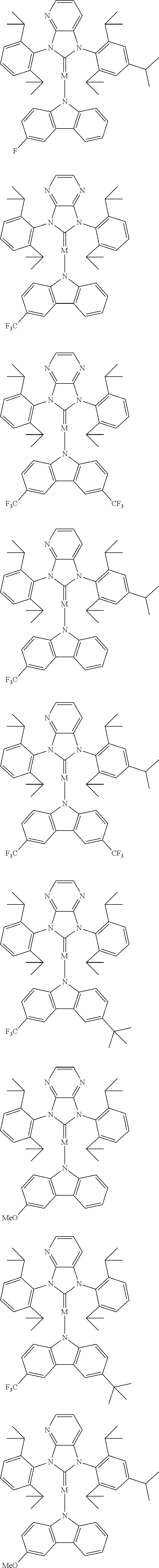 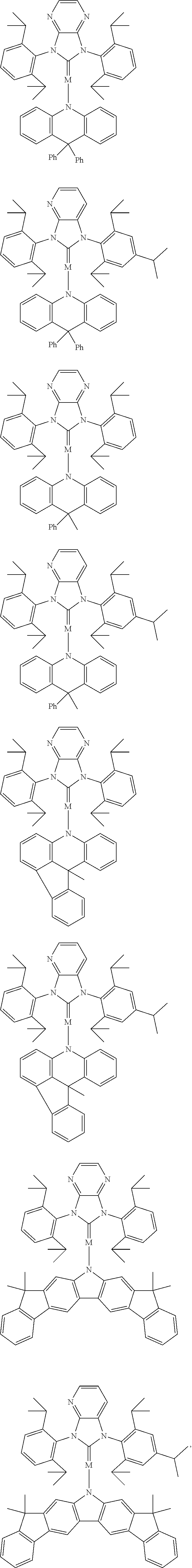
wherein M=Cu(I), Au(I), or Ag(I).

27. The compound of claim 1, wherein substituted means substituted with one or more substituents selected from: halogen, hydroxyl, thiol, nitro-, unsubstituted alkyl, unsubstituted alkenyl, unsubstituted alkynyl, unsubstituted aryl, unsubstituted heteroaryl, unsubstituted arylalkyl, unsubstituted alkoxy, unsubstituted aroxy, unsubstituted alkylthio, unsubstituted arylthio, cyano, isocyano, unsubstituted carbonyl, unsubstituted carboxyl, oxo, unsubstituted amino, unsubstituted amido, unsubstituted sulfonyl, unsubstituted sulfonic acid, unsubstituted phosphoryl, unsubstituted phosphonyl, unsubstituted polyaryl, or unsubstituted C₃-C₂₀ cycloalkyl, and unsubstituted heterocyclyl.

28. An organic electronic component comprising the compound of claim 1.

29. The organic electronic component of claim 28, wherein the organic electronic component is an organic light-emitting diode (OLED) or a light-emitting electrochemical cell (LEEC).

30. The organic electronic component of claim 28, wherein the compounds are in a light-emitting layer.

31. The organic electronic component of claim 28, further comprising an anode, a cathode, a hole transport region, and an electron transport region,
wherein the hole transport region comprises a hole injection layer and/or a hole transport layer, and optionally an electron blocking layer,
wherein the electron transport region comprises an electron transport layer and/or an electron injection layer, and optionally a hole blocking layer,
wherein the light emitting layer is located in between the anode and the cathode,
wherein the hole transport region is located between the anode and the light-emitting layer, and wherein the electron transport region is located in between the cathode and the light-emitting layer.

32. The organic electronic component of claim 29, wherein the light-emitting layer is fabricated by vacuum deposition, spin-coating or ink printing (such as, ink-jet printing or roll-to-roll printing).

33. A light-emitting layer comprising the compound of claim 1.

34. A light-emitting layer comprising the compound of claim 1 and a pure organic emitter, wherein the compound acts as a sensitizer to transfer energy (such as exciton energy or photon energy) to the pure organic emitter.

35. A light-emitting layer comprising the compound of claim 1 and a pure organic emitter, wherein the compound has a higher-lying singlet state than the pure organic emitter.

36. A light-emitting layer comprising the compound of claim 1 and a pure organic emitter, wherein the compound acts as a sensitizer to transfer energy (such as exciton energy or photon energy) to the pure organic emitter that exhibits thermally activated delayed fluorescence.

37. A light-emitting layer comprising the compound of claim 1 and a pure organic emitter, wherein the compound acts as a sensitizer to transfer energy (such as exciton energy or photon energy) to the pure organic emitter that is boron-based.

38. An OLED, comprising the light-emitting layer of claim 33.

39. A device, comprising the OLED of claim 38, wherein the device is selected from stationary visual display units, mobile visual display units, illumination units, keyboards, clothes, ornaments, garment accessories, wearable devices, medical monitoring devices, wall papers, tablet computers, laptops, advertisement panels, panel display units, household appliances, or office appliances.
